(19) United States
(12) Patent Application Publication
(10) Pub. No.: US 2026/0075875 A1
(43) Pub. Date: Mar. 12, 2026

(54) SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Takanori MATSUZAKI, Atsugi (JP); Yoshiaki OIKAWA, Atsugi (JP)

(21) Appl. No.: 19/132,900

(22) PCT Filed: Nov. 24, 2023
(86) PCT No.: PCT/IB2023/061857

§ 371 Date: May 27, 2025

(30) Foreign Application Priority Data
Dec. 1, 2022 (JP) 2022-192655
Dec. 1, 2022 (JP) 2022-192676

(51) Int. Cl. H10D 30/67; H10B 12/00; H10D 30/01; H10D 62/10

(52) U.S. Cl. CPC H10D 30/6728; H10D 30/0318; H10D 30/6729; H10D 30/6755; H10D 62/116; H10B 12/33

(57) ABSTRACT

A semiconductor device that can be miniaturized or highly integrated is provided. The semiconductor device includes a first conductor, a first insulator, a second conductor over the first insulator, an oxide semiconductor, a second insulator, a third conductor, a third insulator, and a fourth insulator. In the semiconductor device, an opening portion reaching the first conductor is provided in the first insulator and the second conductor, part of the oxide semiconductor is placed in the opening portion and is in contact with a top surface of the first conductor, another part of the oxide semiconductor is placed over the opening portion and is in contact with at least part of a top surface of the second conductor, the second insulator is placed over the oxide semiconductor so as to be at least partly positioned in the opening, the third conductor is placed over the second insulator so as to be at least partly positioned in the opening, the third insulator is placed between a sidewall of the opening portion and the oxide semiconductor so as to be positioned in the opening, and the fourth insulator is placed between the sidewall of the opening portion and the third insulator, the third insulator comprises a metal oxide, and the fourth insulator comprises silicon nitride.

### TECHNICAL FIELD

One embodiment of the present invention relates to a transistor, a semiconductor device, a memory device, and an electronic appliance. Another embodiment of the present invention relates to a method for manufacturing a memory device or a semiconductor device. Another embodiment of the present invention relates to a semiconductor wafer and a module.

Note that in this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic appliance, and the like include a semiconductor device.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

In recent years, semiconductor devices have been developed, and LSIs, CPUs, memories, and the like are mainly used as the semiconductor devices. A CPU is an aggregation of semiconductor elements; the CPU includes a semiconductor integrated circuit (including at least a transistor and a memory) formed into a chip by processing a semiconductor wafer and is provided with an electrode serving as a connection terminal.

A semiconductor circuit (IC chip) of an LSI, a CPU, a memory, or the like is mounted on a circuit board, for example, a printed wiring board, to be used as one of components of a variety of electronic appliances.

A technique in which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film usable for the transistor and further, an oxide semiconductor has been attracting attention as another material.

It is known that a transistor including an oxide semiconductor has an extremely low leakage current in a non-conduction state. For example, Patent Document 1 discloses a low-power-consumption CPU utilizing a feature of a low leakage current of the transistor including an oxide semiconductor. Furthermore, for example, Patent Document 2 discloses a memory device that can retain stored contents for a long time of period by utilizing a feature of a low leakage current of the transistor including an oxide semiconductor.

In recent years, demand for an integrated circuit with higher density has risen with reductions in size and weight of electronic appliances. Furthermore, the productivity of a semiconductor device including an integrated circuit is desired to be improved. For example, Patent Document 3 and Non-Patent Document 1 disclose a technique for achieving an integrated circuit with higher density by making a plurality of memory cells overlap with each other by stacking a first transistor including an oxide semiconductor film and a second transistor including an oxide semiconductor film.

Furthermore, by employing vertical transistors, an integrated circuit with higher density can be achieved. For example, Patent Document 4 discloses a vertical transistor in which a side surface of an oxide semiconductor is covered with a gate electrode with a gate insulator therebetween.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1] M. Oota, et al., “3D-Stacked CAAC—In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device that can be miniaturized or highly integrated. Another object is to provide a semiconductor device with high reliability. Another object is to provide a semiconductor device with high operation speed. Another object is to provide a semiconductor device having favorable electrical characteristics. Another object is to provide a semiconductor device with a small variation in electrical characteristics of transistors. Another object is to provide a semiconductor device with a high on-state current. Another object is to provide a semiconductor device with low power consumption. Another object is to provide a novel semiconductor device. Another object is to provide a method for manufacturing a novel semiconductor device.

Note that the description of these objects does not preclude the existence of other objects. One embodiment of the present invention does not necessarily achieve all these objects. Note that other objects will be apparent from and can be derived from the description of the specification, the drawings, the claims, and the like.

### Means for Solving the Problems

One embodiment of the present invention is a semiconductor device including a first conductor, a first insulator, a second conductor over the first insulator, an oxide semiconductor, a second insulator, a third conductor, a third insulator, and a fourth insulator. In the semiconductor device, an opening portion reaching the first conductor is provided in the first insulator and the second conductor, part of the oxide semiconductor is placed in the opening portion and is in contact with a top surface of the first conductor, another part of the oxide semiconductor is placed over the opening portion and is in contact with at least part of a top surface of the second conductor, the second insulator is placed over the oxide semiconductor so as to be at least partly positioned in the opening portion, the third conductor is placed over the second insulator so as to be at least partly positioned in the opening portion, the third insulator is placed between a sidewall of the opening portion and the oxide semiconductor so as to be positioned in the opening portion, the fourth insulator is placed between the sidewall of the opening portion and the third insulator so as to be positioned in the opening portion, the third insulator includes a metal oxide, and the fourth insulator includes silicon nitride.

In the above, it is preferable that the first insulator include a first layer, a second layer over the first layer, and a third layer over the second layer, the first layer and the third layer each include silicon nitride, and the second layer include silicon oxide.

In the above structure, a side surface of the second conductor may be in contact with the fourth insulator.

In the above, part of a bottom surface of the second conductor may be in contact with an upper end portion of the third insulator and an upper end portion of the fourth insulator.

In the above, part of a bottom surface of the third layer may be in contact with an upper end portion of the third insulator and an upper end portion of the fourth insulator.

In the above, a width of the opening portion is preferably larger than a height of the opening portion in a cross-sectional view.

In the above, it is preferable that a fifth insulator including silicon oxide be included and the fifth insulator be placed between the third insulator and the oxide semiconductor so as to be positioned in the opening portion.

In the above, it is preferable that part of the fourth insulator be placed under the third insulator and part of the fourth insulator be in contact with a lower end portion of the third insulator and a side surface of the fifth insulator.

In the above, the metal oxide preferably contains hafnium.

Another embodiment of the present invention is a semiconductor device including a first conductor, a second conductor, a third conductor, a fourth conductor, an oxide semiconductor, a first insulator, a second insulator, a third insulator, a fourth insulator, and a fifth insulator. In the semiconductor device, the second conductor is positioned over the first insulator, the second insulator is positioned over the second conductor, the third conductor is positioned over the second insulator, an opening portion reaching the first conductor is provided in the first insulator, the second conductor, the second insulator, and the third conductor, part of the oxide semiconductor is placed in the opening portion and is in contact with a top surface of the first conductor, another part of the oxide semiconductor is in contact with at least part of a top surface of the third conductor outside the opening portion, the third insulator is placed over the oxide semiconductor so as to be at least partly positioned in the opening portion, the fourth conductor is placed over the third insulator so as to be at least partly positioned in the opening portion, the fourth insulator is placed between the second conductor and the oxide semiconductor so as to be positioned in the opening portion, the fifth insulator is placed between the second conductor and the fourth insulator so as to be positioned in the opening portion, the fourth insulator includes a metal oxide, and the fifth insulator includes silicon nitride.

In the above, the first insulator and the second insulator each preferably include silicon nitride.

In the above, a side surface of the third conductor may be in contact with the fifth insulator.

In the above, part of a bottom surface of the third conductor may be in contact with an upper end portion of the fourth insulator and an upper end portion of the fifth insulator.

In the above, part of a bottom surface of the second insulator may be in contact with an upper end portion of the fourth insulator and an upper end portion of the fifth insulator.

In the above, a width of the opening portion is preferably larger than a height of the opening portion in a cross-sectional view.

In the above, a sixth insulator including silicon oxide is included and the sixth insulator be placed between the fourth insulator and the oxide semiconductor so as to be positioned in the opening portion.

In the above, it is preferable that part of the fifth insulator be placed under the fourth insulator and part of the fifth insulator be in contact with a lower end portion of the fourth insulator and a side surface of the sixth insulator.

In the above, the metal oxide preferably contains hafnium.

### Effect of the Invention

One embodiment of the present invention can provide a semiconductor device that can be miniaturized or highly integrated. Alternatively, a semiconductor device with high reliability can be provided. Alternatively, a semiconductor device with a high operation speed can be provided. Alternatively, a semiconductor device with a small variation in electrical characteristics of transistors can be provided. Alternatively, a semiconductor device having favorable electrical characteristics can be provided. Alternatively, a semiconductor device with a high on-state current can be provided. Alternatively, a semiconductor device with low power consumption can be provided. Alternatively, a novel semiconductor device can be provided. Alternatively, a method for manufacturing a novel semiconductor device can be provided.

Note that the description of these effects does not preclude the existence of other effects. Note that one embodiment of the present invention does not need to have all of these effects. Other effects will be apparent from and can be derived from the description of the specification, the drawings, the claims, and the like.

### BRIEF DESCRIPTION OF THE DRAWINGS

FIG. 1 is a perspective view illustrating an example of a semiconductor device.

FIG. 2A is a plan view illustrating an example of a semiconductor device. FIG. 2B to FIG. 2E are cross-sectional views illustrating the example of the semiconductor device.

FIG. 3 is a cross-sectional view illustrating an example of a semiconductor device.

FIG. 4A is a plan view illustrating an example of a semiconductor device. FIG. 4B to FIG. 4E are cross-sectional views illustrating the example of the semiconductor device.

FIG. 5A is a plan view illustrating an example of a semiconductor device. FIG. 5B to FIG. 5E are cross-sectional views illustrating the example of the semiconductor device.

FIG. 6A to FIG. 6C are cross-sectional views each illustrating an example of a semiconductor device.

FIG. 7A to FIG. 7D are cross-sectional views each illustrating an example of a semiconductor device.

FIG. 8A to FIG. 8E are cross-sectional views each illustrating an example of a semiconductor device.

FIG. 9A is a plan view illustrating an example of a semiconductor device. FIG. 9B to FIG. 9D are cross-sectional views illustrating the example of the semiconductor device.

FIG. 10A is a plan view illustrating an example of a method for manufacturing a semiconductor device. FIG. 10B and FIG. 10C are cross-sectional views illustrating the example of the method for manufacturing the semiconductor device.

FIG. 11A is a plan view illustrating the example of the method for manufacturing the semiconductor device. FIG. 11B and FIG. 11C are cross-sectional views illustrating the example of the method for manufacturing the semiconductor device.

FIG. 12A is a plan view illustrating the example of the method for manufacturing the semiconductor device. FIG. 12B and FIG. 12C are cross-sectional views illustrating the example of the method for manufacturing the semiconductor device.

FIG. 13A is a plan view illustrating the example of the method for manufacturing the semiconductor device. FIG. 13B and FIG. 13C are cross-sectional views illustrating the example of the method for manufacturing the semiconductor device.

FIG. 14A is a plan view illustrating the example of the method for manufacturing the semiconductor device. FIG. 14B and FIG. 14C are cross-sectional views illustrating the example of the method for manufacturing the semiconductor device.

FIG. 15A is a plan view illustrating the example of the method for manufacturing the semiconductor device. FIG. 15B and FIG. 15C are cross-sectional views illustrating the example of the method for manufacturing the semiconductor device.

FIG. 16A is a plan view illustrating the example of the method for manufacturing the semiconductor device. FIG. 16B and FIG. 16C are cross-sectional views illustrating the example of the method for manufacturing the semiconductor device.

FIG. 17A is a plan view illustrating the example of the method for manufacturing the semiconductor device. FIG. 17B and FIG. 17C are cross-sectional views illustrating the example of the method for manufacturing the semiconductor device.

FIG. 18A is a plan view illustrating the example of the method for manufacturing the semiconductor device. FIG. 18B and FIG. 18C are cross-sectional views illustrating the example of the method for manufacturing the semiconductor device.

FIG. 19A is a plan view illustrating the example of the method for manufacturing the semiconductor device. FIG. 19B and FIG. 19C are cross-sectional views illustrating the example of the method for manufacturing the semiconductor device.

FIG. 20A to FIG. 20F are cross-sectional views illustrating an example of a method for manufacturing a semiconductor device.

FIG. 21A to FIG. 21F are cross-sectional views illustrating an example of a method for manufacturing a semiconductor device.

FIG. 22A is a plan view illustrating an example of a memory device. FIG. 22B and FIG. 22C are cross-sectional views illustrating the example of the memory device. FIG. 22D is a circuit diagram for describing a structure example of the memory device.

FIG. 23A is a plan view illustrating an example of a memory device. FIG. 23B is a cross-sectional view illustrating the example of the memory device.

FIG. 24A is a plan view illustrating an example of a memory device. FIG. 24B is a cross-sectional view illustrating the example of the memory device.

FIG. 25A is a plan view illustrating an example of a memory device. FIG. 25B is a cross-sectional view illustrating the example of the memory device.

FIG. 26 is a cross-sectional view illustrating an example of a memory device.

FIG. 27A is a plan view illustrating an example of a memory device. FIG. 27B and FIG. 27C are cross-sectional views illustrating the example of the memory device. FIG. 27D is a circuit diagram for describing a structure example of the memory device.

FIG. 28A to FIG. 28E are cross-sectional views illustrating a method for forming a metal oxide according to one embodiment of the present invention.

FIG. 29A to FIG. 29D are cross-sectional views of metal oxides according to one embodiment of the present invention.

FIG. 30A to FIG. 30D are cross-sectional views illustrating a method for forming a metal oxide according to one embodiment of the present invention.

FIG. 31A to FIG. 31C are cross-sectional views illustrating the method for forming the metal oxide according to one embodiment of the present invention.

FIG. 32 is a block diagram illustrating a structure example of a memory device.

FIG. 33A is a schematic cross-sectional view illustrating a structure example of a memory device.

FIG. 33B is a circuit diagram illustrating the structure example of the memory device.

FIG. 34A and FIG. 34B are schematic views illustrating structure examples of a memory device.

FIG. 35 is a circuit diagram illustrating a structure example of a memory device.

FIG. 36A and FIG. 36B are schematic views of a semiconductor device according to one embodiment of the present invention.

FIG. 37A and FIG. 37B are diagrams illustrating examples of electronic components.

FIG. 38A to FIG. 38E are schematic views of memory devices according to one embodiment of the present invention.

FIG. 39A to FIG. 39H are diagrams illustrating electronic appliances according to one embodiment of the present invention.

FIG. 40A is a diagram illustrating an example of a storage system that can be used in a data center.

FIG. 40B is a diagram illustrating an example of space equipment.

### MODE FOR CARRYING OUT THE INVENTION

Embodiments are described below with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the description of the embodiments below.

In the drawings, the size, the layer thickness, or the region is exaggerated for the sake of clarity in some cases. Therefore, the size, the layer thickness, or the region is not limited to the illustrated scale. Note that the drawings schematically show ideal examples, and embodiments of the present invention are not limited to shapes or values shown in the drawings. For example, in the actual manufacturing process, a layer, a resist mask, or the like might be unintentionally reduced in size by treatment such as etching, which is not be reflected in the drawings for easy understanding in some cases. Furthermore, in the drawings, the same reference numerals are used in common for the same portions or portions having similar functions in different drawings, and repeated description thereof is omitted in some cases. The same hatching pattern is used to show portions having similar functions, and the portions are not especially denoted by reference numerals in some cases.

Furthermore, especially in a plan view (also referred to as a “top view”), a perspective view, or the like, the description of some components is omitted for easy understanding of the invention in some cases. The description of some hidden lines is also omitted in some cases.

The ordinal numbers such as “first” and “second” in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like do not correspond to the ordinal numbers that are used to specify one embodiment of the present invention in some cases.

Moreover, in this specification and the like, terms for describing arrangement, such as “over” and “under”, are used for convenience for describing the positional relationship between components with reference to drawings. The positional relationship between components changes as appropriate in accordance with the direction in which the components are described. Thus, without limitation to terms described in this specification, the description can be changed appropriately depending on the situation.

In this specification and the like, for example, the expression “X and Y are connected” means the case where X and Y are electrically connected. Here, the expression “X and Y are electrically connected” means connection that enables electrical signal transmission between X and Y in the case where an object (that refers to an element such as a switch, a transistor, or a diode, a circuit including the element and a wiring, or the like) is present between X and Y. Note that the case where X and Y are electrically connected includes the case where X and Y are directly connected. Here, the expression “X and Y are directly connected” means connection that enables electrical signal transmission between X and Y through a wiring (or an electrode) or the like, not through the above object. In other words, direct connection refers to connection that can be regarded as the same circuit diagram when represented by an equivalent circuit.

In this specification and the like, a transistor is an element having at least three terminals including a gate, a drain, and a source. In addition, the transistor includes a region where a channel is formed (hereinafter also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, the channel formation region refers to a region through which a current mainly flows.

Furthermore, functions of a source and a drain are sometimes interchanged with each other when a transistor of different polarity is used or when the direction of a current is changed in a circuit operation, for example. Therefore, the terms “source” and “drain” can sometimes be interchanged with each other in this specification and the like.

Note that impurities in a semiconductor refer to, for example, elements other than the main components of the semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. Note that water also serves as an impurity in some cases. In addition, an oxygen vacancy (also referred to as Vo) is formed in an oxide semiconductor in some cases by entry of impurities, for example.

Note that in this specification and the like, an oxynitride is a material that contains more oxygen than nitrogen in its composition. Examples of oxynitride include silicon oxynitride, aluminum oxynitride, and hafnium oxynitride. Moreover, a nitride oxide is a material that contains more nitrogen than oxygen in its composition. Examples of nitride oxide include silicon nitride oxide, aluminum nitride oxide, and hafnium nitride oxide.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and with a change in the reference potential, a potential supplied to a wiring, a potential applied to a circuit or the like, and a potential or the like output from a circuit or the like change as well.

In this specification and the like, when a plurality of components are denoted with the same reference numeral, and in particular need to be distinguished from each other, an identification sign such as “_1”, “[n]”, or “[m,n]” is sometimes added to the reference numeral.

Note that in this specification and the like, the expression “the levels are the same” is used to describe a structure in which heights from a reference plane (e.g., a flat surface such as a substrate surface) are at the same level in a cross-sectional view. For example, in a manufacturing process of a semiconductor device, planarization treatment (typically, CMP treatment) is performed, whereby the surface of a single layer or the surfaces of a plurality of layers is/are exposed in some cases. In this case, the surfaces on which the CMP treatment is performed are at the same level from a reference plane. Note that the plurality of layers are at different levels in some cases, depending on a treatment apparatus, a treatment method, or a material of the treated surfaces at the time when the CMP treatment is performed. This case is also described with the expression “the levels are the same” in this specification and the like. For example, the expression “the levels are the same” is also used to describe the case where two layers (here, a first layer and a second layer) having heights from a reference plane are provided to have a difference less than or equal to 20 nm between the top-surface level of the first layer and the top-surface level of the second layer.

Note that in this specification and the like, the expression “end portions are aligned” means that outlines of stacked layers at least partly overlap with each other in a plan view. For example, the case of processing an upper layer and a lower layer with the use of the same mask pattern or mask patterns that are partly the same is included. Note that in some cases, the outlines do not exactly overlap with each other and the outline of the upper layer is located inward from the outline of the lower layer or the outline of the upper layer is located outward from the outline of the lower layer; such a case is also represented by the expression “end portions are aligned”.

Thus, in general, it is difficult to clearly differentiate “perfectly the same” from “substantially the same”. Therefore, in this specification and the like, the expression “the same” includes both “perfectly the same” and “substantially the same”.

Note that in this specification and the like, “normally-on characteristics” means a state where a channel is formed without application of a voltage to a gate and a current flows through a transistor. Furthermore, “normally-off characteristics” mean a state where a current does not flow through a transistor when a potential is not applied to a gate or a ground potential is applied to the gate.

In this specification and the like, leakage current sometimes expresses the same meaning as off-state current. Furthermore, in this specification and the like, the off-state current sometimes refers to a current that flows between a source and a drain of a transistor in an off state, for example.

### Embodiment 1

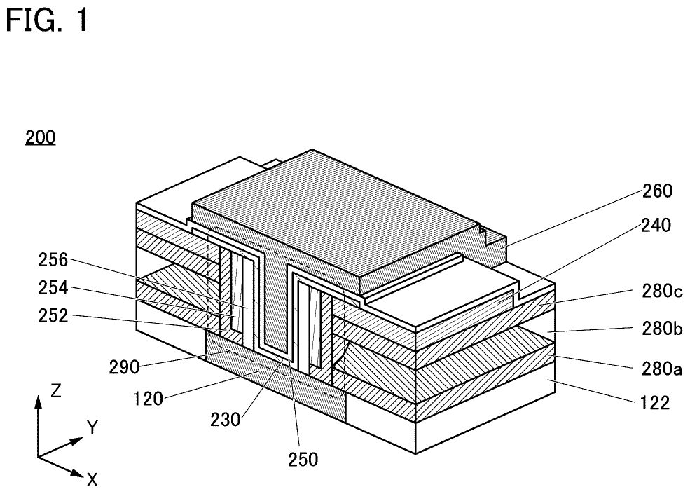

In this embodiment, an example of a semiconductor device of one embodiment of the present invention and a manufacturing method thereof are described with reference to FIG. 1 to FIG. 27. In addition, an example of a memory device including the semiconductor device is described.

### Structure Example of Semiconductor Device

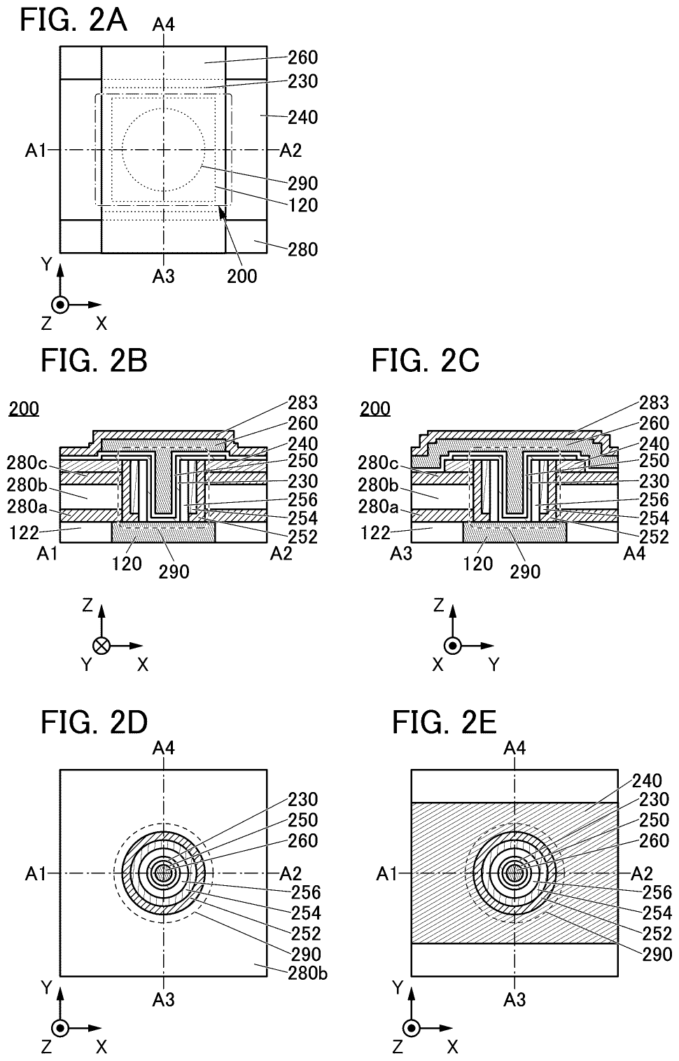

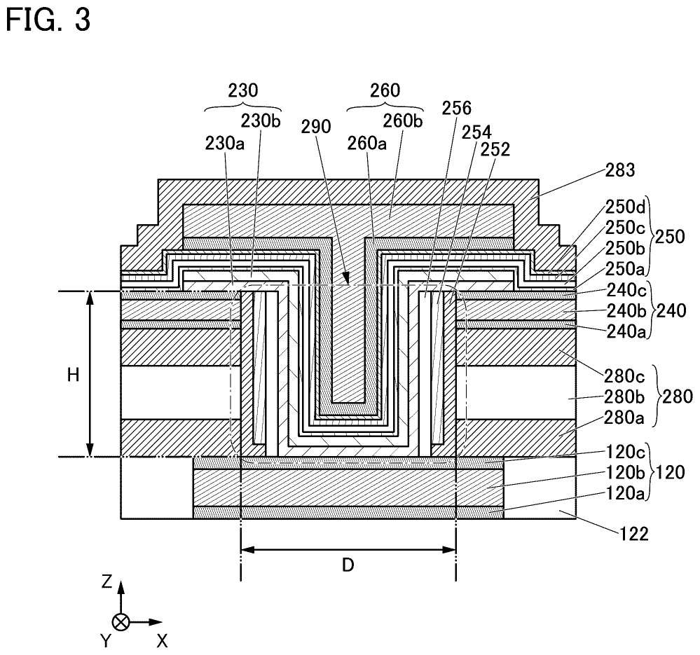

A structure of a semiconductor device including a transistor 200 is described with reference to FIG. 1 to FIG. 3. FIG. 1 is a perspective view of the semiconductor device. FIG. 2A to FIG. 2E are a plan view and cross-sectional views of the semiconductor device. FIG. 2A is a plan view of the semiconductor device. FIG. 2B and FIG. 2C are cross-sectional views of the semiconductor device. Here, FIG. 2B is a cross-sectional view of a portion indicated by the dashed-dotted line A1-A2 in FIG. 2A. FIG. 2C is a cross-sectional view of a portion indicated by the dashed-dotted line A3-A4 in FIG. 2A. FIG. 2D is a cross-sectional view of a layer including an insulator 280b along the XY plane. FIG. 2E is a cross-sectional view of a layer including a conductor 240 along the XY plane. FIG. 3 is an enlarged view corresponding to FIG. 2B. Note that for clarity of the drawing, some components are omitted or illustrated transparently in the perspective view of FIG. 1 and the plan view of FIG. 2A.

Note that in the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. Specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

The semiconductor device illustrated in FIG. 1 and FIG. 2A to FIG. 2C includes an insulator 122 over a substrate (not illustrated), an insulator 280 (including an insulator 280a, the insulator 280b, and an insulator 280c) over the insulator 122, the transistor 200 partly embedded in an opening portion 290 formed in the insulator 280, and an insulator 283 over the transistor 200. The insulator 122, the insulator 280, and the insulator 283 each function as an interlayer film.

The transistor 200 includes a conductor 120 formed to be embedded in the insulator 122, the conductor 240 over the insulator 280, an oxide semiconductor 230, an insulator 250 over the oxide semiconductor 230, and a conductor 260 over the insulator 250. The oxide semiconductor 230 functions as a semiconductor layer, the conductor 260 functions as a gate electrode, the insulator 250 functions as a gate insulator, the conductor 120 functions as one of a source electrode and a drain electrode, and the conductor 240 functions as the other of the source electrode and the drain electrode.

As illustrated in FIG. 2B and FIG. 2C, the opening portion 290 reaching the conductor 120 is formed in the insulator 280 and the conductor 240. At least part of the components of the transistor 200 is placed in the opening portion 290. Here, the bottom portion of the opening portion 290 is the top surface of the conductor 120, and the sidewall of the opening portion 290 is the side surface of the insulator 280 and the side surface of the conductor 240. Note that the sidewall of the opening portion 290 is preferably perpendicular to the top surface of the conductor 120. At this time, the opening portion 290 has a cylindrical shape. With the structure, the semiconductor device can be miniaturized or highly integrated.

At least part of the oxide semiconductor 230 is placed in the opening portion 290. Here, the oxide semiconductor 230 includes a region in contact with the top surface of the conductor 120 in the opening portion 290 and a region in contact with at least part of the top surface of the conductor 240 over the opening portion 290. The insulator 250 provided in contact with the top surface of the oxide semiconductor 230 is placed so as to be at least partly positioned in the opening portion 290. The conductor 260 provided in contact with the top surface of the insulator 250 is placed so as to be at least partly positioned in the opening portion 290. In addition, at least part of the conductor 260 is preferably provided to fill the opening portion 290 as illustrated in FIG. 2B and FIG. 2C.

Furthermore, an insulator 254 is placed between the sidewall of the opening portion 290 and the oxide semiconductor 230, an insulator 252 is placed between the sidewall of the opening portion 290 and the insulator 254, and an insulator 256 is placed between the insulator 254 and the oxide semiconductor 230 so that these insulators can be positioned in the opening portion 290.

The insulator 252 is in contact with the side surface of the insulator 280, the side surface of the conductor 240, the bottom surface of the oxide semiconductor 230 positioned above the conductor 240, the side surface and the lower end portion of the insulator 254, the side surface of the insulator 256, and the top surface of the conductor 120. As illustrated in FIG. 2B and FIG. 2C, a protruding portion is formed in a portion of the insulator 252 that is in contact with the top surface of the conductor 120 in a cross-sectional view. The end portion of the protruding portion of the insulator 252 is in contact with the insulator 256. The protruding portion of the insulator 252 extends toward the center of the opening portion 290 beyond the other portion of the insulator 252. That is, in a cross-sectional view in a direction perpendicular to the Z axis (which can also be referred to as a direction perpendicular to the channel length direction), the insulator 252 has what is called an L shape (including a laterally-inverted L shape).

The insulator 252 preferably has a barrier property against hydrogen, and particularly preferably has high capability of inhibiting diffusion of hydrogen. For the insulator 252, silicon nitride or the like can be used, for example. For the insulator having a barrier property against hydrogen, the insulators described in the section of [Insulator] can be referred to. By providing the insulator 252 with such a property, diffusion of an excess amount of hydrogen into the insulator 254, the insulator 256, and the oxide semiconductor 230 from the outside of the transistor 200 can be inhibited.

The insulator 254 is in contact with the top surface of the protruding portion of the insulator 252 and the side surface of the insulator 252, the bottom surface of the oxide semiconductor 230 positioned above the conductor 240, and the side surface of the insulator 256. As illustrated in FIG. 2B and FIG. 2C, the side surface of the insulator 254 is sometimes aligned with the side end portion of the protruding portion of the insulator 252 in the cross-sectional view.

The insulator 254 preferably has a barrier property against hydrogen, and is particularly preferably has high capability of capturing or fixing (also referred to as gettering) hydrogen. For the insulator 254, a metal oxide such as hafnium oxide can be used, for example. For the insulator having a barrier property against hydrogen, the insulators described in the section of [Insulator] can be referred to. By providing the insulator 254 with such a property, hydrogen contained in the oxide semiconductor 230 and the insulator 256 in contact with the oxide semiconductor 230 can be captured or fixed by the insulator 254.

The insulator 256 is in contact with the side surface of the protruding portion of the insulator 252, the side surface of the insulator 254, the bottom surface and the side surface of the oxide semiconductor 230, and the top surface of the conductor 120. The insulator 256 is preferably an insulator containing oxygen. For example, silicon oxide can be used for the insulator 256. Note that for the insulator containing oxygen, the insulators containing oxygen among the insulators described in the section of [Insulator] can be referred to. When the insulator 256 containing oxygen is formed in contact with the oxide semiconductor 230, release of oxygen from the oxide semiconductor 230 can be inhibited and formation of oxygen vacancies (hereinafter, sometimes referred to as Vo) and defects in which hydrogen enters the oxygen vacancies (hereinafter, sometimes referred to as VoH) can be inhibited. When an insulator containing oxygen that is released by heating (hereinafter, sometimes referred to as excess oxygen) is used as the insulator 256, oxygen can be supplied to the oxide semiconductor 230.

FIG. 2A is a plan view selectively illustrating the conductor 120, the oxide semiconductor 230, the conductor 240, the conductor 260, and the opening portion 290. Note that the opening portion 290 provided in the insulator 280 is indicated by dashed lines. As illustrated in FIG. 2A, the conductor 240 includes the opening portion 290 in a region overlapping with the conductor 120.

Portions of the insulator 252, the insulator 254, the insulator 256, the oxide semiconductor 230, the insulator 250, and the conductor 260 that are placed in the opening portion 290 reflect the shape of the opening portion 290. Thus, the insulator 252 is provided to cover the sidewall of the opening portion 290, the insulator 254 is provided in contact with the inner side surface of the insulator 252, the insulator 256 is provided in contact with the inner side surface of the insulator 254, the oxide semiconductor 230 is provided to cover the bottom portion of the opening portion 290 and the inner side surface of the insulator 256, the insulator 250 is provided to cover the oxide semiconductor 230, and the conductor 260 is provided to fill a depressed portion of the insulator 250, which reflects the shape of the opening portion 290.

Thus, when a cross-sectional structure of the layer including the insulator 280b is observed, the insulator 252, the insulator 254, the insulator 256, the oxide semiconductor 230, the insulator 250, and the conductor 260 are placed concentrically as illustrated in FIG. 2D. The same applies to a cross-sectional structure of the layer including the conductor 240 as illustrated in FIG. 2E. Although not illustrated, the same applies also to a cross-sectional structure of the layer including the insulator 280a and a cross-sectional structure of the layer including the insulator 280c.

Although this embodiment describes the example where the opening portion 290 has a circular shape in the plan view, the present invention is not limited thereto. For example, the opening portion 290 in the plan view may have a substantially circular shape such as an elliptical shape, a polygonal shape such as a quadrangular shape, or a polygonal shape such as a quadrangular shape with rounded corners.

The oxide semiconductor 230 includes a channel formation region, and a source region and a drain region that are provided to sandwich the channel formation region.

One of a source region and a drain region of the transistor 200 is a region of the oxide semiconductor 230 that is in contact with the conductor 120. The other of the source region and the drain region of the transistor 200 is a region of the oxide semiconductor 230 that is in contact with the conductor 240. As illustrated in FIG. 2A to FIG. 2E, the conductor 240 is in contact with the entire outer circumference of the oxide semiconductor 230 outside the opening portion 290.

A channel formation region of the oxide semiconductor 230 is at least part of a region between one of the source region and the drain region and the other of the source region and the drain region. In other words, the channel formation region of the transistor 200 is positioned in a region of the oxide semiconductor 230 that is between the conductor 120 and the conductor 240. It can also be said that the channel formation region of the transistor 200 is positioned in a region of the oxide semiconductor 230 that is in contact with the insulator 256 or a region in the vicinity thereof.

The channel length of the transistor 200 is a distance between the source region and the drain region. In other words, the channel length of the transistor 200 depends on the thicknesses of the insulator 280 the conductor 240 that are over the conductor 120. It can also be said that the channel length of the transistor 200 depends on the height H of the opening portion 290. In FIG. 3, the height H of the opening portion 290 is indicated by a dashed double-dotted double-headed arrow. To be exact, the channel length of the transistor 200 includes a distance from a portion of the oxide semiconductor 230 protruding from the opening portion 290 to a portion where the oxide semiconductor 230 and the conductor 240 are in contact with each other. Thus, the channel of the transistor 200 can be regarded as having an upside down L shape (including a laterally-inverted upside-down L shape) in a cross-sectional view. Note that the upside-down L shape indicates the vertically-inverted L shape.

In a conventional transistor, the channel length is determined by the light exposure limit of photolithography. However, in the present invention, the channel length can be determined by the thickness of the insulator 280. Thus, the transistor 200 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 200 can have a higher on-state current and improved frequency characteristics.

In addition, as described above, the channel formation region, the source region, and the drain region can be formed in the opening portion 290 and the vicinity thereof. Thus, the occupation area of the transistor 200 can be reduced as compared with a conventional transistor in which a channel formation region, a source region, and a drain region are provided separately on the XY plane. Accordingly, high integration of the semiconductor device can be achieved.

As described above, in the transistor 200, the source region and the drain region are positioned at different heights, so that a current flows through the semiconductor in the Z axis direction. In other words, the channel length direction can be regarded as having a component of the height direction (the vertical direction); accordingly, the transistor of one embodiment of the present invention can also be referred to as a VFET (Vertical Field Effect Transistor), a vertical transistor, a vertical-channel transistor, and the like. The above-described vertical transistor may be referred to as a CFET (Columnar Field Effect Transistor) because of its shape.

Furthermore, also in the XY plane including the channel formation region of the oxide semiconductor 230, the oxide semiconductor 230, the insulator 250, and the conductor 260 are provided concentrically. Thus, the side surface of the conductor 260 provided at the center faces the side surface of the oxide semiconductor 230 with the insulator 250 therebetween. That is, in the plan view, all the circumference of the oxide semiconductor 230 serves as the channel formation region. In this case, for example, the channel width of the transistor 200 is determined by the length of the outer circumference of the oxide semiconductor 230. In other words, the channel width of the transistor 200 depends on the width D of the opening portion 290. In FIG. 3, the width D of the opening portion 290 is indicated by a dashed double-dotted double-headed arrow. By increasing the width D of the opening portion 290, the channel width per unit area can be increased and the on-state current can be increased. Thus, the width D of the opening portion 290 is preferably larger than the height H of the opening portion 290, further preferably larger than or equal to twice the height H of the opening portion 290. This structure enables a transistor with favorable electrical characteristics and high reliability.

Here, the width D of the opening portion 290 is calculated as appropriate in accordance with the shape of the uppermost portion of the opening portion 290. For example, in the case where the opening portion 290 is quadrangular in the plan view, the width D of the opening portion 290 is preferably a length of the diagonal line of the uppermost portion of the opening portion 290.

In the case where the opening portion 290 is formed to be circular in a plan view, the oxide semiconductor 230, the insulator 250, and the conductor 260 are formed concentrically. This makes the distance between the conductor 260 and the oxide semiconductor 230 substantially uniform, so that a gate electric field can be substantially uniformly applied to the oxide semiconductor 230.

It is preferable that the channel formation region of the transistor including oxide semiconductor as a semiconductor layer contain fewer oxygen vacancies or have a lower concentration of an impurity such as hydrogen, nitrogen, or a metal element than the source region and the drain region. In some cases, hydrogen in the vicinity of an oxygen vacancy forms a defect that is an oxygen vacancy into which hydrogen enters (hereinafter sometimes referred to as VoH), which generates an electron serving as a carrier. Therefore, it is preferable that VoH be also decreased in the channel formation region. Thus, the channel formation region of the transistor is a high-resistance region having a low carrier concentration. Thus, the channel formation region of the transistor can be regarded as being i-type (intrinsic) or substantially i-type.

The insulator 252, the insulator 254, and the insulator 256 are formed in the vicinity of the oxide semiconductor 230 as described above, whereby the hydrogen concentration in the channel formation region of the oxide semiconductor 230 can be reduced. Accordingly, oxygen vacancies and VoH in the oxide semiconductor 230 can be reduced, so that a semiconductor device that has favorable electrical characteristics and high reliability can be provided.

Meanwhile, the source region and the drain region of the transistor including oxide semiconductor as a semiconductor layer include more oxygen vacancies, include more VoH, or have a higher concentration of an impurity such as hydrogen, nitrogen, or a metal element than the channel formation region, and thus are low-resistance regions with high carrier concentrations. In other words, the source region and the drain region of the transistor are n-type regions that have a higher carrier concentration and a lower resistance than the channel formation region.

Although the opening portion 290 is provided such that the sidewall of the opening portion 290 is substantially perpendicular to the top surface of the conductor 120 in FIG. 2B and FIG. 2C, the present invention is not limited thereto. The sidewall of the opening portion 290 may have a tapered shape, for example.

Note that in this specification and the like, the tapered shape refers to a shape such that at least part of a side surface of a component is inclined to a substrate surface or a formation surface. For example, the tapered shape preferably includes a region where the angle between the inclined side surface and the substrate surface or the formation surface (such an angle is also referred to as a taper angle) is greater than 0° and less than 90°. Note that the side surface of the component, the substrate surface, and the formation surface are not necessarily completely flat, and may have a substantially planar shape with a small curvature or a substantially planar shape with slight unevenness.

As illustrated in FIG. 2B and FIG. 2C, part of the oxide semiconductor 230 is positioned outside the opening portion 290, that is, over the conductor 240. Note that although the oxide semiconductor 230 is divided in the X direction in FIG. 2B, the present invention is not limited thereto. For example, the oxide semiconductor 230 may be provided to extend in the X direction. Also in this case, the oxide semiconductor 230 is divided in the Y direction.

FIG. 2C illustrates a structure in which the side end portion of the oxide semiconductor 230 is positioned inward from the side end portion of the conductor 240. Note that the present invention is not limited thereto. For example, a structure may be employed in which the side end portion of the oxide semiconductor 230 and the side end portion of the conductor 240 may be substantially aligned with each other in the Y direction. Alternatively, the side end portion of the oxide semiconductor 230 may be positioned outward from the side end portion of the conductor 240.

The metal oxide functioning as the oxide semiconductor 230 preferably has a band gap of 2 eV or higher, further preferably 2.5 eV or higher. With the use of a metal oxide having a wide band gap as the oxide semiconductor 230, the off-state current of the transistor can be reduced. Using the transistor having a low off-state current in the memory cell enables long-period retention of stored contents. In other words, such a semiconductor device does not require refresh operation or has extremely low frequency of the refresh operation, which leads to a sufficient reduction in power consumption of the semiconductor device. The frequency of refresh operation in a general DRAM is approximately once per 60 msec, whereas the frequency of refresh operation in the semiconductor device of one embodiment of the present invention can be approximately once per 10 sec, which is greater than or equal to 10 times or greater than or equal to 100 times that of the general DRAM. In the semiconductor device of one embodiment of the present invention, the frequency of refresh operation can be once per period of 1 sec to 100 sec, both inclusive, preferably once per period of 5 sec to 50 sec, both inclusive.

As the oxide semiconductor 230, a single layer or stacked layers including any of the metal oxides described in a later-described section [Metal oxide] can be used.

As the oxide semiconductor 230, specifically, a metal oxide with a composition of In:M:Zn=1:3:2 [atomic ratio] or in the neighborhood thereof, a metal oxide with a composition of In:M:Zn=1:3:4 [atomic ratio] or in the neighborhood thereof, a metal oxide with a composition of In:M:Zn=1:1:0.5 [atomic ratio] or in the neighborhood thereof, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a metal oxide with a composition of In:M:Zn=1:1:2 [atomic ratio] or in the neighborhood thereof, or a metal oxide with a composition of In:M:Zn=4:2:3 [atomic ratio] or in the neighborhood thereof may be used. Note that a composition in the neighborhood includes the range of ±30% of an intended atomic ratio. Gallium is preferably used as the element M.

When the metal oxide is deposited by a sputtering method, the above atomic ratio is not limited to the atomic ratio of the deposited metal oxide and may be the atomic ratio of a sputtering target used for depositing the metal oxide.

As an analysis method of the composition of a metal oxide used for the oxide semiconductor 230, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used.

Alternatively, some of the analysis methods may be performed in combination. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an atomic layer deposition (ALD) method can be suitably used for forming a film of the metal oxide. In the case where the metal oxide is deposited by a sputtering method, the composition of the deposited metal oxide may be different from the composition of a sputtering target. In particular, the content percentage of zinc in the deposited metal oxide may be reduced to approximately 50% of that of the sputtering target.

The oxide semiconductor 230 preferably has crystallinity. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. As the oxide semiconductor 230, the CAAC-OS or the nc-OS is preferably used, and the CAAC-OS is particularly preferably used.

CAAC-OS preferably includes a plurality of layered crystal regions and a c-axis is preferably aligned in a normal direction of a surface where the CAAC-OS is formed. For example, the oxide semiconductor 230 preferably includes a layered crystal that is substantially parallel to the side surface of the insulator 256. With this structure, the layered crystals of the oxide semiconductor 230 are formed substantially in parallel with the channel length direction of the transistor 200, so that the on-state current of the transistor can be increased.

The CAAC-OS is a metal oxide having a dense structure with high crystallinity and a small number of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as CAAC-OS, is used as the oxide semiconductor 230, oxygen extraction from the oxide semiconductor 230 by the source electrode or the drain electrode can be inhibited. This can inhibit oxygen extraction from the oxide semiconductor 230 even when heat treatment is performed; thus, the transistor 200 is stable with respect to high temperatures in a manufacturing process (what is called thermal budget).

The crystallinity of the oxide semiconductor 230 can be analyzed with X-ray diffraction (XRD), a transmission electron microscope (TEM), or electron diffraction (ED), for example. Alternatively, some of the analysis methods may be performed in combination.

Although a single layer of the oxide semiconductor 230 is illustrated in FIG. 2B and FIG. 2C, the present invention is not limited thereto. The oxide semiconductor 230 may have a stacked-layer structure of a plurality of oxide layers with different chemical compositions. For example, a structure in which a plurality of kinds of metal oxides selected from the metal oxides described in the above-described section [Metal oxide] are stacked as appropriate may be used.

For example, as illustrated in FIG. 3, the oxide semiconductor 230 may have a stacked-layer structure of an oxide semiconductor 230a and an oxide semiconductor 230b over the oxide semiconductor 230a.

The conductivity of a material used for the oxide semiconductor 230a is preferably different from the conductivity of a material used for the oxide semiconductor 230b.

For example, a material having higher conductivity than a material for the oxide semiconductor 230b can be used for the oxide semiconductor 230a. The use of the material having high conductivity for the oxide semiconductor 230a, which is in contact with the conductor 120 and the conductor 240 functioning as the source electrode and the drain electrode, can reduce the contact resistance between the oxide semiconductor 230 and the conductor 120 and the contact resistance between the oxide semiconductor 230 and the conductor 240, and thus the transistor can have high on-state current.

Here, in the case where a material having high conductivity is used for the oxide semiconductor 230b provided on the side of the conductor 260 functioning as the gate electrode, the threshold voltage of the transistor is shifted and a drain current flowing when the gate voltage is 0 V (hereinafter also referred to as cutoff current) becomes large in some cases. Specifically, the threshold voltage may be low when the transistor 200 is an n-channel transistor. Thus, a material having lower conductivity than a material for the oxide semiconductor 230a is preferably used for the oxide semiconductor 230b. Accordingly, the transistor 200 can have high threshold voltage in the case where the transistor 200 is an n-channel transistor, in which case the transistor 200 can have low cut-off current. Note that the low cut-off current is sometimes referred to as normally-off.

When the oxide semiconductor 230 has a stacked-layer structure and the material having higher conductivity than the material for the oxide semiconductor 230b is used for the oxide semiconductor 230a as described above, the transistor can have normally-off characteristics and high on-state current. Consequently, the semiconductor device can have both low power consumption and high performance.

The carrier concentration of the oxide semiconductor 230a is preferably higher than the carrier concentration of the oxide semiconductor 230b. Increasing the carrier concentration of the oxide semiconductor 230a results in higher conductivity thereof, which can reduce the contact resistance between the oxide semiconductor 230 and the conductor 120 and the contact resistance between the oxide semiconductor 230 and the conductor 240, and thus the transistor can have high on-state current. When the carrier concentration of the oxide semiconductor 230b is reduced, the conductivity is reduced, and thus the transistor can have normally-off characteristics.

Although the example in which a material having higher conductivity than a material for the oxide semiconductor 230b is used for the oxide semiconductor 230a is described here, one embodiment of the present invention is not limited to the example. A material having lower conductivity than a material for the oxide semiconductor 230b may be used for the oxide semiconductor 230a. The carrier concentration of the oxide semiconductor 230a can be lower than that of the oxide semiconductor 230b.

The band gap of the first metal oxide used for the oxide semiconductor 230a and the band gap of the second metal oxide used for the oxide semiconductor 230b are preferably different from each other. For example, the difference between the band gap of the first metal oxide and the band gap of the second metal oxide is preferably greater than or equal to 0.1 eV, further preferably greater than or equal to 0.2 eV, still further preferably greater than or equal to 0.3 eV.

The band gap of the first metal oxide used for the oxide semiconductor 230a can be smaller than the band gap of the second metal oxide used for the oxide semiconductor 230b. Thus, the contact resistance between the oxide semiconductor 230 and the conductor 120 and the contact resistance between the oxide semiconductor 230 and the conductor 240 can be reduced, and thus the transistor can have high on-state current. Furthermore, the transistor 200 can have high threshold voltage in the case where the transistor is an n-channel transistor; accordingly, the transistor 200 can be a normally-off transistor.

Although the example in which the band gap of the first metal oxide is smaller than that of the second metal oxide is described here, one embodiment of the present invention is not limited to the example. The band gap of the first metal oxide can be larger than that of the second metal oxide.

As described above, the band gap of the first metal oxide used for the oxide semiconductor 230a can be smaller than the band gap of the second metal oxide used for the oxide semiconductor 230b. The composition of the first metal oxide is preferably different from that of the second metal oxide. When the compositions of the first metal oxide and the second metal oxide are different from each other, the band gap can be controlled. For example, the content percentage of the element M in the first metal oxide is preferably lower than that of the element M in the second metal oxide. Specifically, in the case where the first metal oxide and the second metal oxide are each an In-M-Zn oxide, the first metal oxide can have an atomic ratio of In:M:Zn=1:1:1 or a composition in the neighborhood thereof, and the second metal oxide can have an atomic ratio of In:M:Zn=1:3:2 or a composition in the neighborhood thereof. It is particularly preferable to use one or more of gallium, aluminum, and tin as the element M.

The first metal oxide may have a composition not including the element M. For example, the first metal oxide used for the oxide semiconductor 230a can be an In—Zn oxide, and the second metal oxide used for the oxide semiconductor 230b can be an In-M-Zn oxide. Specifically, the first metal oxide can be an In—Zn oxide, and the second metal oxide can be an In—Ga—Zn oxide. More specifically, the first metal oxide can have an atomic ratio of In:Zn=1:1 or a composition in the neighborhood thereof or an atomic ratio of In:Zn=4:1 or a composition in the neighborhood thereof and the second metal oxide can have an atomic ratio of In:Ga:Zn=1:1:1 or a composition in the neighborhood thereof.

Although the example in which the content percentage of the element M in the first metal oxide is lower than that of the element M in the second metal oxide is described here, one embodiment of the present invention is not limited to the example. The content percentage of the element M in the first metal oxide may be higher than that of the element M in the second metal oxide. As long as the compositions of the first metal oxide and the second metal oxide are different from each other, the content percentages of elements other than the element M may be different from each other.

The film thickness of the oxide semiconductor 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

The thicknesses of the layers included in the oxide semiconductor 230 (here, the oxide semiconductor 230a and the oxide semiconductor 230b) are determined in such a manner that the thickness of the oxide semiconductor 230 is within the above-described range. The thickness of the oxide semiconductor 230a can be determined in such a manner that the contact resistance between the oxide semiconductor 230a and the conductor 120 and the contact resistance between the oxide semiconductor 230a and the conductor 240 are within required ranges. The thickness of the oxide semiconductor 230b can be determined in such a manner that the threshold voltage of the transistor is within a required range. Note that the thickness of the oxide semiconductor 230a may be the same as or different from the thickness of the oxide semiconductor 230b.

The oxide semiconductor 230a and the oxide semiconductor 230b differ in the ratio between the thickness of a portion formed over the top surface of the conductor 240 and the thickness of a portion formed along the side surface of the conductor 240 and the side surface of the insulator 280 in some cases.

Although FIG. 3 illustrates the structure in which the oxide semiconductor 230 has a stacked-layer structure of two layers, the oxide semiconductor 230a and the oxide semiconductor 230b, the present invention is not limited to the structure. The oxide semiconductor 230 may have a stacked-layer structure of three or more layers.

In the case where the oxide semiconductor 230 has a three-layer structure, the oxide semiconductor 230 may have a structure in which a metal oxide with a composition of In:Ga:Zn=1:1:1 [atomic ratio] or in the neighborhood thereof, a metal oxide with a composition of In:Zn=1:1 [atomic ratio] or in the neighborhood thereof or with a composition of In:Zn=4:1 [atomic ratio] or in the neighborhood thereof, and a metal oxide with a composition of In:Ga:Zn=1:1:1 [atomic ratio] or in the neighborhood thereof are provided in order from the conductor 120 side. With this structure, the on-state current of the transistor 200 can be increased, and the transistor can have high reliability with small variations.

As the insulator 250, a single layer or stacked layers of any of the insulators described in the later-described section [Insulator] can be used. For the insulator 250, silicon oxide or silicon oxynitride can be used, for example. Silicon oxide and silicon oxynitride, which are thermally stable, are preferable.

As the insulator 250, any of materials each having high relative permittivity, that is, high-k materials, described in the later-described section [Insulator] may be used. For example, hafnium oxide, aluminum oxide, or the like may be used.

The thickness of the insulator 250 is preferably greater than or equal to 0.5 nm and less than or equal to 15 nm, further preferably greater than or equal to 1 nm and less than or equal to 12 nm, still further preferably greater than or equal to 2 nm and less than or equal to 10 nm. At least part of the insulator 250 preferably has a region with the above-described thickness.

The concentration of impurities such as water and hydrogen in the insulator 250 is preferably reduced. This can inhibit entry of impurities such as water and hydrogen into the channel formation region of the oxide semiconductor 230.

As illustrated in FIG. 2B and FIG. 2C, part of the insulator 250 is positioned outside the opening portion 290, that is, over the conductor 240 and the insulator 280. In this case, the insulator 250 preferably covers the side end portions of the oxide semiconductor 230. This can prevent a short circuit between the conductor 260 and the oxide semiconductor 230. The insulator 250 preferably covers the side end portions of the conductor 240. This can prevent a short circuit between the conductor 260 and the conductor 240.

Although the insulator 250 has a single layer in FIG. 2B and FIG. 2C, the present invention is not limited thereto. The insulator 250 may have a stacked-layer structure.

For example, as illustrated in FIG. 3, the insulator 250 may have a stacked-layer structure of an insulator 250a, an insulator 250b over the insulator 250a, an insulator 250c over the insulator 250b, and an insulator 250d over the insulator 250c.

For the insulator 250b, any of materials each having low relative permittivity described in the later-described section [Insulator] is preferably used. In particular, silicon oxide and silicon oxynitride, which are thermally stable, are preferable. The insulator 250b in this case contains at least oxygen and silicon. With such a structure, parasitic capacitance between the conductor 260 and the conductor 240 can be reduced. Furthermore, the concentration of impurities such as water and hydrogen in the insulator 250b is preferably reduced.

For the insulator 250a, any of the insulators having a barrier property against oxygen described in the later-described section [Insulator] is preferably used. The insulator 250a includes a region in contact with the oxide semiconductor 230. When the insulator 250a has a barrier property against oxygen, release of oxygen from the oxide semiconductor 230 at the time of performing heat treatment or the like can be inhibited. This can inhibit formation of oxygen vacancies in the oxide semiconductor 230. Accordingly, the transistor 200 can have favorable electrical characteristics and higher reliability. As the insulator 250a, aluminum oxide is preferably used, for instance. In this case, the insulator 250a contains at least oxygen and aluminum.

The insulator 250c preferably has a barrier property against hydrogen, and particularly preferably has high capability of capturing or fixing hydrogen. That is, for the insulator 250d, an insulating material similar to the insulator 254, e.g., hafnium oxide, can be used. Thus, hydrogen contained in the oxide semiconductor 230 can be captured or fixed more effectively. Thus, the hydrogen concentration in the oxide semiconductor 230 can be reduced. In that case, the insulator 250c contains at least oxygen and hafnium. The insulator may have an amorphous structure.

The insulator 250d preferably has a barrier property against hydrogen, and particularly preferably has high capability of inhibiting diffusion of hydrogen. In other words, an insulating material similar to the insulator 252, e.g., silicon nitride, can be used for the insulator 250d. In that case, diffusion of impurities contained in the conductor 260 into the oxide semiconductor 230 can be inhibited. Silicon nitride is suitably used for the insulator 250d because of its high hydrogen barrier property. In this case, the insulator 250d contains at least nitrogen and silicon.

The insulator 250d may further have a barrier property against oxygen. The insulator 250d is provided between the insulator 250b and the conductor 260. Thus, diffusion of oxygen contained in the insulator 250b into the conductor 260 can be prevented, so that oxidation of the conductor 260 can be inhibited. It is also possible to inhibit a reduction in the amount of oxygen supplied to the channel formation region of the oxide semiconductor 230.

The thicknesses of the insulator 250a to the insulator 250d are preferably small for miniaturization of the transistor 200, and are preferably within the above-described ranges. Typically, the thicknesses of the insulator 250a, the insulator 250b, the insulator 250c, and the insulator 250d are 1 nm, 2 nm, 2 nm, and 1 nm, respectively. This structure enables the transistor 200 to have favorable electrical characteristics even when the transistor 200 is miniaturized or highly integrated.

Although FIG. 3 illustrates the structure in which the insulator 250 has a four-layer stacked structure of the insulator 250a to the insulator 250d, the present invention is not limited to the structure. The insulator 250 may have a stacked-layer structure of two layers, three layers, or five or more layers. In that case, the layers included in the insulator 250 are preferably selected as appropriate from the insulator 250a to the insulator 250d.

As the conductor 260, a single layer or stacked layers of any of the conductors described in the later-described section [Conductor] can be used. For example, a conductive material with high conductivity such as tungsten can be used for the conductor 260, for example.

In addition, a conductive material that is less likely to be oxidized, a conductive material having a function of inhibiting diffusion of oxygen, or the like is preferably used as the conductor 260. Examples of the conductive material include a conductive material containing nitrogen (e.g., titanium nitride or tantalum nitride) and a conductive material containing oxygen (e.g., ruthenium oxide). Alternatively, ruthenium may be used for the conductor 260. This can inhibit a decrease in the conductivity of the conductor 260.

Although FIG. 2B and FIG. 2C illustrates the conductor 260 having the single-layer structure, the present invention is not limited thereto. The conductor 260 may have a stacked-layer structure. For example, as illustrated in FIG. 3, the conductor 260 may have a stacked-layer structure of a conductor 260a and a conductor 260b over the conductor 260a. In this case, titanium nitride may be used as the conductor 260a, and tungsten may be used as the conductor 260b, for example. When a layer including tungsten is provided in this manner, the conductivity of the conductor 260 can be improved and can serve well as the wiring.

Although FIG. 3 illustrates the structure in which the conductor 260 has a stacked-layer structure of two layers of the conductor 260a and the conductor 260b, the present invention is not limited thereto. The conductor 260 may have a stacked-layer structure of three or more layers. For example, in the case of employing a three-layer structure, a conductor similar to the conductor 260a may further be provided over the conductor 260b in the structure of FIG. 3.

Although the conductor 260 is provided to fill the opening portion 290 in FIG. 2B and FIG. 2C, the present invention is not limited thereto. For example, a depressed portion reflecting the shape of the opening portion 290 is formed in a center portion of the conductor 260 and part of the depressed portion is positioned in the opening portion 290 in some cases. In this case, the depressed portion may be filled with an inorganic insulating material or the like.

As illustrated in FIG. 2B and FIG. 2C, part of the conductor 260 is positioned outside the opening portion 290, that is, over the conductor 240 and the insulator 280. Although FIG. 2B illustrates the structure in which the side end portion of the conductor 260 is aligned with the side end portion of the oxide semiconductor 230, the present invention is not limited thereto. For example, the side end portion of the conductor 260 may be positioned inward from the side end portion of the oxide semiconductor 230. This can prevent a short circuit between the conductor 260 and the oxide semiconductor 230. Note that the side end portion of the conductor 260 may be positioned outward from the side end portion of the oxide semiconductor 230.

As the conductor 240, a single layer or stacked layers of any of conductors described in the later-described section [Conductor] can be used. Moreover, a conductive material with high conductivity such as tungsten can be used for the conductor 240, for example.

A conductive material that is less likely to be oxidized, a conductive material having a function of inhibiting diffusion of oxygen, or the like is preferably used for the conductor 240 like the conductor 260. Examples of the conductive material include a conductive material containing nitrogen (e.g., titanium nitride or tantalum nitride) and a conductive material containing oxygen (e.g., ruthenium oxide, indium tin oxide to which silicon is added, and the like). Alternatively, ruthenium may be used for the conductor 260. Such a structure can reduce excessive oxidation of the conductor 240 due to the oxide semiconductor 230 and the like. This can inhibit a decrease in the conductivity of the conductor 240.

Although the conductor 240 has a single layer in FIG. 2B and FIG. 2C, the present invention is not limited thereto. The conductor 240 may have a stacked-layer structure. For example, as illustrated in FIG. 3, the conductor 240 may have a stacked-layer structure of a conductor 240a, a conductor 240b over the conductor 240a, and a conductor 240c over the conductor 240b. In this case, titanium nitride may be used for the conductor 240a and the conductor 240c and tungsten may be used for the conductor 240b, for example. When a layer including tungsten is provided in this manner, the conductor 240 can have improved conductivity and can serve well as a wiring.

Although FIG. 3 illustrates the structure in which the conductor 240 has a stacked-layer structure of three layers of the conductor 240a to the conductor 240c, the present invention is not limited thereto. The conductor 240 may have a stacked-layer structure of two layers or four or more layers. For example, in the case of employing a two-layer structure, only the conductor 240b and the conductor 240c may be used in the structure in FIG. 3. In that case, titanium nitride can be used for the conductor 240c and tungsten can be used for the conductor 240b, as in the above description. Alternatively, indium tin oxide to which silicon is added can be used for the conductor 240b, and ruthenium can be used for the conductor 240c.

Although FIG. 2B and FIG. 2C illustrate the structure in which a region of the insulator 250 that does not overlap with the conductor 240 includes a region in contact with the top surface of the insulator 280, the present invention is not limited thereto. For example, a structure may be employed in which the conductor 240 is provided to be embedded in an insulator provided over the insulator 280 and the insulator 250 is not in contact with the insulator 280. In that case, the top surface of the conductor 240 is preferably level with the top surface of the insulator. With such a structure, the physical distance from the conductor 260 to the conductor 240 (specifically, the side end portion of the conductor 240) can be increased, so that a short circuit between the conductor 260 and the conductor 240 can be prevented.

Note that the oxide semiconductor 230 and the conductor 240 are in contact with each other, whereby a low-resistance region is formed in the oxide semiconductor 230. Thus, the contact resistance between the oxide semiconductor 230 and the conductor 240 can be reduced.

As illustrated in FIG. 2B and FIG. 2C, the insulator 280 preferably has a stacked-layer structure of the insulator 280a, the insulator 280b over the insulator 280a, and the insulator 280c over the insulator 280b. Note that the present invention is not limited thereto. For example, the insulator 280 can have a single-layer structure of only the insulator 280b or a single-layer structure of only the insulator 280c.

The insulator 280b functions as an interlayer film and thus preferably has low relative permittivity. When a material with low relative permittivity is used for an interlayer film, parasitic capacitance generated between wirings can be reduced. As the insulator 280b, a single layer or stacked layers of any of insulators each including a material with low relative permittivity described in the later-described section of [Insulator] can be used. Silicon oxide and silicon oxynitride are preferable because they are thermally stable. The insulator 280b in this case contains at least oxygen and silicon. Note that a film of TEOS (Tetra-Ethyl-Ortho-Silicate, the chemical formula: Si(OC₂H₅)₄), formed by a plasma CVD method can be used for the insulator 280b. Thus, the productivity can be improved. Note that even in the case where a kind of a film in which the concentration of impurities (e.g., the concentration of hydrogen) is high is used for the insulator 280b, the insulator 280b is surrounded by the insulator 280a, the insulator 280c, and the insulator 252 in one embodiment of the present invention. Accordingly, even in the case where the concentration of impurities in the film of the insulator 280b is high, impurities (e.g., hydrogen) in the film are not diffused to the outside or are less likely to be diffused to the outside, thereby a highly reliable semiconductor device can be obtained.

The concentration of impurities such as water and hydrogen in the insulator 280b is preferably reduced. This can inhibit entry of impurities such as water and hydrogen into the channel formation region of the oxide semiconductor 230.

The insulator 280b is preferably formed by a film formation method such as a sputtering method or a plasma-enhanced chemical vapor deposition (PECVD) method. In particular, a film is formed by a sputtering method as a film formation method that does not use a hydrogen gas as a film formation gas, so that a film with an extremely low hydrogen content can be formed. Thus, supply of hydrogen to the oxide semiconductor 230 is inhibited and the electrical characteristics of the transistor 200 can be stabilized.

The insulator 280a and the insulator 280c each preferably have a barrier property against hydrogen and each particularly preferably have high capability of inhibiting diffusion of hydrogen. In other words, an insulating material similar to the insulator 252, e.g., silicon nitride, can be used for each of the insulator 280a and the insulator 280c. In this case, the insulator 280a and the insulator 280c each contain at least nitrogen and silicon. Thus, hydrogen can be inhibited from being diffused from the outside of the transistor to the oxide semiconductor 230 through the insulator 280a or the insulator 280c. A silicon nitride film releases fewer impurities (e.g., water and hydrogen) and is less likely to transmit oxygen and hydrogen, and thus can be suitably used for each of the insulator 280a and the insulator 280c. For the insulator 280a and the insulator 280c, the same material or different materials may be used.

Also, the insulator 280a and the insulator 280c each preferably have a barrier property against oxygen. Providing the insulator 280a between the insulator 280b and the conductor 120 can inhibit the conductor 120 from being oxidized by oxygen contained in the insulator 280b and having high resistance. Furthermore, providing the insulator 280c between the insulator 280b and the conductor 240 can inhibit the conductor 240 from being oxidized by oxygen contained in the insulator 280b and having high resistance.

A region of the oxide semiconductor 230 that is in contact with the insulator 280c is supplied with a smaller amount of oxygen than a region of the oxide semiconductor 230 that is in contact with the insulator 256. Thus, the region of the oxide semiconductor 230 that is in contact with the insulator 280c has a low resistance in some cases. That is, the low-resistance regions functioning as the source region and the drain region can each be formed relatively easily in a region of the oxide semiconductor 230 that is in contact with the insulator 280c and in the vicinity of the region.

The thickness of the insulator 280a is preferably smaller than the thickness of the insulator 280b. The thickness of the insulator 280c is preferably smaller than the thickness of the insulator 280b. The thicknesses of the insulator 280a and the insulator 280c are each preferably greater than or equal to 1 nm and less than or equal to 15 nm, further preferably greater than or equal to 2 nm and less than or equal to 10 nm, still further preferably greater than or equal to 3 nm and less than or equal to 7 nm, yet still further preferably greater than or equal to 3 nm and less than or equal to 5 nm. The thickness of the insulator 280b is preferably greater than or equal to 3 nm and less than or equal to 30 nm, further preferably greater than or equal to 5 nm and less than or equal to 20 nm, still further preferably greater than or equal to 7 nm and less than or equal to 15 nm.

Although the thickness of the insulator 280c and the thickness of the insulator 280a are substantially equal to each other in FIG. 2B and FIG. 2C, the present invention is not limited thereto. For example, the thickness of the insulator 280c may be smaller than the thickness of the insulator 280a. Alternatively, the thickness of the insulator 280a may be smaller than the thickness of the insulator 280c, for example.

Although FIG. 2B and FIG. 2C illustrate the structure in which the insulator 280c is provided over the planarized insulator 280b, the present invention is not limited to the structure. For example, the insulator 280c may be formed without performing planarization treatment on the insulator 280b. By not performing planarization treatment, manufacturing cost can be reduced and production yield can be increased. The insulator 280a, the insulator 280b, and the insulator 280c can be successively formed without exposure to the air. By the formation without exposure to the air, impurities or moisture from the atmospheric environment can be prevented from being attached onto the insulator 280a to the insulator 280c, so that the vicinity of the interface between the insulator 280a and the insulator 280b and the vicinity of the interface between the insulator 280b and the insulator 280c can be kept clean.

The insulator 283 preferably has a barrier property against hydrogen, and particularly preferably has high capability of inhibiting diffusion of hydrogen. In other words, an insulating material similar to the insulator 252, e.g., silicon nitride, can be used for the insulator 283. In that case, the insulator 283 contains at least nitrogen and silicon. Thus, hydrogen can be inhibited from being diffused from the outside of the transistor to the oxide semiconductor 230. A silicon nitride film and a silicon nitride oxide film can be suitably used for the insulator 283 because the silicon nitride film and the silicon nitride oxide film release fewer impurities (e.g., water and hydrogen) and are less likely to transmit oxygen and hydrogen.

The insulator 283 may further have a barrier property against oxygen. The insulator 283 is provided on and in contact with the conductor 260. Accordingly, oxidation of the conductor 260 can be inhibited.

As the conductor 120, a single layer or stacked layers of any of conductors described in the later-described section [Conductor] can be used. Moreover, a conductive material with high conductivity such as tungsten can be used for the conductor 120, for example.

A conductive material that is less likely to be oxidized, a conductive material having a function of inhibiting diffusion of oxygen, or the like is preferably used for the conductor 120, like the conductor 260. Examples of the conductive material include a conductive material containing nitrogen (e.g., titanium nitride or tantalum nitride) and a conductive material containing oxygen (e.g., ruthenium oxide or indium tin oxide to which silicon is added). Alternatively, ruthenium may be used for the conductor 120. Such a structure can reduce excessive oxidation of the conductor 240 due to the oxide semiconductor 230 or the like. This can inhibit a decrease in the conductivity of the conductor 120.

Note that although the conductor 120 has a single layer in FIG. 2B and FIG. 2C, the present invention is not limited thereto. The conductor 120 may have a stacked-layer structure. For example, as illustrated in FIG. 3, the conductor 120 may have a stacked-layer structure of a conductor 120a, a conductor 120b over the conductor 120a, and a conductor 120c over the conductor 120b. In this case, titanium nitride may be used as the conductor 120a and the conductor 120c, and tungsten may be used as the conductor 120b, for example. When a layer including tungsten is provided in this manner, the conductivity of the conductor 120 can be improved.

Although FIG. 3 illustrates the structure in which the conductor 120 has a stacked-layer structure of three layers of the conductor 120a to the conductor 120c, the present invention is not limited thereto. The conductor 120 may have a stacked-layer structure of two layers or four or more layers. For example, in the case of employing a two-layer structure, only the conductor 120b and the conductor 120c may be used in the structure in FIG. 3. For example, in the structure in FIG. 3, only the conductor 120a and the conductor 120b may be used.

Here, when the oxide semiconductor 230 and the conductor 120 are in contact with each other, a metal compound or oxygen vacancies are formed, whereby the low-resistance region can be formed in the oxide semiconductor 230. Thus, the contact resistance between the oxide semiconductor 230 and the conductor 120 can be reduced.

Note that although FIG. 2B and FIG. 2C illustrate the structure in which the conductor 120 is provided to have an island shape, the present invention is not limited thereto. For example, the conductor 120 can be extended in the X direction or the Y direction to be used as a wiring in accordance with the circuit design of a semiconductor device using the transistor 200.

Although FIG. 2B and FIG. 2C illustrate a structure including a region where the top surface of the conductor 120 and the bottom surface of the oxide semiconductor 230 are in contact with each other, the present invention is not limited thereto. For example, a conductor may be provided between the conductor 120 and the oxide semiconductor 230.

The insulator 122 functions as an interlayer film and thus preferably has low relative permittivity. An insulating material that can be used for the insulator 280b is used for the insulator 122.

### Modification Example of Semiconductor Device

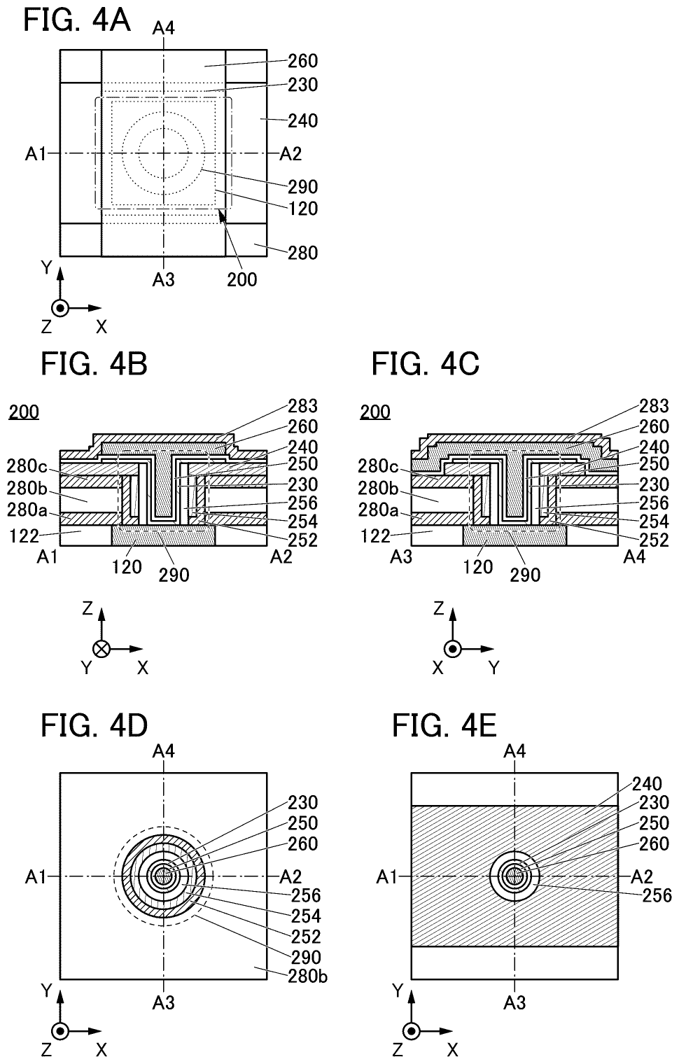

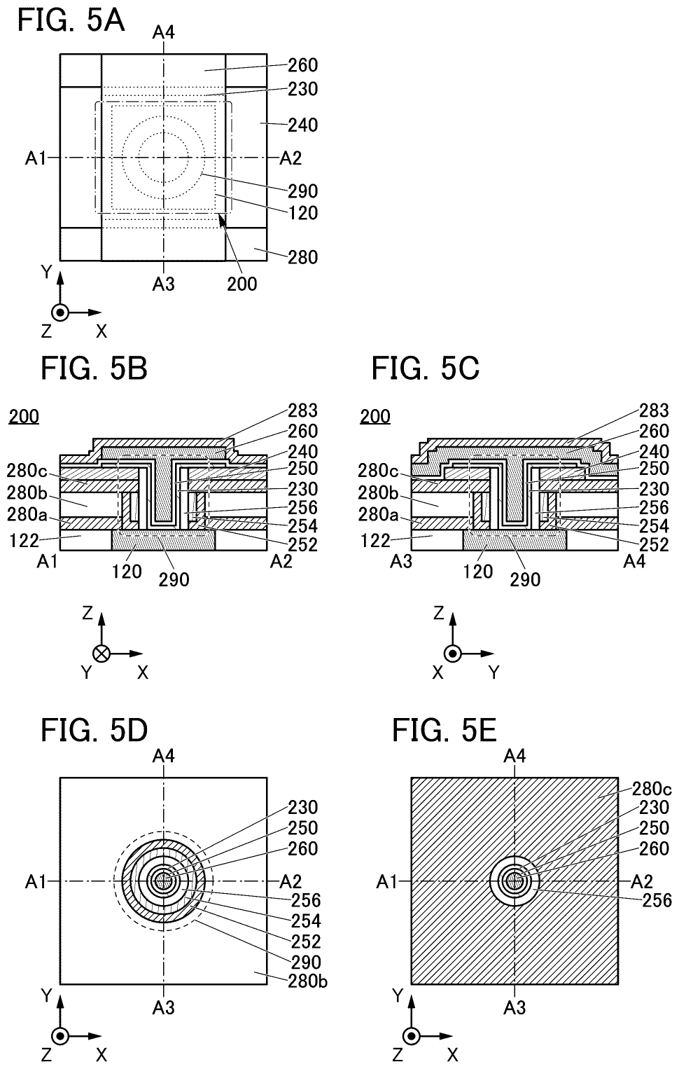

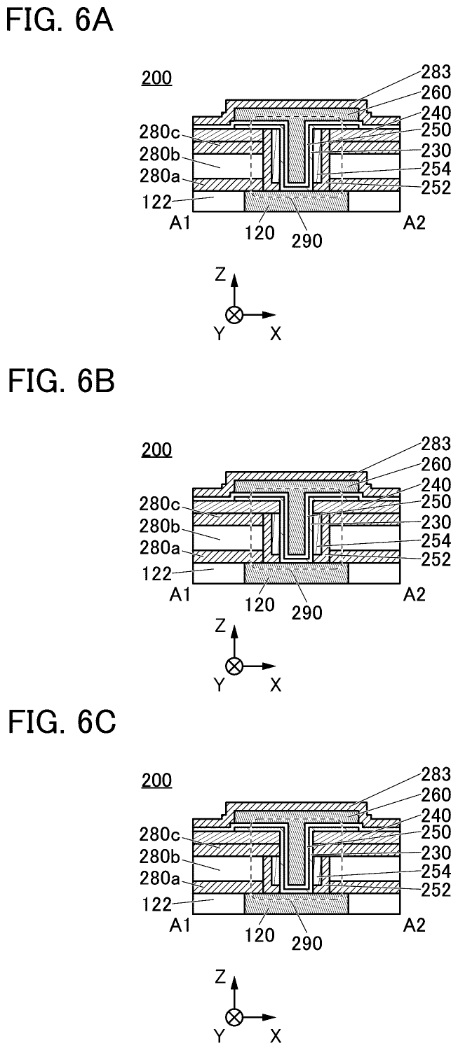

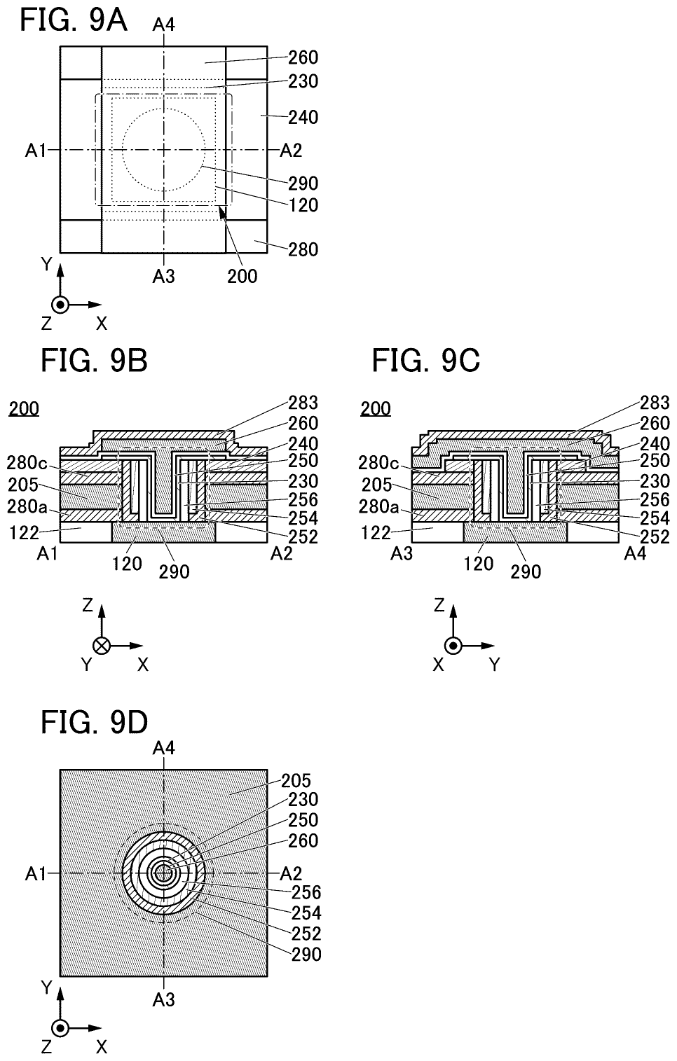

Next, modification examples of the semiconductor device including the transistor 200 is described with reference to FIG. 4 to FIG. 9. Here, FIG. 4A to FIG. 4E, FIG. 5A to FIG. 5E, and FIG. 9A to FIG. 9D are plan views and cross-sectional views of the semiconductor device corresponding to that in FIG. 2A to FIG. 2E. FIG. 9D is a cross-sectional view of the XY plane of a layer including the conductor 205. FIG. 4E is a cross-sectional view of the XY plane of a layer including the conductor 240. FIG. 5E is a cross-sectional view of the XY plane of a layer including the insulator 280c. FIG. 6A to FIG. 8E are cross-sectional views of a portion indicated by the dashed-dotted line A1-A2.

In the semiconductor device illustrated in FIG. 4 to FIG. 9, components similar to those in the semiconductor device illustrated in FIG. 2 are denoted by the same reference numerals, and the description of FIG. 1 to FIG. 3 can be referred to for the details.

Although the above structure example shows an example in which the side surface of the conductor 240 is in contact with the side surface of the insulator 252 and part of the insulator 252 and part of the insulator 254 are formed in the same layer as the conductor 240, the present invention is not limited thereto. As in the semiconductor device illustrated in FIG. 4A to FIG. 4E, part of the bottom surface of the conductor 240 can be in contact with the upper end portion of the insulator 252 and the upper end portion of the insulator 254. In this case, as illustrated in FIG. 4B and FIG. 4C, the insulator 252 and the insulator 254 are formed under the conductor 240. The side surface of the conductor 240 is in contact with the insulator 256.

Also in this modification example, as illustrated in FIG. 4D, the insulator 252, the insulator 254, the insulator 256, the oxide semiconductor 230, the insulator 250, and the conductor 260 are formed in the opening portion 290 in the layer including the insulator 280b. Meanwhile, in this modification example, as illustrated in FIG. 4E, only the oxide semiconductor 230, the insulator 250, and the conductor 260 are formed in the opening portion 290 in the layer including the conductor 240.

With the above structure, a region where the conductor 240 and the oxide semiconductor 230 are in contact with each other, i.e., the low-resistance region, is formed closer to the center portion of the opening portion 290. Thus, the channel length of the transistor 200 is reduced, so that the on-state current, the field-effect mobility, and the frequency characteristics of the semiconductor device can be improved.

Furthermore, as in the semiconductor device illustrated in FIG. 5A to FIG. 5E, the insulator 280c in addition to the conductor 240 may be formed over the insulator 252 and the insulator 254. In this case, part of the bottom surface of the insulator 280c is in contact with the upper end portion of the insulator 252 and the upper end portion of the insulator 254. The side surface of the insulator 280c is in contact with the insulator 256. As illustrated in FIG. 5E, also in a layer including the insulator 280c, only the oxide semiconductor 230, the insulator 250, and the conductor 260 are formed in the opening portion 290.

Although the above structure example illustrates an example in which the insulator 256 is provided and the insulator 254 is provided to face the oxide semiconductor 230 with the insulator 256 therebetween, the present invention is not limited thereto. As in the semiconductor device illustrated in FIG. 6A, a structure can be employed in which the insulator 256 is not provided, and the side surface of the insulator 254 and part of the insulator 252 are in contact with the oxide semiconductor 230. Thus, the step of forming the insulator 256 is omitted and the productivity of the semiconductor device can be improved.

Note that as illustrated in FIG. 6B, the semiconductor device in FIG. 4A to FIG. 4E can also have a structure in which the insulator 256 is not provided. As illustrated in FIG. 6C, the semiconductor device in FIG. 5A to FIG. 5E can also have a structure in which the insulator 256 is not provided. In the structure illustrated in FIG. 6B and FIG. 6C, the side surface of the conductor 240 is in contact with the oxide semiconductor 230, so that the area where the oxide semiconductor 230 and the conductor 240 are in contact with each other can be increased. Accordingly, the on-state current, the field-effect mobility, and the frequency characteristics of the semiconductor device can be improved.

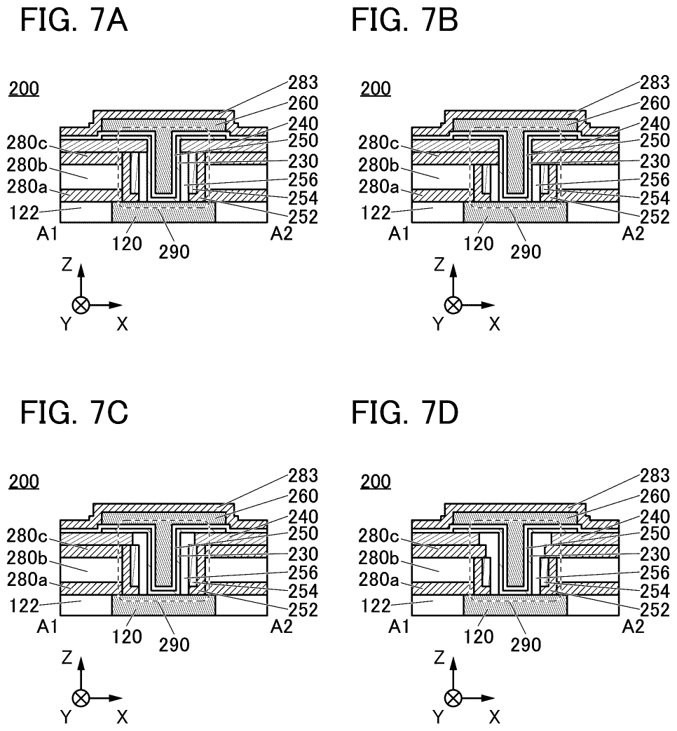

Although FIG. 4A to FIG. 4E illustrate an example of the semiconductor device in which the side surface of the conductor 240 is in contact with the side surface of the insulator 256 and part of the insulator 256 is formed in the same layer as the conductor 240, the present invention is not limited thereto. As in the semiconductor device illustrated in FIG. 7A, part of the bottom surface of the conductor 240 can be in contact with the upper end portion of the insulator 252, the upper end portion of the insulator 254, and the upper end portion of the insulator 256. In this case, as illustrated in FIG. 7A, the insulator 252, the insulator 254, and the insulator 256 are formed under the conductor 240. Here, since the side surface of the conductor 240 is in contact with the oxide semiconductor 230, the area where the oxide semiconductor 230 and the conductor 240 are in contact with each other can be increased. Accordingly, the on-state current, the field-effect mobility, and the frequency characteristics of the semiconductor device can be improved.

Furthermore, as in a semiconductor device illustrated in FIG. 7B, the insulator 280c in addition to the conductor 240 may also be formed over the insulator 256. In this case, part of the bottom surface of the insulator 280c is in contact with the upper end portion of the insulator 252, the insulator 254, and the upper end portion of the insulator 256. The side surface of the insulator 280c is in contact with the oxide semiconductor 230.

Although FIG. 4A to FIG. 4E illustrate an example of the semiconductor device in which the inner side surface of the conductor 240 (also referred to as the side surface on the conductor 260 side) is aligned with the inner side surface of the insulator 254, the present invention is not limited thereto. As in a semiconductor device illustrated in FIG. 7C, the inner side surface of the conductor 240 may be placed outward from the inner side surface of the insulator 254. In that case, part of the insulator 256 is in contact with the upper end portion of the insulator 254 in some cases.

Furthermore, as in a semiconductor device illustrated in FIG. 7D, the inner side surface of the insulator 280c may be placed outward from the inner side surface of the insulator 254. Here, the inner side surface of the conductor 240 is preferably placed outward from the inner side surface of the insulator 280c. In that case, part of the insulator 256 may be in contact with the upper end portion of the insulator 254 and the upper end portion of the insulator 280c in some cases.

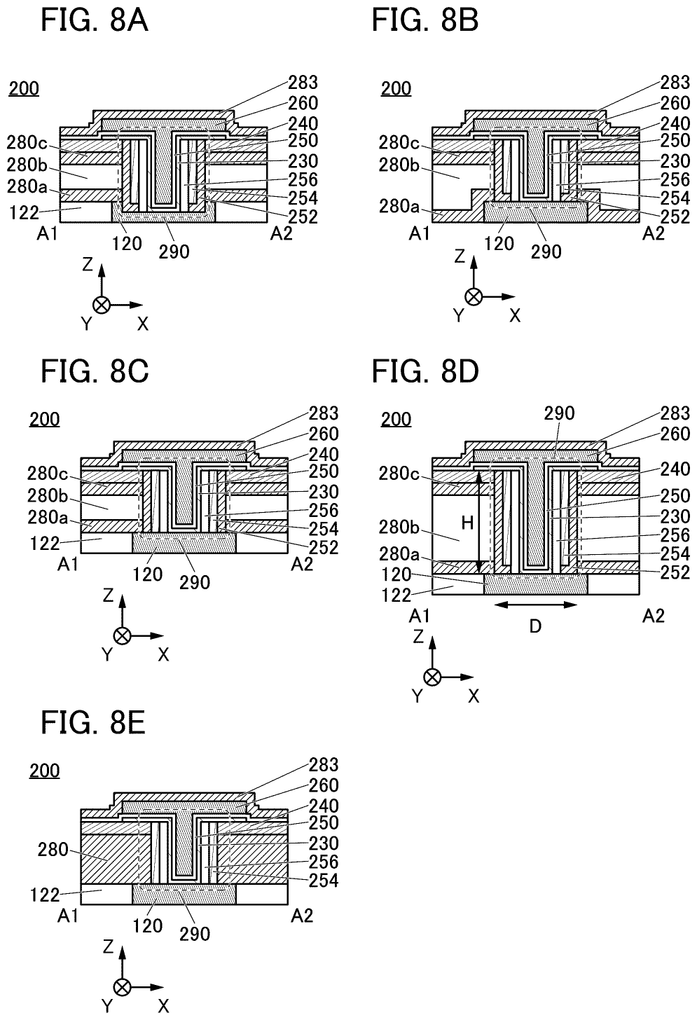

Although the above structure example illustrates an example in which the top surface of the conductor 120 is flat, the present invention is not limited to the structure. For example, as illustrated in FIG. 8A, a depressed portion overlapping with the opening portion 290 may be formed over the conductor 120. At least parts of the insulator 252, the insulator 254, the insulator 256, the oxide semiconductor 230, the insulator 250, and the conductor 260 are formed to fill the depressed portion. When the oxide semiconductor 230, the insulator 250, and the conductor 260 are formed in the depressed portion, the gate electric field of the conductor 260 can be easily applied to a portion of the oxide semiconductor 230 close to the conductor 120.

Although the conductor 120 is embedded in the insulator 122 in the above structure example, the present invention is not limited thereto. For example, as illustrated in FIG. 8B, the insulator 280a may be provided to cover the conductor 120. In this case, the insulator 280a is in contact with part of the top surface and the side surface of the conductor. Thus, the step of forming the insulator 122 is omitted and the productivity of the semiconductor device can be improved.

Although the above structure example illustrates an example in which the insulator 252 has an L shape in a cross-sectional view, the present invention is not limited thereto. For example, as illustrated in FIG. 8C, a structure may be employed in which the insulator 252 and the insulator 254 do not overlap with each other. In this case, the lower end portion of the insulator 254 is in contact with the top surface of the conductor 120. The insulator 252 is not in contact with the insulator 256.

Although the above structure example illustrates an example in which the width D of the opening portion 290 is larger than the height H of the opening portion 290 in the cross-sectional view, the present invention is not limited thereto. For example, as illustrated in FIG. 8D, the width D of the opening portion 290 may be smaller than the height H of the opening portion 290. The width D and the height H of the opening portion 290 can be set as appropriate in consideration of the electrical characteristics required for the transistor 200.

Although the above structure example illustrates an example in which the insulator 280 has a three-layer structure of the insulator 280a to the insulator 280c, the present invention is not limited thereto. For example, the insulator 280 can have a single-layer structure as illustrated in FIG. 8E. Here, for the insulator 280, an insulating material that can be used for the insulator 280a and the insulator 280c and has high capability of inhibiting diffusion of hydrogen (e.g., silicon nitride) is preferably used. With such a structure, hydrogen can be inhibited from being diffused from the outside of the transistor to the oxide semiconductor 230 through the insulator 280.

Although the above structure example illustrates an example in which the transistor 200 has a single-gate structure, the present invention is not limited thereto. For example, as illustrated in FIG. 9A to FIG. 9D, the conductor 205 functioning as a second gate (also referred to as a back gate) may be provided between the insulator 280a and the insulator 280c.

The conductor 205 is provided in contact with the top surface of the insulator 280a, the bottom surface of the insulator 280c, and the side surface of the insulator 254. The conductive material that can be used for the conductor 260 can be used for the conductor 205. Here, as illustrated in FIG. 9D, in a cross section including the conductor 205, the opening portion 290 is formed in the conductor 205, and the insulator 252, the insulator 254, the insulator 256, the oxide semiconductor 230, the insulator 250, and the conductor 260 are provided concentrically in the opening portion 290.

The conductor 205 functions as a second gate electrode, and the insulator 252, the insulator 254, and the insulator 256 function as a second gate insulating layer. A fixed potential or a given signal can be supplied to the conductor 205. For example, by changing a potential applied to the conductor 205 not in conjunction with but independently of a potential applied to the conductor 260, the threshold voltage (Vₜₕ) of the transistor 200 can be controlled. In particular, by applying a negative potential to the conductor 205, Vₜₕ of the transistor 200 can be higher, and its off-state current can be reduced. Without limitation to the above, the conductor 205 can be electrically connected to any one of the conductor 260, the conductor 240, and the conductor 120.

Although FIG. 9B, FIG. 9C, and FIG. 9D illustrate a structure in which the conductor 205 is provided to have a planar shape, without limitation to this structure, the conductor 205 can be provided to extend in the X direction or the Y direction. An insulator similar to the insulator 280b may be provided between the conductor 205 and the insulator 280a and/or between the conductor 205 and the insulator 280c.

Note that the structures illustrated in FIG. 8A to FIG. 8E and FIG. 9A to FIG. 9D can also be used for the semiconductor device in FIG. 4A to FIG. 4E and the semiconductor device in FIG. 5A to FIG. 5E.

### <Component Material of Memory Device>

Component materials that can be used for the semiconductor device and the memory device are described below.

### [Substrate]

As a substrate where the transistor 200 and the capacitor 100 are formed, an insulator substrate, a semiconductor substrate, or a conductor substrate may be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate in which an insulator region is included in the semiconductor substrate described above, e.g., an SOI (Silicon On Insulator) substrate.

Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a memory element.

### [Insulator]

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as leakage current may arise because of a thinner gate insulator. When a high-k material is used for the insulator functioning as a gate insulator, the voltage at the time of the operation of the transistor can be reduced while the physical thickness is maintained. In addition, the equivalent oxide thickness (EOT) of the insulator functioning as the gate insulator can be reduced. In contrast, when a material with low relative permittivity is used for the insulator functioning as an interlayer film, parasitic capacitance generated between wirings can be reduced. Thus, a material is preferably selected in accordance with the function of the insulator. Note that the material with low relative permittivity is a material with high dielectric strength.

Examples of the material with high relative permittivity (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of an inorganic insulating material with low relative permittivity include silicon oxide to which fluorine is added, silicon oxide to which carbon is added, and silicon oxide to which carbon and nitrogen are added. Another example is porous silicon oxide. These silicon oxides may contain nitrogen.

When a transistor including a metal oxide is surrounded by an insulator having a function of inhibiting passage of oxygen and impurities, the transistor can have stable electrical characteristics. As the insulator having a function of inhibiting passage of oxygen and impurities, a single layer or stacked layers including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of inhibiting passage of oxygen and impurities, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor layer or provided in the vicinity of the semiconductor layer, such as a gate insulator, preferably includes a region containing excess oxygen. For example, when an insulator including a region containing excess oxygen is in contact with a semiconductor layer or provided in the vicinity of the semiconductor layer, oxygen vacancies in the semiconductor layer can be reduced. Examples of an insulator in which a region containing excess oxygen is easily formed include silicon oxide, silicon oxynitride, and porous silicon oxide.

Examples of an insulator having a barrier property against oxygen include an oxide containing one or both of aluminum and hafnium, an oxide containing hafnium and silicon (hafnium silicate), magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of an insulator having a barrier property against hydrogen include aluminum oxide, magnesium oxide, hafnium oxide, gallium oxide, indium gallium zinc oxide, silicon nitride, and silicon nitride oxide.

An insulator having a barrier property against oxygen and an insulator having a barrier property against hydrogen can each be regarded as an insulator having a barrier property against one or both of oxygen and hydrogen.

Examples of the insulator having a function of capturing or fixing hydrogen include an oxide containing magnesium and an oxide containing one or both of aluminum and hafnium. These oxides preferably have an amorphous structure. In such an oxide having an amorphous structure, an oxygen atom has a dangling bond and sometimes has a property of capturing or fixing hydrogen with the dangling bond. Note that such a metal oxide preferably has an amorphous structure, but may include a crystal region that is partly formed.

Examples of the insulator having high capability of inhibiting diffusion of hydrogen include silicon nitride and silicon nitride oxide.

In this specification and the like, a barrier insulating film refers to an insulating film having a barrier property. In addition, the barrier property refers to a property that does not easily allow diffusion of a target substance (also referred to as a property that does not easily allow passage of a target substance, a property with low permeability to a target substance, or a function of inhibiting diffusion of a target substance). Moreover, a function of capturing or fixing (also referred to as gettering) a target substance can be rephrased as a barrier property. In addition, hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule. Specifically, a barrier property against oxygen refers to a property that does not easily allow diffusion of at least one of an oxygen atom, an oxygen molecule, and the like.

### [Conductor]

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having high electrical conductivity, typified by polycrystalline silicon containing an impurity element such as phosphorus, or silicide such as nickel silicide may also be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive film formed using the conductive material containing oxygen may be referred to as an oxide conductive film.

In addition, a conductive material containing tungsten, copper, or aluminum as its main component is preferable because it has high conductivity.

A stack of a plurality of conductive layers formed of the above-described materials may be used. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where a metal oxide is used for the channel formation region of the transistor, the conductor functioning as the gate electrode preferably has a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### [Metal Oxide]

A metal oxide sometimes includes a lattice defect. Examples of a lattice defect include point defects such as an atomic vacancy and an exotic atom, a line defect such as dislocation, a plane defect such as a crystal grain boundary, and a volume defect such as a void. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects in a semiconductor layer of a transistor may cause unstable electrical characteristics of the transistor. Hence, a metal oxide used in a semiconductor layer of a transistor preferably has a small number of lattice defects.

A transistor using a metal oxide is likely to change its electrical characteristics especially in the case where oxygen vacancies (Vo) and impurities are present in a region of the metal oxide where a channel is formed, which may degrade the reliability in some cases. In some cases, a defect (hereinafter sometimes referred to as VoH) that is an oxygen vacancy into which hydrogen in the vicinity of the oxygen vacancy has entered is formed, which generates an electron serving as a carrier. Thus, when the channel formation region in the metal oxide includes oxygen vacancies, the transistor is likely to have normally-on characteristics. Therefore, oxygen vacancies and impurities are preferably reduced as much as possible in the channel formation region in the metal oxide. In other words, it is preferable that the region of the metal oxide where a channel is formed have a reduced carrier concentration and be of an i-type (intrinsic) or substantially i-type.

The kind of a lattice defect that is likely to be present in a metal oxide and the number of lattice defects that are present there vary depending on the structure of the metal oxide, a method for depositing the metal oxide, or the like.

The structure of a metal oxide is classified into a single crystal structure and other structures (non-single-crystal structures). Examples of non-single-crystal structures include a CAAC structure, a polycrystalline structure, an nc structure, an amorphous-like (a-like) structure, and an amorphous structure. The a-like structure has a structure between the nc structure and the amorphous structure. Note that the classification of crystal structures will be described later.

A metal oxide having an a-like structure and a metal oxide having an amorphous structure each include a void or a low-density region. That is, the metal oxide having the a-like structure and the metal oxide having the amorphous structure have low crystallinity as compared with a metal oxide having the nc structure and a metal oxide having the CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Thus, a metal oxide with high crystallinity is preferably used in a semiconductor layer of a transistor. For example, it is preferable to use the metal oxide having the CAAC structure or the metal oxide having the single crystal structure. The use of such a metal oxide for a transistor enables the transistor to have favorable electrical characteristics. In addition, a transistor with high reliability can be achieved.

For the channel formation region of a transistor, a metal oxide that increases the on-state current of the transistor is preferably used. To increase the on-state current of the transistor, the mobility of the metal oxide used for the transistor is increased. To increase the mobility of the metal oxide, the transfer of carriers (electrons in the case of an n-channel transistor) needs to be facilitated or scattering factors that affect the carrier transfer need to be reduced. The carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor and a CAAC-OS (c-axis aligned crystalline oxide semiconductor).

The c-axis of the above crystal is preferably aligned in the normal direction with respect to the surface over which the metal oxide is formed or the film surface of the metal oxide. This enables the plurality of layers to be placed parallel or substantially parallel to the surface over which the metal oxide is formed or the film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal are a YbFe₂O₄ type structure, a Yb₂Fe₃O₇ type structure, their deformed structures, and the like.

Preferably, each of the first layer to the third layer is composed of one metal element or a plurality of metal elements with the same valence and oxygen. The valences of the one or plurality of metal elements included in the first layer are preferably equal to the valences of the one or plurality of metal elements included in the second layer. The first layer and the second layer may include the same metal element. The valences of the one or plurality of metal elements included in the first layer are preferably different from the valences of the one or plurality of metal elements included in the third layer.

The above structure can increase the crystallinity of the metal oxide, which leads to an increase in the mobility of the metal oxide. Thus, the use of the metal oxide for the channel formation region of the transistor increases the on-state current of the transistor, leading to an improvement in the electrical characteristics of the transistor.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three elements selected from indium, an element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. When the element M included in the metal oxide is gallium, the metal oxide in one embodiment of the present invention preferably includes one or more selected from indium, gallium, and zinc. In this specification and the like, a metal element and a metalloid element may be collectively referred to as a “metal element”, and a “metal element” in this specification and the like may include a metalloid element.

For example, for the metal oxide semiconductor of one embodiment of the present invention, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO) can be used. Alternatively, indium tin oxide containing silicon, gallium tin oxide (Ga—Sn oxide), aluminum tin oxide (Al—Sn oxide), or the like can be used.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers. Alternatively, the metal oxide may contain, in addition to indium, one or more kinds of metal elements with large period numbers. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Incidentally, lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the proportion of the number of atoms of the element M in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

By increasing the proportion of the number of In atoms in the total number of atoms of all the metal elements contained in the metal oxide, a high on-state current and high frequency characteristics of the transistor can be achieved.

In the description of this embodiment, In—Ga—Zn oxide is sometimes taken as an example of the metal oxide.

For the formation of a metal oxide having the layered crystal structure, atomic layers are preferably deposited one by one. Since an ALD method is employed as the formation method of a metal oxide in one embodiment of the present invention, a metal oxide having the layered crystal structure is easily formed.

Examples of an ALD method include a thermal ALD method, in which a precursor and a reactant react with each other only by a thermal energy, and a plasma ALD (PEALD: Plasma Enhanced ALD) method, in which a reactant excited by plasma is used.

An ALD method, which enables atomic layers to be deposited one by one, has advantages such as deposition of an extremely thin film, deposition on a component with a high aspect ratio, deposition of a film with a small number of defects such as pinholes, deposition with excellent coverage, and low-temperature deposition. The use of plasma in a PEALD method is sometimes preferable because it enables deposition at a lower temperature. Note that a precursor used in an ALD method sometimes contains an element such as carbon or chlorine. Thus, in some cases, a film provided by an ALD method contains a larger amount of an element such as carbon or chlorine than a film provided by another formation method. Note that these elements can be quantified by XPS or SIMS. The formation method of a metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike a formation method in which particles ejected from a target or the like are deposited, an ALD method is a formation method in which a film is formed by reaction at a surface of an object. Thus, an ALD method is a formation method that enables favorable step coverage almost regardless of the shape of an object to be processed. In particular, an ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another formation method with a high deposition rate, such as a sputtering method or a CVD method, in some cases. A method in which a sputtering method is used to deposit a first metal oxide and an ALD method is used to deposit a second metal oxide over the first metal oxide is given as an example. For example, in the case where the first metal oxide has a crystal part, crystal growth occurs in the second metal oxide with the use of the crystal part as a nucleus.

When an ALD method is employed, the composition of a film to be formed can be controlled with the amount of introduced source gases. For example, a film with an arbitrary composition can be deposited by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film having a continuously-changed composition can be deposited. In the case where the film is deposited while the source gas is changed, as compared to the case where a film is deposited using a plurality of deposition chambers, the time taken for the deposition can be shortened because the time taken for transfer and pressure adjustment is omitted. Thus, the productivity of the semiconductor device can be increased in some cases.

### [Transistor Including Metal Oxide]

Next, the case where a metal oxide (oxide semiconductor) is used for a transistor will be described. Hereinafter, a transistor with a semiconductor layer of an oxide semiconductor is sometimes referred to as an OS transistor, and a transistor with a semiconductor layer of silicon is sometimes referred to as a Si transistor.

When a metal oxide (oxide semiconductor) of one embodiment of the present invention is used for a transistor, a transistor with high field-effect mobility can be achieved. In addition, a transistor with high reliability can be achieved. Furthermore, a miniaturized or highly integrated transistor can be achieved. For example, a transistor with a channel length of 2 nm to 30 nm, both inclusive, can be manufactured.

An oxide semiconductor having a low carrier concentration is preferably used for a channel formation region of a transistor. For example, the carrier concentration in an oxide semiconductor in the channel formation region is lower than or equal to 1×10¹⁸ cm⁻³, preferably lower than or equal to 1×10¹⁷ cm⁻³, further preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and sometimes behaves like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, carbon, and nitrogen. Note that an impurity in an oxide semiconductor refers to, for example, an element other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. For this reason, it is difficult to miniaturize the Si transistor. One factor that causes the short-channel effect is a small band gap of silicon. By contrast, the OS transistor includes an oxide semiconductor that is a semiconductor material having a wide band gap, and thus can suppress the short-channel effect. In other words, the OS transistor is a transistor in which the short-channel effect does not appear or hardly appears.

Note that the short-channel effect refers to degradation of electrical characteristics which becomes apparent along with miniaturization of a transistor (a decrease in channel length). Specific examples of the short-channel effect include a decrease in threshold voltage, an increase in subthreshold swing value (sometimes also referred to as S value), and an increase in leakage current. Here, the S value means the amount of change in gate voltage in the subthreshold region by which the drain current is changed by one order of magnitude at a constant drain voltage.

The characteristic length is widely used as an indicator of resistance to the short-channel effect. The characteristic length is an indicator of curving of potential in a channel formation region. When the characteristic length is shorter, the potential rises more sharply, which means that the resistance to the short-channel effect is high.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to the short-channel effect than the Si transistor. That is, in the case where a transistor with a short channel length is to be manufactured, the OS transistor is preferable to the Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region may decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source and drain regions become n⁺-type regions.

An OS transistor having the above structure enables favorable electrical characteristics even when the semiconductor device is miniaturized or highly integrated. For example, favorable electrical characteristics can be obtained even when the OS transistor has a channel length or a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Therefore, the OS transistor can be suitably used as a transistor having a short channel length as compared with the Si transistor. Note that the gate length refers to the length of a gate electrode in a direction in which carriers move inside a channel formation region during an operation of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz in a room temperature environment, for example.

The above comparison of the OS transistor with the Si transistor demonstrates that the OS transistor is advantageous over the Si transistor in that the off-state current is low and a short-channel transistor can be formed.

### [Impurity in Metal Oxide]

Here, the influence of each impurity in the metal oxide (oxide semiconductor) will be described.

When silicon or carbon, which is one of Group 14 elements, is contained in the oxide semiconductor, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. When nitrogen is contained in the oxide semiconductor, trap states are sometimes formed. This might make the electrical characteristics of the transistor unstable. Therefore, the concentration of nitrogen in the channel formation region in the oxide semiconductor, which is obtained by SIMS, is set lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor that is obtained by SIMS is set lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the channel formation region of the oxide semiconductor that is obtained by SIMS is set lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, stable electrical characteristics can be given.

### [Other Semiconductor Materials]

The oxide semiconductor 230 can be rephrased as a semiconductor layer including a channel formation region of the transistor. A semiconductor material that can be used for the semiconductor layer is not limited to the above metal oxides. The semiconductor material that has a band gap (a semiconductor material that is not a zero-gap semiconductor) may be used for the semiconductor layer. For example, a single element semiconductor, a compound semiconductor, or a layered substance (also referred to as an atomic layer substance, a two-dimensional material, or the like) is preferably used as a semiconductor material.

Here, in this specification and the like, the layered substance generally refers to a group of materials having a layered crystal structure. In the layered crystal structure, layers formed by covalent bonding or ionic bonding are stacked with bonding such as the van der Waals force, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. As silicon that can be used for the semiconductor layer, single crystal silicon, polycrystalline silicon, microcrystalline silicon, and amorphous silicon can be given. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered material contains carbon, nitrogen, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For the semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a semiconductor device with a high on-state current to be provided.

### Example 1 of Method for Manufacturing Semiconductor Device

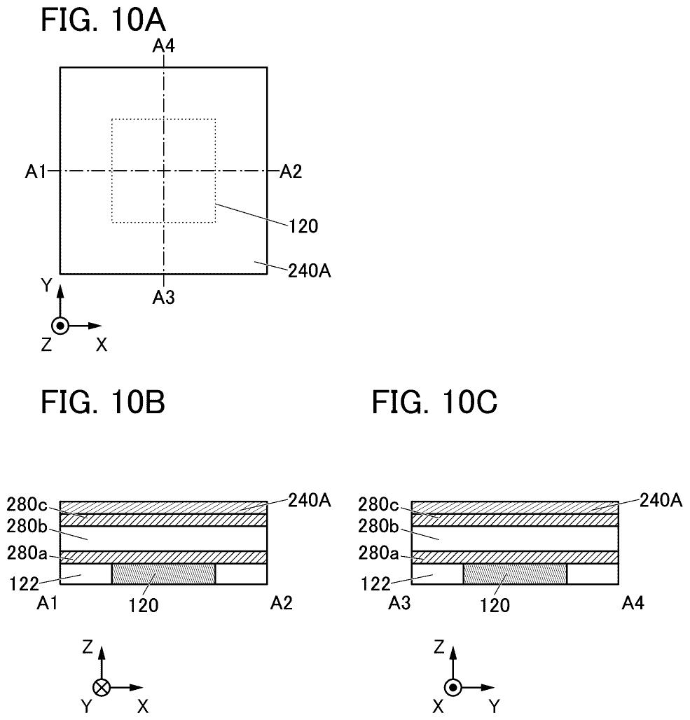

Next, a method for manufacturing the memory device of one embodiment of the present invention illustrated in FIG. 2A to FIG. 2E and the like is described with reference to FIG. 10 to FIG. 19C.

Note that A of each drawing is a plan view. Moreover, B of each drawing is a cross-sectional view corresponding to a portion indicated by the dashed-dotted line A1-A2 in A of each drawing. Furthermore, C of each drawing is a cross-sectional view corresponding to a portion indicated by the dashed-dotted line A3-A4 in A of each drawing. Note that for the sake of clarity of the drawing, some components are omitted in the plan view of A of each drawing.

Hereinafter, a film of an insulating material for forming an insulator, a film of a conductive material for forming a conductor, or a film of a semiconductor material for forming a semiconductor can be formed by a sputtering method, a chemical vapor deposition (CVD) method, a molecular beam epitaxy (MBE) method, a pulsed laser deposition (PLD) method, an ALD method, or the like as appropriate.

Examples of a sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. An RF sputtering method is mainly used in the case where an insulating film is formed, and a DC sputtering method is mainly used in the case where a metal conductive film is formed. A pulsed DC sputtering method is mainly used in the case where a film of a compound such as an oxide, a nitride, or a carbide is formed by a reactive sputtering method.

In addition, CVD methods can be classified into a plasma CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method depending on a source gas to be used.

A high-quality film can be obtained at a relatively low temperature by a plasma CVD method. Furthermore, a thermal CVD method is a film formation method that does not use plasma and thus enables less plasma damage to an object. For example, a wiring, an electrode, an element (a transistor, a capacitor, or the like), or the like included in a semiconductor device may be charged up by receiving charge from plasma. In that case, accumulated charge may break the wiring, the electrode, the element, or the like included in the semiconductor device. In contrast, such plasma damage is not caused in the case of a thermal CVD method, which does not use plasma, and thus the yield of the semiconductor device can be increased. In addition, a thermal CVD method does not cause plasma damage during film formation, so that a film with few defects can be obtained.

As an ALD method, a thermal ALD method, in which a precursor and a reactant react with each other only by a thermal energy, a PEALD method, in which a reactant excited by plasma is used, or the like can be used.

A CVD method and an ALD method are different from a sputtering method in which particles ejected from a target or the like are deposited. Thus, a CVD method and an ALD method are film formation methods that enable favorable step coverage almost regardless of the shape of an object. In particular, an ALD method enables excellent step coverage and excellent thickness uniformity and thus is suitable for covering a surface of an opening portion with a high aspect ratio, for example. On the other hand, an ALD method has a relatively low film formation rate, and thus is preferably used in combination with another film formation method with a high film formation rate, such as a CVD method, in some cases.

By a CVD method, a film with an arbitrary composition can be formed depending on the flow rate ratio of the source gases. For example, by a CVD method, a film whose composition is continuously changed can be formed by changing the flow rate ratio of the source gases during film formation. In the case where the film is formed while the flow rate ratio of the source gases is changed, as compared with the case where the film is formed using a plurality of film formation chambers, the time taken for the film formation can be shortened because the time taken for transfer or pressure adjustment is not required. Thus, the productivity of the semiconductor device can be increased in some cases.

By an ALD method, a film with an arbitrary composition can be formed by introducing different kinds of precursors. For example, in the case where different kinds of precursors are introduced, a film with an arbitrary composition can be formed by controlling the number of cycles for each of the precursors.

In the case where a plurality of different kinds of precursors are introduced in an ALD method, the kind of oxidizer may be changed depending on the precursors. For example, in the case where at least a first precursor and a second precursor are introduced, ozone (O₃) may be used as an oxidizer for the first precursor and oxygen (O₂) may be used as an oxidizer for the second precursor.

In addition, heat treatment may be performed before formation of a film. This heat treatment may be performed under reduced pressure, and the film may be successively formed without exposure to the air. Such treatment can remove moisture and hydrogen adsorbed onto the surface over which the film is to be formed, and further can reduce the moisture concentration and the hydrogen concentration in a structural element that serves as the surface over which the film is to be formed. The heat treatment temperature is preferably higher than or equal to 100° C. and lower than or equal to 400° C.

First, a substrate (not illustrated) is prepared, and the insulator 122 is formed over the substrate (see FIG. 10A to FIG. 10C). The insulator 122 can be formed by a sputtering method, a CVD method, an MBE method, a PLD method, an ALD method, or the like as appropriate. A silicon oxide film may be formed as the insulator 122 by a sputtering method, for example.

Next, an opening portion is formed in the insulator 122, and the conductor 120 is formed to be embedded in the opening portion (see FIG. 10A to FIG. 10C). The conductor 120 can be formed in the following manner: a conductive film is formed to be embedded in the opening portion, and the conductive film is subjected to chemical mechanical polishing (CMP) treatment until the insulator 122 is exposed. The conductive film may be formed by a sputtering method, a CVD method, an MBE method, a PLD method, an ALD method, or the like as appropriate. For example, a stacked film in which titanium nitride, tungsten, and titanium nitride are deposited in this order by a CVD method may be used as the conductive film.

Note that the conductor 120 is not necessarily formed to be embedded in the conductor 120. In that case, the transistor 200 illustrated in FIG. 8B can be formed by forming the insulator 280a to cover the conductor 120.

Next, the insulator 280a to the insulator 280c are formed over the insulator 122 and the conductor 120 (see FIG. 10A to FIG. 10C). Any of the above-described insulating materials can be used as appropriate for the insulator 280a to the insulator 280c. The insulator 280a to the insulator 280c can be formed by a sputtering method, a CVD method, an MBE method, a PLD method, an ALD method, or the like as appropriate. For the insulator 280a and the insulator 280c, a silicon nitride film may be formed by a sputtering method, for example. For the insulator 280b, a silicon oxide film may be formed by a sputtering method, for example. The top surface of the deposited insulator 280 is preferably planarized by CMP treatment. The planarization treatment for the insulator 280 enables favorable formation of the conductor 240 functioning as a wiring.

The CMP treatment may be skipped in some cases. In that case, the top surface of the insulator 280 has an upward-convex curved top surface shape. By not performing planarization treatment, manufacturing cost can be reduced and production yield can be increased.

Note that planarization treatment is not always performed after the insulator 280a to the insulator 280c are formed. For example, planarization treatment may be performed after the insulator 280a and the insulator 280b are formed, and then the insulator 280c may be formed.

By using a sputtering method that does not necessarily use a molecule containing hydrogen as a deposition gas for the insulator 280a to the insulator 280c, the hydrogen concentration in the insulator 280a to the insulator 280c can be reduced. When the insulator 280a to the insulator 280c are formed in this manner, diffusion of hydrogen from the insulators 280a to 280c into the oxide semiconductor 230 can be reduced, and oxygen vacancies and VoH in the channel formation region can be reduced.

Note that the insulator 280 does not necessarily have a stacked-layer structure. For example, the insulator 280 may be formed of a single layer of silicon nitride. In that case, the transistor 200 illustrated in FIG. 8E can be formed.

Next, a conductive film 240A is formed over the insulator 280c (see FIG. 10A to FIG. 10C). Any of the above-described conductive materials can be used for the conductive film 240A as appropriate. The conductive film 240A can be deposited by a sputtering method, a CVD method, an MBE method, a PLD method, an ALD method, or the like as appropriate. For example, a stacked film in which titanium nitride, tungsten and titanium nitride are deposited in this order by a CVD method may be used as the conductive film 240A. Alternatively, for example, a stacked film of a indium tin oxide film to which silicon is added deposited by a sputtering method and a ruthenium film deposited thereover by an ALD method may be used as the conductive film 240A.

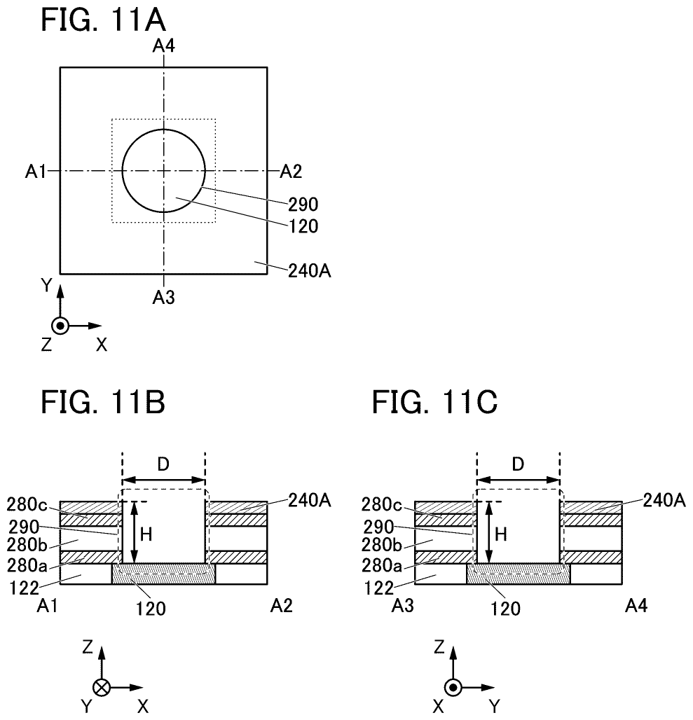

Then, part of the conductive film 240A and parts of the insulator 280a to the insulator 280c are processed to form the opening portion 290 reaching the conductor 120 (see FIG. 11A to FIG. 11C). The opening portion 290 may be formed by a lithography method. The opening portion 290 in FIG. 11A has a circular shape in the plan view; however, the shape is not limited thereto. For example, the opening portion 290 in the plan view may have a substantially circular shape such as an elliptical shape, a polygonal shape such as a quadrangular shape, or a polygonal shape such as a quadrangular shape with rounded corners.

In the lithography method, first, a resist is exposed to light through a mask. Next, a region exposed to light is removed or left using a developing solution, so that a resist mask is formed. Then, etching process through the resist mask is conducted, whereby a conductor, a semiconductor, an insulator, or the like can be processed into a desired shape. The resist mask may be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. The resist mask can be removed by dry etching treatment such as ashing, wet etching treatment, wet etching treatment after dry etching treatment, or dry etching treatment after wet etching treatment.

In addition, a hard mask formed of an insulator or a conductor may be used under the resist mask. In the case of using a hard mask, a hard mask with a desired shape can be formed in the following manner: an insulating film or a conductive film that is the material of the hard mask is formed over the insulator 280c, a resist mask is formed thereover, and then the hard mask material is etched. The etching of the insulator 280c and the like may be performed after removing the resist mask or with the resist mask remaining. In the latter case, the resist mask sometimes disappears during the etching. The hard mask may be removed by etching after the formation of the opening portion 290. Meanwhile, the hard mask is not necessarily removed when the hard mask material does not affect later steps or can be utilized in later steps.

An SOC (Spin On Carbon) film and an SOG (Spin On Glass) film may be formed between an object to be processed or the hard mask and the resist mask. Using the SOC film and the SOG film as masks can improve the adhesion between the object to be processed or the hard mask and the resist mask, resulting in enhancement of the durability of a mask pattern. For example, the SOC film, the SOG film, and the resist mask are formed in this order over the object to be processed and lithography can be performed.

As described above, the sidewall of the opening portion 290 is preferably perpendicular to the top surface of the conductor 120. With the structure, the semiconductor device can be miniaturized or highly integrated. Not being limited to the above, the sidewall of the opening portion 290 may have a tapered shape. When the sidewall of the opening portion 290 has a tapered shape, the coverage with a later-described oxide semiconductor film to be the oxide semiconductor 230, and the like can be improved, so that defects such as voids can be reduced.

Here, as illustrated in FIG. 11A and FIG. 11B, the width D of the opening portion 290 is preferably larger than the height H of the opening portion 290, and the width D of the opening portion 290 is further preferably larger than or equal to twice the height H of the opening portion 290. The channel width of the transistor 200 depends on the width D of the opening portion 290, and the channel length of the transistor 200 depends on the height H of the opening portion 290. That is, when the width D of the opening portion 290 is increased and the height H is decreased, the channel width of the transistor 200 can be increased and the channel length can be decreased. Accordingly, the on-state current, the field-effect mobility, and the frequency characteristics of the semiconductor device can be improved. Note that the height H of the opening portion 290 is the sum of the thickness of the insulator 280a to the insulator 280c and the thickness of the conductive film 240A; thus, the thickness of the insulator 280a to the insulator 280c and the thickness of the conductive film 240A may be set in accordance with the height H of the opening portion 290.

In addition, the width D of the opening portion 290 (the maximum diameter in the case where the opening portion 290 is circular in the plan view) is preferably small. For example, the maximum width of the opening portion 290 is preferably less than or equal to 60 nm, less than or equal to 50 nm, less than or equal to 40 nm, less than or equal to 30 nm, or less than or equal to 20 nm and greater than or equal to 1 nm or greater than or equal to 5 nm. In order to process the opening portion 290 to have a small width D, a lithography method using an electron beam or short-wavelength light such as EUV light is preferably used.

In the opening portion 290, part of the conductive film 240A and parts of the insulator 280a to the insulator 280c are preferably processed by anisotropic etching. Processing by a dry etching method is particularly preferable because it is suitable for microfabrication. The processing may be performed under different conditions. Here, when the height H of the opening portion 290 is smaller than the width D of the opening portion 290, the distance to be dug by anisotropic etching can be shortened, so that the sidewall of the opening portion 290 can be made to have a shape that is closer to the perpendicular shape relatively easily.

When the conductive film 240A has a stacked-layer structure of a film of a indium tin oxide film to which silicon is added and a ruthenium film as described above, a ruthenium film with a small thickness can function as a hard mask in the anisotropic etching treatment. This can inhibit side etching of a indium tin oxide film to which silicon is added during anisotropic etching; thus, the sidewall of the opening portion 290 can be made to have a shape that is closer to the perpendicular shape relatively easily.

Depending on the materials for the conductive film 240A and the insulator 280a to the insulator 280c, and the condition of the anisotropic etching, the inclination of the side surface of the conductor 240 in the opening portion 290 may be different from the inclination of the side surface of the insulator 280 in the opening portion 290.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example.

Note that the opening portion 290 is not necessarily formed such that the top surface of the conductor 120 is flat. In that case, a depressed portion overlapped with the opening portion 290 is formed on the top surface of the conductor 120, whereby the transistor 200 illustrated in FIG. 8A can be formed.

The opening portion 290 is not necessarily formed such that the width D of the opening portion 290 is larger than the height H of the opening portion 290. In this case, the opening portion 290 is formed such that the height H of the opening portion 290 is larger than the width D of the opening portion 290, whereby the transistor 200 illustrated in FIG. 8D can be formed.

Next, heat treatment may be performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere including an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at higher than or equal to 10 ppm, higher than or equal to 1%, or higher than or equal to 10% in order to compensate for oxygen released, after heat treatment is performed in a nitrogen gas or inert gas atmosphere. By the above-described heat treatment, impurities such as water contained in the insulator 280 or the like can be reduced before formation of the later-described oxide semiconductor film to be the oxide semiconductor 230. Note that the heat treatment is preferably performed under the condition where the conductor 120 and the conductor 240 are not excessively oxidized.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment using a highly purified gas can prevent entry of moisture or the like into the insulator 280 and the like as much as possible.

Next, an insulating film 252A to be the insulator 252 is formed in contact with the bottom portion and the sidewall of the opening portion 290 and at least part of the top surface of the conductive film 240A. For the insulating film 252A, any of the above insulating materials that can be used for the insulator 252 can be used as appropriate. The insulating film 252A may be deposited by a sputtering method, a CVD method, an MBE method, a PLD method, an ALD method, or the like as appropriate. Here, the insulating film 252A is preferably formed in contact with the sidewall of the opening portion 290. Thus, the insulating film 252A is preferably formed by a deposition method providing favorable coverage, and is further preferably formed by a CVD method, an ALD method, or the like. For example, silicon nitride may be formed by a PEALD method as the insulating film 252A.

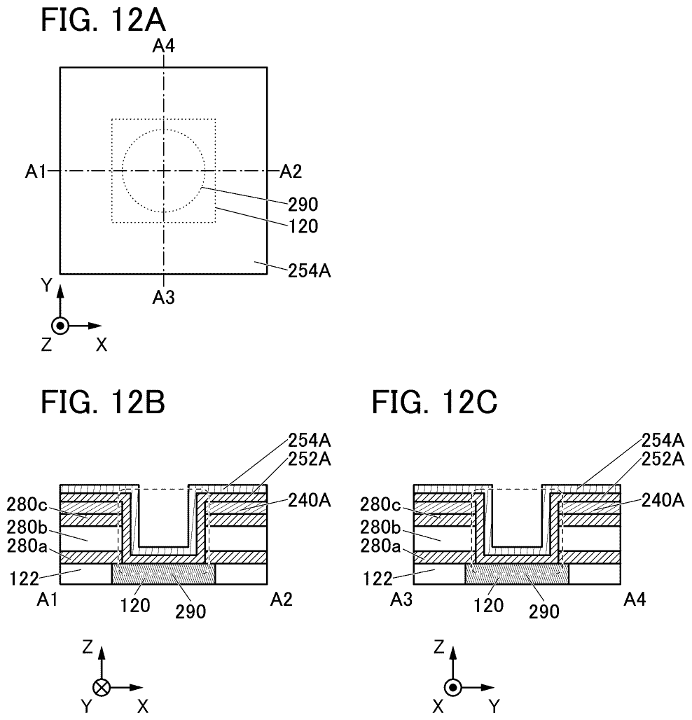

Next, an insulating film 254A to be the insulator 254 is formed over and in contact with the insulating film 252A (see FIG. 12A to FIG. 12C). For the insulating film 254A, any of the above-described insulating materials that can be used for the insulator 254 can be used as appropriate. The insulating film 254A can be deposited by a sputtering method, a CVD method, an MBE method, a PLD method, an ALD method, or the like as appropriate. Here, the insulating film 254A is preferably formed in contact with the depressed portion of the insulating film 252A formed to reflect the shape of the opening portion 290. Thus, the insulating film 254A is preferably formed by a deposition method providing favorable coverage, and is further preferably formed by a CVD method, an ALD method, or the like. As the insulating film 254A, for example, a hafnium oxide may be deposited by a thermal ALD method.

Note that the insulating film 252A and the insulating film 254A can be formed successively without exposure to the air. For example, the processing is performed without exposure to the air by using a multi-chamber deposition apparatus.

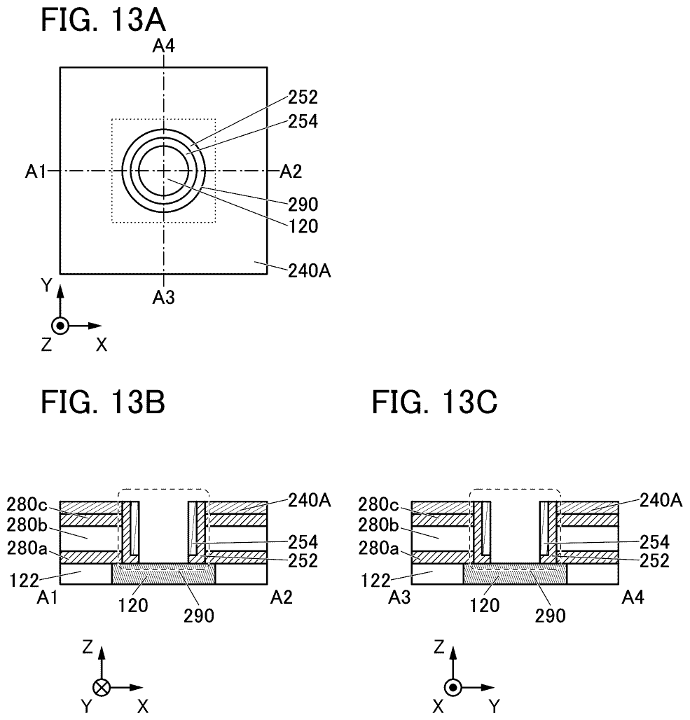

Next, part of the insulating film 252A and part of the insulating film 254A are removed by anisotropic etching, so that the insulator 252 in contact with the sidewall of the opening portion 290 and the insulator 254 in contact with the insulator 252 are formed (see FIG. 13A to FIG. 13C). Accordingly, the insulator 252 is formed in contact with the side surface of the insulator 280a, the side surface of the insulator 280b, the side surface of the insulator 280c, the side surface of the conductive film 240A, and the top surface of the conductor 120. As illustrated in FIG. 13A, in the plan view, the insulator 252 and the insulator 254 are formed concentrically, and the conductor 120 is exposed at the center of the opening portion 290.

As illustrated in FIG. 13B and FIG. 13C, a protruding portion is formed in a portion of the insulator 252 in contact with the top surface of the conductor 120. The protruding portion of the insulator 252 extends toward the center of the opening portion 290 beyond the other portion of the insulator 252. That is, the insulator 252 has what is called an L shape in a cross-sectional view perpendicular to the Z axis (also referred to as a direction perpendicular to the channel length direction).

The insulator 254 is formed to be positioned on the inner side of the insulator 252. As illustrated in FIG. 13B and FIG. 13C, the bottom surface of the insulator 254 is in contact with the top surface of the protruding portion of the insulator 252, and one side surface of the insulator 254 is in contact with the side surface of the insulator 252. The other side surface of the insulator 254 is formed to be aligned with an end portion of the projecting portion of the insulator 252. The insulator 254 is not in contact with the conductor 120.

Dry etching is preferably employed for anisotropic etching of the insulating film 252A and the insulating film 254A. Note that the above description can be referred to for the conditions and an apparatus for the dry etching method. In the case where silicon nitride is used for the insulating film 252A, etching treatment can be performed with an ICP etching apparatus using CHF₃ and O₂ as an etching gas, for example. For example, in the case where hafnium oxide is used for the insulating film 254A, etching treatment can be performed with an ICP etching apparatus using BCl₃ as an etching gas. Note that in the etching of the insulating film 252A, it is preferable that the etching selectivity of the insulating film 252A with respect to the conductive film 240A and the conductor 120 be sufficiently high so that the conductive film 240A and the conductor 120 are not etched.

In the etching of the insulating film 252A and the insulating film 254A, the generated ions may collide with corner portions of the edge of the opening of the insulator 252 and the insulator 254. Thus, the corner portion is polished to have a tapered shape in some cases. The corner portion is easily removed when a gas that is easily ionized, such as argon, is contained in the etching gas or a bias voltage is applied to an electrode on the substrate side, for example.

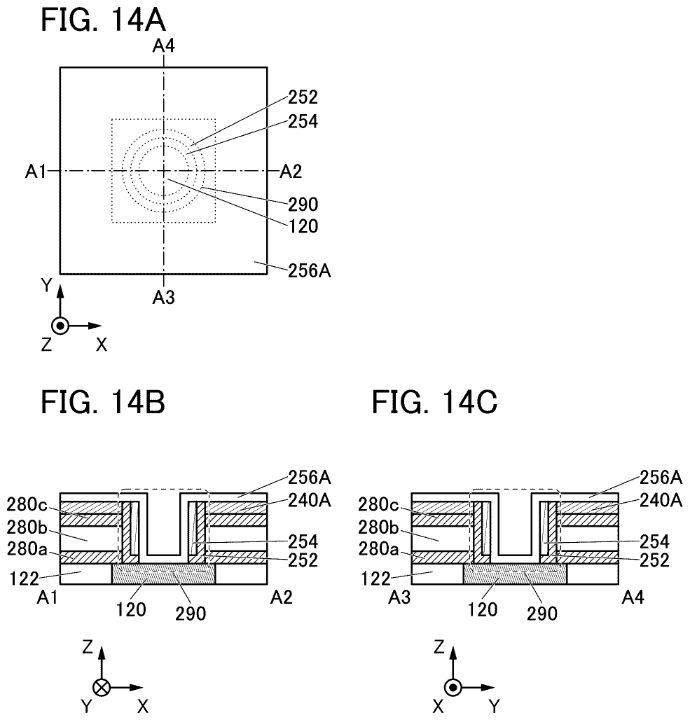

Next, an insulating film 256A to be the insulator 256 is formed in contact with at least parts of the top surface of the conductor 120, the protruding portion and the upper end portion of the insulator 252, the side surface and the upper end portion of the insulator 254, and the top surface of the conductive film 240A (see FIG. 14A to FIG. 14C). For the insulating film 256A, any of the above insulating materials that can be used for the insulator 256 can be used as appropriate. The insulating film 256A can be deposited by a sputtering method, a CVD method, an MBE method, a PLD method, an ALD method, or the like as appropriate. Here, the insulating film 256A is preferably formed in contact with the protruding portion of the insulator 252 and the side surface of the insulator 254. Thus, the insulating film 256A is preferably formed by a deposition method providing favorable coverage, and is further preferably formed by a CVD method, an ALD method, or the like. As the insulating film 256A, for example, silicon oxide may be deposited by a PEALD method.

Next, microwave treatment may be performed in an oxygen-containing atmosphere to reduce the impurity concentration in the insulating film 256A. Specific examples of the impurity include hydrogen and carbon. When the silicon oxide film is subjected to microwave treatment in an oxygen-containing atmosphere, hydrogen contained in the insulating film 256A can be released as H₂O to the outside. Release of hydrogen from the insulator 256 positioned in the vicinity of the oxide semiconductor 230 enables formation of a highly reliable semiconductor device.

The microwave treatment in an oxygen-containing atmosphere can convert an oxygen gas into plasma using a high-frequency wave such as a microwave or RF and activate the oxygen plasma. When oxygen plasma is applied to the insulating film 256A in this manner, excess oxygen can be contained in the insulating film 256A. When the insulator 256 containing excess oxygen is formed in contact with the oxide semiconductor 230, heat treatment or the like can be performed to supply oxygen from the insulator 256 to the channel formation region of the oxide semiconductor 230. Thus, oxygen vacancies and VoH in the channel formation region of the oxide semiconductor 230 can be reduced. Thus, the transistor 200 can have stable electrical characteristics and increased reliability. Oxygen that acts on the insulating film 256A has any of a variety of forms such as an oxygen atom, an oxygen molecule, an oxygen ion, and an oxygen radical (also referred to as O radical, which is an atom, a molecule, or an ion having an unpaired electron). The oxygen that acts on the insulating film 256A has any one or more of the above forms, particularly suitably an oxygen radical.

The above-described microwave treatment in an oxygen-containing atmosphere is preferably performed while the substrate is heated, in which case the impurity concentration in the insulating film 256A can be further reduced. The substrate heating temperature is higher than or equal to 100° C. and lower than or equal to 650° C., preferably higher than or equal to 200° C. and lower than or equal to 600° C., and further preferably higher than or equal to 300° C. and lower than or equal to 450° C.

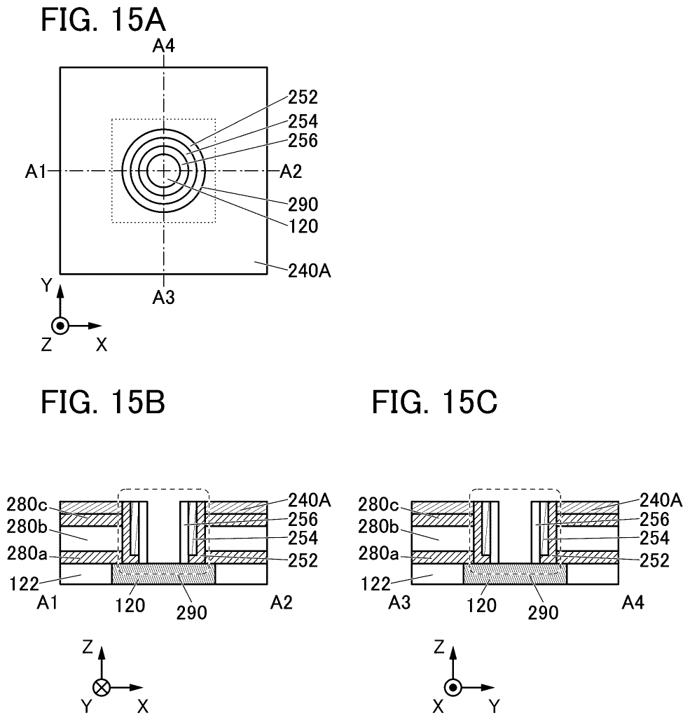

Next, part of the insulating film 256A is removed by anisotropic etching, and the insulator 256 in contact with the protruding portion of the insulator 252 and the side surface of the insulator 254 is formed (see FIG. 15A to FIG. 15C). Accordingly, as illustrated in FIG. 15A, in the plan view, the insulator 252, the insulator 254, and the insulator 256 are formed concentrically, and the conductor 120 is exposed at the center of the opening portion 290.

A dry etching method is preferably employed for the anisotropic etching of the insulating film 256A. Note that the above description can be referred to for the conditions and an apparatus for the dry etching method. In the case where silicon oxide is used for the insulating film 256A, etching treatment can be performed with an ICP etching apparatus using CHF₃ and O₂ as an etching gas, for example. Note that in the etching of the insulating film 256A, it is preferable that the etching selectivity of the insulating film 256A with respect to the conductive film 240A and the conductor 120 be sufficiently high so that the conductive film 240A and the conductor 120 are not etched.

In the etching of the insulating film 256A, the generated ions may collide with a corner portion of the edge of the opening of the insulator 256. Thus, the corner portion is polished to have a tapered shape in some cases. The corner portion is easily removed when a gas that is easily ionized, such as argon, is contained in the etching gas or a bias voltage is applied to an electrode on the substrate side, for example.

Next, the oxide semiconductor film to be the oxide semiconductor 230 is formed in contact with at least parts of the top surface of the conductor 120, the side surface and the upper end portion of the insulator 256, the upper end portion of the insulator 254, the upper end portion of the insulator 252, and the top surface of the conductive film 240A. For the oxide semiconductor film, a metal oxide usable for the oxide semiconductor 230 is used as appropriate. The oxide semiconductor film can be deposited as appropriate by a sputtering method, a CVD method, an MBE method, a PLD method, an ALD method, or the like. Here, the oxide semiconductor film is preferably formed in contact with the top surface and the bottom portion of the conductor 120 and the side surface of the insulator 256. Thus, the oxide semiconductor film is preferably formed by a formation method with favorable coverage, and is further preferably formed by a CVD method, an ALD method, or the like. For example, an In—Ga—Zn oxide may be deposited by an ALD method as the oxide semiconductor film. Incidentally, a method for depositing the metal oxide by an ALD method will be described in detail in an embodiment described below.

Note that the method for depositing the oxide semiconductor film to be the oxide semiconductor 230 is not limited to a CVD method or an ALD method. For example, a sputtering method may be employed. After the oxide semiconductor film is formed by a sputtering method, microwave treatment is preferably performed.

In the case where the oxide semiconductor 230 has a stacked-layer structure as illustrated in FIG. 3, the layers included in the oxide semiconductor 230 may be formed by the same method or different methods. For example, in the case where the oxide semiconductor 230 has a stacked-layer structure of two layers, the lower oxide semiconductor film (the oxide semiconductor 230a in FIG. 3) may be deposited by a sputtering method and the upper oxide semiconductor film (the oxide semiconductor 230b in FIG. 3) may be deposited by an ALD method. An oxide semiconductor film formed by a sputtering method is likely to have crystallinity. Thus, when an oxide semiconductor film having crystallinity is provided as the lower oxide semiconductor film, the crystallinity of the upper oxide semiconductor film can be increased. Thus, even when a pinhole, disconnection, or the like is generated in the lower oxide semiconductor film deposited by a sputtering method, a portion overlapping with the pinhole, disconnection, or the like can be filled with the upper oxide semiconductor film that is deposited by an ALD method and has excellent coverage.

In the case where the oxide semiconductor 230a is formed by a sputtering method and the oxide semiconductor 230b is formed by an ALD method, the oxide semiconductor 230a and the oxide semiconductor 230b may differ in the ratio between the thickness of a portion formed over the top surface of the conductor 240 (hereinafter referred to as a first thickness) and the thickness of a portion formed along the side surface of the conductor 240 and the side surface of the insulator 280 (hereinafter referred to as a second thickness) in some cases. For example, the ratio of the second thickness to the first thickness of the oxide semiconductor 230b can be 1 or an approximate value thereof. On the other hand, in the oxide semiconductor 230a, the ratio of the second thickness to the first thickness is lower than 1, lower than 0.8, or lower than 0.5 in some cases. In particular, as the angle subtended between the side surface of the insulator 280 in the opening portion 290 and the top surface of the conductor 120 is closer to 90°, the ratio of the second thickness to the first thickness of the oxide semiconductor 230a tends to be lower.

In addition, the oxide semiconductor 230 can have a concentration gradient in the impurity concentration in the film. For example, in the case where the oxide semiconductor 230a is deposited by a sputtering method and the oxide semiconductor 230b is deposited by an ALD method, the impurity in the film of the oxide semiconductor 230a may be lower than the impurity in the film of the oxide semiconductor 230b. Thus, the impurity concentration in the oxide semiconductor 230 may have a concentration gradient in which the impurity concentration in the film decreases from the conductor 260 toward the conductor 120. As the impurities in the film of the oxide semiconductor 230, one or more selected from hydrogen, nitrogen, and carbon can be given as examples.

Here, the oxide semiconductor film to be the oxide semiconductor 230 is preferably formed in contact with the top surface of the conductor 120 in the opening portion 290, the side surface of the insulator 256 in the opening portion 290, and the top surface of the conductor 240. When the oxide semiconductor film is formed in contact with the conductor 120, the conductor 120 functions as one of a source electrode and a drain electrode of the transistor 200. When the oxide semiconductor film is formed in contact with the conductor 240, the conductor 240 functions as the other of the source electrode and the drain electrode of the transistor 200.

Next, heat treatment is preferably performed. The heat treatment can be performed in a temperature range where the oxide semiconductor film does not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at higher than or equal to 10 ppm, higher than or equal to 1%, or higher than or equal to 10% in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment using a highly purified gas can prevent entry of moisture or the like into the oxide semiconductor film and the like as much as possible.

Here, the above-described heat treatment is preferably performed in the state where the insulator 256 containing excess oxygen is in contact with the oxide semiconductor film. By the heat treatment performed in that manner, oxygen is supplied from the insulator 256 to the channel formation region of the oxide semiconductor 230, whereby oxygen vacancies and VoH can be reduced. Since the insulator 254 having a function of capturing or fixing hydrogen is formed in contact with the insulator 256, hydrogen contained in the oxide semiconductor 230 and the insulator 256 can be captured or fixed by the insulator 254. Since the insulator 254, the insulator 280a, and the insulator 280c through all of which hydrogen is less likely to pass are formed to surround the insulator 280b, diffusion of hydrogen contained in the insulator 280b and the like into the insulator 254, the insulator 256, and the oxide semiconductor 230 can be reduced. Thus, hydrogen concentration in the channel formation region of the oxide semiconductor 230 can be reduced. As described above, oxygen vacancies and VoH in the oxide semiconductor 230 can be reduced, so that a semiconductor device that has favorable electrical characteristics and high reliability can be provided.

Although the heat treatment is performed after the formation of the oxide semiconductor film in the above, the present invention is not limited thereto. The heat treatment may be performed in a later step.

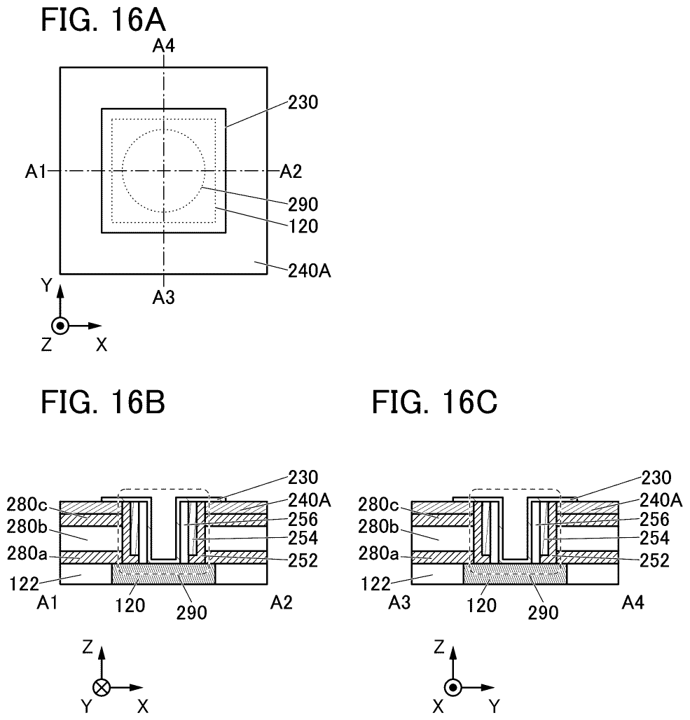

Next, the oxide semiconductor film to be the oxide semiconductor 230 is processed by a lithography method to form the oxide semiconductor 230 (see FIG. 16A to FIG. 16C). Accordingly, part of the oxide semiconductor 230 is formed in the opening portion 290. Here, the oxide semiconductor 230 is in contact with the side surface and part of the top surface of the conductor 240. For the processing of the oxide semiconductor 230, a dry etching method or a wet etching method can be employed. Processing by a dry etching method is suitable for microfabrication.

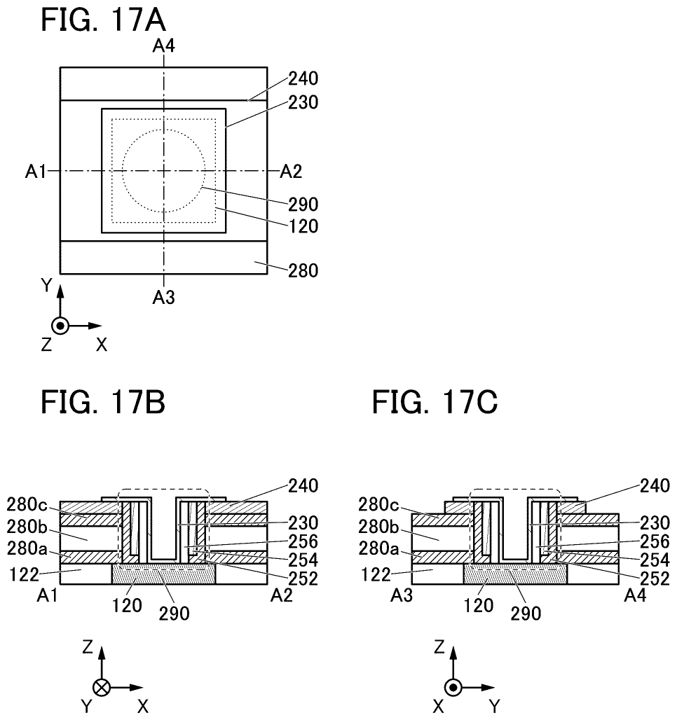

Next, the conductive film 240A is processed to form the conductor 240 (see FIG. 17A to FIG. 17C). The conductor 240 can be formed by a lithography method. For the processing of the conductive film 240A, a dry etching method or a wet etching method can be employed. Processing by a dry etching method is suitable for microfabrication.

In addition, the conductive film 240A is preferably processed by an etching method providing high selectivity to the insulator 280c (an etching method in which the insulator 280c is a stop film). For example, the etching selectivity between the conductive film 240A and the insulator 280c is preferably increased. Alternatively, an insulator having high etching selectivity to the conductive film 240A is preferably provided between the conductive film 240A and the insulator 280c.

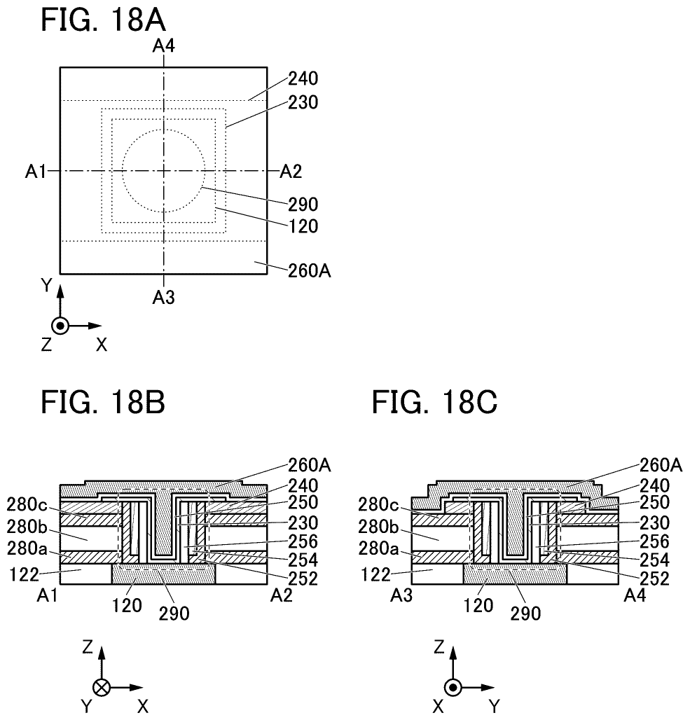

Next, the insulator 250 is formed over the oxide semiconductor 230, the conductor 240, and the insulator 280 (see FIG. 18A to FIG. 18C). Any of the above-described insulating materials can be used for the insulator 250 as appropriate. The insulator 250 can be deposited by a sputtering method, a CVD method, an MBE method, a PLD method, an ALD method, or the like as appropriate. The insulator 250 is preferably formed in contact with the oxide semiconductor 230 that is provided in the opening portion 290. Thus, the insulator 250 is preferably formed by a formation method providing favorable coverage, and is further preferably formed by a CVD method, an ALD method, or the like. For example, silicon oxide may be deposited as the insulator 250 by a PEALD method. Note that the method for depositing the insulator 250 is not limited to a CVD method or an ALD method. For example, a sputtering method may be employed.

As illustrated in FIG. 3, the insulator 250 can have a stacked-layer structure of the insulator 250a to the insulator 250d. For example, an aluminum oxide can be deposited as the insulator 250a by a thermal ALD method. For example, silicon oxide may be deposited as the insulator 250b by a PEALD method. For example, hafnium oxide may be deposited as the insulator 250c by a thermal ALD method. For example, silicon nitride may be deposited as the insulator 250d by a PEALD method.

When the insulator 250 is formed after the formation of the oxide semiconductor 230, the side end portion of the oxide semiconductor 230 is covered with the insulator 250. Thus, a short circuit between the oxide semiconductor 230 and the conductor 260 can be prevented. Furthermore, in the above-described structure, the side end portion of the conductor 240 is covered with the insulator 250. Thus, a short circuit between the conductor 240 and the conductor 260 can be prevented.

Microwave treatment may be performed after the formation of the insulator 250. When the insulator 250 is subjected to microwave treatment in an oxygen-containing atmosphere, hydrogen contained in the insulator 250 can be released as H₂O to the outside. Release of hydrogen from the silicon oxide film positioned in the vicinity of the metal oxide enables formation of a highly reliable semiconductor device.

Furthermore, the microwave treatment can remove impurities such as carbon in the oxide semiconductor 230. With the removal of carbon, which is an impurity in the oxide semiconductor 230, the crystallinity of the oxide semiconductor 230 can be improved. Accordingly, the oxide semiconductor 230 can be a CAAC-OS. Particularly in the case where the oxide semiconductor 230 is deposited by an ALD method, carbon included in a precursor is sometimes taken into the oxide semiconductor 230; thus, carbon is preferably removed by the microwave treatment.

Note that in the case where the insulator 250 has a stacked-layer structure, the microwave treatment is not always performed after all the insulators included in the insulator 250 are formed. For example, in the case of the structure illustrated in FIG. 3, microwave treatment may be performed after the insulator 250a and the insulator 250b are formed, and then the insulator 250c and the insulator 250d may be formed. Alternatively, for example, the steps may be performed in the following order: formation of the insulator 250a and the insulator 250b, microwave treatment, formation of the insulator 250c, microwave treatment, and formation of the insulator 250d. In this manner, the microwave treatment in an oxygen-containing atmosphere may be performed multiple times.

Next, a conductive film 260A is deposited to fill the depressed portion of the insulator 250 (see FIG. 18A to FIG. 18C). Any of the above-described conductive materials can be used for the conductive film 260A as appropriate. The conductive film 260A can be deposited by a sputtering method, a CVD method, an MBE method, a PLD method, an ALD method, or the like as appropriate. Here, the conductive film 260A is preferably formed in contact with the insulator 250 provided in the opening portion 290. Thus, the conductive film 260A is preferably formed by a formation method enabling favorable coverage or a good filling property, and is further preferably formed by a CVD method, an ALD method, or the like. For example, as the conductive film 260A, titanium nitride may be deposited by a CVD method or an ALD method and tungsten may be deposited over the titanium nitride by a CVD method.

Although the conductive film 260A is provided to fill the opening portion 290 in the above description, the present invention is not limited thereto. For example, a depressed portion reflecting the shape of the opening portion 290 is formed in a center portion of the conductive film 260A in some cases. The depressed portion may be filled with an inorganic insulating material or the like.

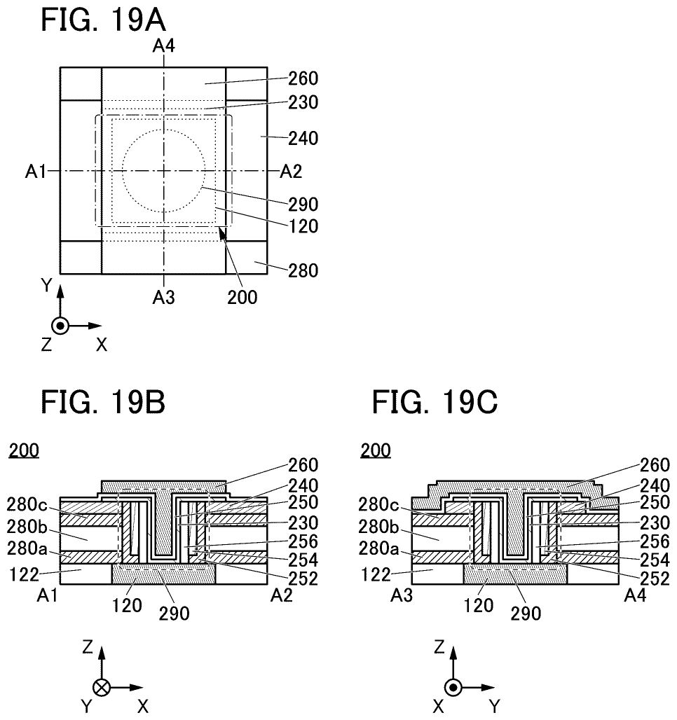

Next, the conductive film 260A is processed to form the conductor 260 (see FIG. 19A to FIG. 19C). The conductor 260 may be formed by a lithography method. A dry etching method or a wet etching method can be used for the processing. Processing by a dry etching method is suitable for microfabrication.

In the above manner, the transistor 200 including the insulator 252, the insulator 254, the insulator 256, the conductor 120, the conductor 240, the oxide semiconductor 230, the insulator 250, and the conductor 260 can be formed.

Next, the insulator 283 is formed to cover the conductor 260 and the insulator 250. Any of the above-described insulating materials can be used as the insulator 283 as appropriate. The insulator 283 can be deposited by a sputtering method, a CVD method, an MBE method, a PLD method, an ALD method, or the like as appropriate.

Through the above process, the transistor 200 illustrated in FIG. 2A to FIG. 2E and the like can be manufactured.

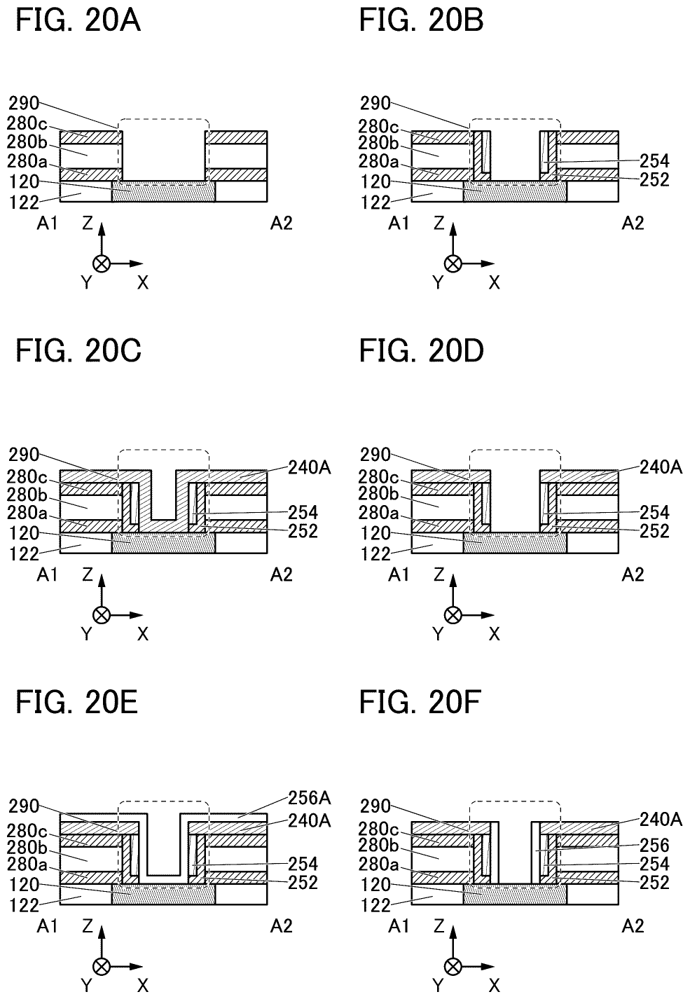

Although the method for manufacturing the transistor 200 in FIG. 2A to FIG. 2E is described above with reference to FIG. 10 to FIG. 19, the transistor 200 in FIG. 4A to FIG. 4E can be manufactured by a similar method. A method for manufacturing the transistor 200 in FIG. 4A to FIG. 4E is described below with reference to FIG. 20A to FIG. 20F.

First, the components up to the insulator 280c are formed by the method illustrated in FIG. 10A to FIG. 10C. Next, the opening portion 290 is formed in the insulator 280a to the insulator 280c by the method illustrated in FIG. 11A to FIG. 11C (see FIG. 20A). That is, in the transistor 200 in FIG. 4A to FIG. 4E, the opening portion 290 is formed before the formation of the conductive film 240A.

Next, the insulator 252 and the insulator 254 are formed by the method illustrated in FIG. 12A to FIG. 13C (see FIG. 20B). Here, the top surface of the insulator 280c is level with or substantially level with the upper end portion of the insulator 252 and the upper end portion of the insulator 254.

Next, the conductive film 240A is formed over the insulator 280c, the insulator 252, the insulator 254, and the conductor 120 by the method illustrated in FIG. 10A to FIG. 10C (see FIG. 20C). Here, the opening portion 290 may be embedded with a filler (e.g., an SOC film), and then the conductive film 240A may be formed.

Next, the conductive film 240A is processed by a lithography method to form an opening overlapping with the opening portion 290 (see FIG. 20D). Here, as illustrated in FIG. 20D, the upper end portion of the insulator 252 and the upper end portion of the insulator 254 are in contact with the conductive film 240A. For the processing of the conductive film 240A, a dry etching method or a wet etching method can be employed. Processing by a dry etching method is suitable for microfabrication. Note that in the case where the opening portion 290 is embedded with a filler, the filler may be removed after the processing of the conductive film 240A.

Although in FIG. 20D, the side surface of the conductive film 240A and the side surface of the insulator 254 are aligned with each other, the present invention is not limited thereto. For example, when the opening of the conductive film 240A is made larger than the opening of the insulator 254, a margin to be processed can be large. In that case, the transistor 200 illustrated in FIG. 7C can be manufactured.

Next, the insulating film 256A is formed over the conductive film 240A, the insulator 280c, the insulator 252, the insulator 254, and the conductor 120 by the method illustrated in FIG. 14A to FIG. 14C (see FIG. 20E).

Next, the insulating film 256A is processed by the method illustrated in FIG. 15A to FIG. 15C to form the insulator 256 in the opening portion 290 (see FIG. 20F). Here, the side surface of the conductive film 240A is in contact with the insulator 256.

Note that the transistor 200 illustrated in FIG. 7A can be manufactured in the following manner: the insulator 256 is formed in the opening portion 290 in the step illustrated in FIG. 20F, and then the conductive film 240A is formed in the step illustrated in FIG. 20C.

With the use of the method illustrated in FIG. 16A to FIG. 19C, the transistor 200 in FIG. 4A to FIG. 4E can be manufactured.

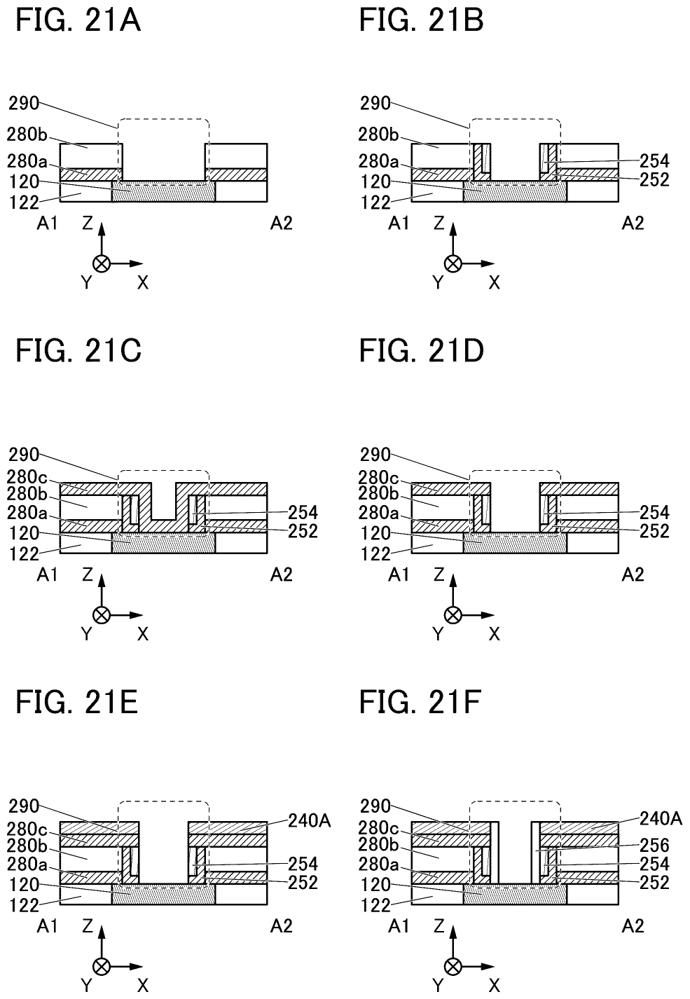

The transistor 200 in FIG. 5A to FIG. 5E can also be manufactured by a method similar to the method for manufacturing the transistor 200 in FIG. 4A to FIG. 4E. A method for manufacturing the transistor 200 in FIG. 5A to FIG. 5E is described below with reference to FIG. 21A to FIG. 21F.

First, the components up to the insulator 280b are formed by the method illustrated in FIG. 10A to FIG. 10C. Next, the opening portion 290 is formed in the insulator 280a and the insulator 280b by the method illustrated in FIG. 11A to FIG. 11C (see FIG. 21A). That is, in the transistor 200 in FIG. 5A to FIG. 5E, the opening portion 290 is formed before the insulator 280c and the conductive film 240A are formed.

Next, the insulator 252 and the insulator 254 are formed by the method illustrated in FIG. 12A to FIG. 13C (see FIG. 21B). Here, the top surface of the insulator 280b is level with or substantially level with the upper end portion of the insulator 252 and the upper end portion of the insulator 254.

Next, the insulator 280c is formed over the insulator 280b, the insulator 252, the insulator 254, and the conductor 120 by the method illustrated in FIG. 20C (see FIG. 21C).

Next, the insulator 280c is processed by the method illustrated in FIG. 20D to form an opening overlapping with the opening portion 290 (see FIG. 21D). Here, as illustrated in FIG. 21D, the upper end portion of the insulator 252 and the upper end portion of the insulator 254 are in contact with the insulator 280c.

Next, the conductive film 240A is formed over the insulator 280b, the insulator 280c, the insulator 252, the insulator 254, and the conductor 120 by the method illustrated in FIG. 20C. Next, the conductive film 240A is processed to form an opening overlapping with the opening portion 290 by the method illustrated in FIG. 20D (see FIG. 21D).

Although in FIG. 21D, the side surface of the conductive film 240A, the side surface of the insulator 280c, and the side surface of the insulator 254 are aligned with each other, the present invention is not limited thereto. For example, when the opening of the conductive film 240A is made larger than the opening of the insulator 280c and the opening of the insulator 280c is made larger than the opening of the insulator 254, a margin to be processed can be large. In that case, the transistor 200 illustrated in FIG. 7D can be manufactured.

Next, the insulator 256 is formed in the opening portion 290 by the method illustrated in FIG. 20A and FIG. 20B (see FIG. 21F). Here, the side surface of the insulator 280c is in contact with the insulator 256.

Note that the transistor 200 illustrated in FIG. 7B can be manufactured in the following manner: the insulator 256 is formed in the opening portion 290 in the step illustrated in FIG. 21F, and then the conductive film 240A is formed in the step illustrated in FIG. 21C.

With the use of the method illustrated in FIG. 16A to FIG. 19C, the transistor 200 in FIG. 5A to FIG. 5E can be manufactured.

### Structure Example of Memory Device

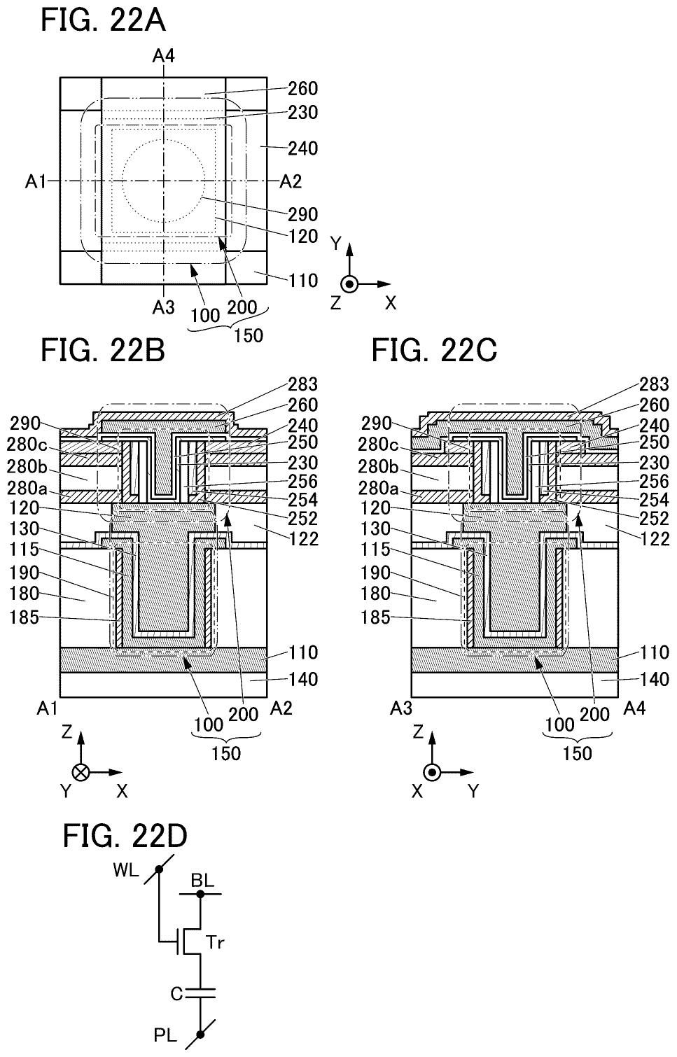

A structure of a memory device including the transistor 200 is described with reference to FIG. 22. FIG. 22A to FIG. 22C are a plan view and cross-sectional views of the memory device including the transistor 200 and the capacitor 100. FIG. 22A is a plan view of the memory device. FIG. 22B and FIG. 22C are cross-sectional views of the memory device. Here, FIG. 22B is a cross-sectional view of a portion indicated by the dashed-dotted line A1-A2 in FIG. 22A. FIG. 22C is a cross-sectional view of a portion indicated by the dashed-dotted line A3-A4 in FIG. 22A. Note that for clarity of the drawing, some components are omitted in the plan view of FIG. 22A.

The memory device illustrated in FIG. 22A to FIG. 22C includes an insulator 140 over a substrate (not illustrated), a conductor 110 over the insulator 140, a memory cell 150 over the conductor 110, an insulator 180 over the conductor 110, the insulator 122, the insulator 280, and the insulator 283 over the memory cell 150. The insulator 140, the insulator 180, the insulator 280, and the insulator 283 each function as an interlayer film. The conductor 110 functions as a wiring.

The memory cell 150 includes the capacitor 100 over the conductor 110 and the transistor 200 over the capacitor 100.

The capacitor 100 includes a conductor 115 over the conductor 110, an insulator 130 over the conductor 115, and a conductor 120 over the insulator 130. The conductor 120 functions as one of a pair of electrodes (sometimes referred to as an upper electrode), the conductor 115 functions as the other of the pair of electrodes (sometimes referred to as a lower electrode), and the insulator 130 functions as a dielectric. That is, the capacitor 100 forms a MIM (Metal-Insulator-Metal) capacitor.

As illustrated in FIG. 22B and FIG. 22C, the opening portion 190 reaching the conductor 110 is provided in the insulator 180. At least part of the conductor 115 is placed in the opening portion 190. Note that the conductor 115 includes a region in contact with the top surface of the conductor 110 in the opening portion 190, a region in contact with the side surface of the insulator 180 in the opening portion 190, and a region in contact with at least part of the top surface of the insulator 180. The insulator 130 is placed in such a manner that at least part of the insulator 130 is positioned in the opening portion 190. The conductor 120 is placed in such a manner that at least part of the conductor 120 is positioned in the opening portion 190. In addition, the conductor 120 is preferably provided to fill the opening portion 190 as illustrated in FIG. 22B and FIG. 22C.

The capacitor 100 has a structure in which the upper electrode and the lower electrode face each other with the dielectric therebetween on the side surface as well as on the bottom surface of the opening portion 190; thus, the capacitance per unit area can be increased. Thus, the deeper the opening portion 190 is, the higher the capacitance of the capacitor 100 can be. Increasing the capacitance per unit area of the capacitor 100 in this manner enables a stable reading operation of the memory device. This also allows further miniaturization or high integration of the memory device.

Note that the sidewall of the opening portion 190 is preferably perpendicular to the top surface of the conductor 110. In that case, the opening portion 190 has a cylindrical shape. With the structure, the memory device can be miniaturized or highly integrated.

The conductor 115 and the insulator 130 are stacked along the sidewall of the opening portion 190 and the top surface of the conductor 110. The conductor 120 is provided over the insulator 130 to fill the opening portion 190. The capacitor 100 having such a structure may be referred to as a trench-type capacitor or a trench capacitor.

The insulator 122 is placed over the capacitor 100. That is, the insulator 122 is placed over the conductor 115, the insulator 130, and the conductor 120. In other words, the conductor 120 is placed under the insulator 122.

As illustrated in FIG. 22A to FIG. 22C, the transistor 200 is provided to overlap with the capacitor 100. The opening portion 290 where part of the structure of the transistor 200 is provided includes a region overlapping with the opening portion 190 where part of the structure of the capacitor 100 is provided. In particular, since the conductor 120 has a function of one of the source electrode and the drain electrode of the transistor 200 and a function of the upper electrode of the capacitor 100, the transistor 200 and the capacitor 100 partly share the structure. With such a structure, the transistor 200 and the capacitor 100 can be provided without a great increase in the occupation area in the plan view. Thus, the occupation area of the memory cell 150 can be reduced, so that the memory cells 150 can be arranged densely and the memory capacity of the memory device can be increased. In other words, the memory device can be highly integrated.

FIG. 22D is a circuit diagram of the memory device described in this embodiment. As illustrated in FIG. 22D, the structure illustrated in FIG. 22A to FIG. 22C functions as a memory cell of the memory device. The memory cell includes a transistor Tr and a capacitor C. In this case, the transistor Tr and the capacitor C correspond to the transistor 200 and the capacitor 100, respectively.

One of a source and a drain of the transistor Tr is electrically connected to one of a pair of electrodes of the capacitor C. The other of the source and the drain of the transistor Tr is connected to a wiring BL. A gate of the transistor Tr is connected to a wiring WL. The other of the pair of electrodes of the capacitor C is connected to a wiring PL.

Here, the wiring BL corresponds to the conductor 240, the wiring WL corresponds to the conductor 260, and the wiring PL corresponds to the conductor 110. As illustrated in FIG. 22A to FIG. 22C, it is preferable that the conductor 260 be formed to extend in the Y direction and the conductor 240 be formed to extend in the X direction. In this structure, the wiring BL and the wiring WL are provided to intersect with each other. Although the wiring PL (the conductor 110) is provided in a planar manner in FIG. 22A, the present invention is not limited thereto. For example, the wiring PL may be provided in parallel with the wiring WL (the conductor 260) or may be provided in parallel with the wiring BL (the conductor 240).

The conductor 110 is provided over the insulator 140. The conductor 110 functions as the wiring PL and can be provided in a planar manner, for example. As the conductor 110, a single layer or stacked layers of any of the conductors described in a later-described section [Conductor] can be used. For example, a conductive material with high conductivity such as tungsten can be used for the conductor 110. With the use of a conductive material with high conductivity, the conductor 110 can have improved conductivity and can work well as the wiring PL.

A single layer or stacked-layer including a conductive material that is less likely to be oxidized, a conductive material having a function of inhibiting diffusion of oxygen, or the like is preferably used for the conductor 110. For example, titanium nitride, indium tin oxide to which silicon is added, or the like may be used. A structure in which titanium nitride is stacked over tungsten may be used, for example. Alternatively, for example, a structure in which tungsten is stacked over a first titanium nitride and a second titanium nitride is stacked over the tungsten may be used. With such a structure, when an oxide insulator is used for the insulator 180, the conductor 110 can be inhibited from being oxidized by the insulator 180.

As the conductor 115, a single layer or stacked layers of any of the conductors described in the later-described section [Conductor] can be used. In addition, a conductive material that is less likely to be oxidized, a conductive material having a function of inhibiting diffusion of oxygen, or the like is preferably used for the conductor 115. For example, titanium nitride, tantalum nitride, or the like can be used. For example, a structure in which tantalum nitride is stacked over titanium nitride may be used. With this structure, in the case of using an oxide insulator for the insulator 130, oxidation of the conductor 115 due to the insulator 130 can be inhibited. In the case of using an oxide insulator for the insulator 180, oxidation of the conductor 115 due to the insulator 180 can be inhibited.

The insulator 130 is provided over the conductor 115. The insulator 130 can be provided to be in contact with the top surface and the side surface of the conductor 115. That is, the insulator 130 preferably covers the side end portion of the conductor 115. This can prevent a short circuit between the conductor 115 and the conductor 120.

In addition, a structure may be employed in which the side end portion of the insulator 130 and the side end portion of the conductor 115 are substantially aligned with each other. This structure enables the insulator 130 and the conductor 115 to be formed using the same mask, so that the manufacturing process of the memory device can be simplified.

For the insulator 130, any of materials with high relative permittivity, that is, high-k materials, described in the above-described section [Insulator] is preferably used. Using such a high-k material for the insulator 130 allows the insulator 130 to be thick enough to inhibit a leakage current and the capacitor 100 to have a sufficiently high capacitance.

It is preferable for the insulator 130 to use stacked insulating layers formed of any of the high-k materials, and it is preferable to use a stacked-layer structure of a high relative permittivity (high-k) material and a material having a higher dielectric strength than the high-k material. As the insulator 130, an insulating film in which zirconium oxide, aluminum oxide, and zirconium oxide are stacked in this order can be used, for example. An insulating film in which zirconium oxide, aluminum oxide, zirconium oxide, and aluminum oxide are stacked in this order can be used, for example. As another example, an insulating film in which hafnium zirconium oxide, aluminum oxide, hafnium zirconium oxide, and aluminum oxide are stacked in this order can be used. The use of stacked insulators with relatively high dielectric strength, such as aluminum oxide, can increase the dielectric strength and inhibit electrostatic breakdown of the capacitor 100.

Alternatively, a material that can have ferroelectricity may be used for the insulator 130. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the atomic ratio of hafnium atom to the element J1 can be set as appropriate; the atomic ratio of hafnium atom to the element J1 is, for example, 1:1 or in the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The atomic ratio of zirconium atom to the element J2 can be set as appropriate; the atomic ratio of zirconium atom to the element J2 is, for example, 1:1 or in the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more selected from aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that can have ferroelectricity also include a material in which an element M3 is added to the above metal nitride. Note that the element M3 is one or more selected from magnesium, calcium, strontium, zinc, cadmium, and the like. Here, the atomic ratio of the element M1 to the element M2 to the element M3 can be set as appropriate.

Examples of the material that can have ferroelectricity also include a perovskite-type oxynitride such as SrTaO₂N or BaTaO₂N, GaFeO₃ with a κ-alumina-type structure, and the like.

In the above description, metal oxides and metal nitrides are presented as non-limiting examples. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, the insulator 130 can have a stacked-layer structure of a plurality of materials selected from the above-listed materials. Note that the crystal structures (properties) of the above-listed materials and the like can be changed depending on the processes as well as the deposition conditions; thus, a material that exhibits ferroelectricity is referred to not only as a ferroelectric but also as a material that can have ferroelectricity in this specification and the like.

A metal oxide containing one or both of hafnium and zirconium is preferable because the metal oxide can have ferroelectricity even when being processed into a thin film of several nanometers. Here, the thickness of the insulator 130 can be less than or equal to 100 nm, preferably less than or equal to 50 nm, further preferably less than or equal to 20 nm, still further preferably less than or equal to 10 nm (typically greater than or equal to 2 nm and less than or equal to 9 nm). The film thickness is preferably greater than or equal to 8 nm and less than or equal to 12 nm, for example. When a ferroelectric layer that can be thinned is used, the capacitor 100 can be combined with a semiconductor element such as a miniaturized transistor to form a semiconductor device. Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

A metal oxide containing one or both of hafnium and zirconium is preferable because the metal oxide can have ferroelectricity even with a minute area. For example, a ferroelectric layer can have ferroelectricity even with an area (occupation area) in the plan view less than or equal to 100 μm², less than or equal to 10 μm², less than or equal to 1 μm², or less than or equal to 0.1 μm². Furthermore, even a ferroelectric layer with an area of less than or equal to 10000 nm² or less than or equal to 1000 nm² can have ferroelectricity in some cases. With a small-area ferroelectric layer, the occupation area of the capacitor 100 can be reduced.

The ferroelectric is an insulator and has a property of causing internal polarization by application of an electric field from the outside and maintaining the polarization even after the electric field is made zero. Thus, with a capacitor that includes this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory), a ferroelectric memory, or the like. For example, a ferroelectric memory has a structure which includes a transistor and a ferroelectric capacitor and in which one of a source and a drain of the transistor is electrically connected to one terminal of the ferroelectric capacitor. Thus, in the case of using a ferroelectric capacitor as the capacitor 100, the memory device described in this embodiment functions as a ferroelectric memory.

It is considered that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulator 130 can exhibit ferroelectricity, the insulator 130 needs to include a crystal. It is particularly preferable for the insulator 130 to include a crystal having an orthorhombic crystal structure to exhibit ferroelectricity. Incidentally, a crystal included in the insulator 130 may have one or more selected from cubic, tetragonal, orthorhombic, monoclinic, hexagonal crystal structures. Alternatively, the insulator 130 may include an amorphous structure. In that case, the insulator 130 may have a composite structure including an amorphous structure and a crystal structure.

The conductor 120 is provided in contact with part of the top surface of the insulator 130. The conductor 120 is similar to the one used for the transistor 200.

The insulator 180, which functions as an interlayer film, preferably has low relative permittivity. When a material with low relative permittivity is used for an interlayer film, parasitic capacitance generated between wirings can be reduced. As the insulator 180, a single layer or stacked layers of any of the insulators each including a material with low relative permittivity described in the above-described section [Insulator] can be used. In particular, silicon oxide and silicon oxynitride are preferable because they are thermally stable. At this time, the insulator 180 contains at least silicon and oxygen.

Note that although the insulator 180 has a single layer in FIG. 22B and FIG. 22C, the present invention is not limited thereto. The insulator 180 may have a stacked-layer structure. In the case of employing a stacked-layer structure, an insulator having a barrier property against hydrogen, which is described in the above-described section of [Insulator], is preferably used for one or more layers of the insulator 180. In that case, diffusion of hydrogen into the insulator 130 from below through the insulator 180 and the conductor 115 can be inhibited. Silicon nitride and silicon nitride oxide can be suitably used for the insulator 180 because silicon nitride and silicon nitride oxide release fewer impurities (e.g., water and hydrogen) and are less likely to transmit oxygen and hydrogen.

As illustrated in FIG. 22B and FIG. 22C, an insulator 185 is preferably provided between the conductor 115 and the insulator 180. The insulator 185 is preferably provided in contact with the side surface of the insulator 180 in the opening portion 190. That is, the insulator 185 is preferably provided between the conductor 115 and the side surface of the insulator 180 in the opening portion 190.

As the insulator 185, any of the insulators having a barrier property against hydrogen described in the above-described section [Insulator] is preferably used. This can inhibit diffusion of hydrogen into the insulator 130 positioned in the opening portion 190 from the outside of the capacitor 100 through the insulator 180. For example, silicon nitride or silicon nitride oxide can be used as the insulator 185. In this case, the insulator 185 contains at least silicon and nitrogen.

As the insulator 185, any of the insulators having a function of capturing or fixing hydrogen described in the above-described section [Insulator] is preferably used. With this structure, hydrogen in the insulator 130 can be captured or fixed, whereby the hydrogen concentration in the insulator 130 can be reduced. As the insulator 185, magnesium oxide, aluminum oxide, hafnium oxide, or the like can be used. Alternatively, for example, a stacked-layer film of aluminum oxide and silicon nitride over the aluminum oxide may be used as the insulator 185.

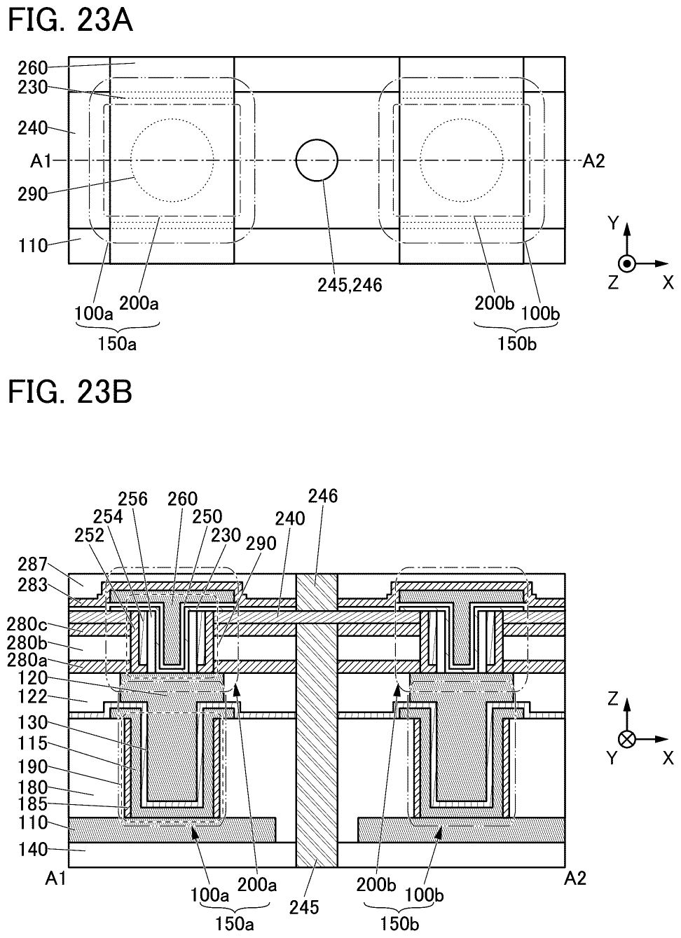

An example of a memory device in which two memory cells 150 (hereinafter referred to as a memory cell 150a and a memory cell 150b) are connected to a common wiring is described with reference to FIG. 23A and FIG. 23B. FIG. 23A is a plan view of the memory device. FIG. 23B is a cross-sectional view of a portion indicated by the dashed-dotted line A1-A2 in FIG. 23A. For the sake of clarity of the drawing, some components are omitted in the plan view of FIG. 23A.

Here, the memory cell 150a and the memory cell 150b illustrated in FIG. 23A and FIG. 23B each have a structure similar to that of the memory cell 150. The memory cell 150a includes a capacitor 100a and a transistor 200a, and the memory cell 150b includes a capacitor 100b and a transistor 200b. Thus, in the memory device illustrated in FIG. 23A and FIG. 23B, components having the same functions as the components of the memory device illustrated in FIG. 22 are denoted by the same reference numerals.

As illustrated in FIG. 23A and FIG. 23B, the conductor 260 functioning as the wiring WL is provided in each of the memory cell 150a and the memory cell 150b. The conductor 240 functioning as part of the wiring BL is provided to be shared by the memory cell 150a and the memory cell 150b. That is, the conductor 240 is in contact with the oxide semiconductor 230 of the memory cell 150a and the oxide semiconductor 230 of the memory cell 150b.

Here, the memory device illustrated in FIG. 23A and FIG. 23B includes a conductor 245 and a conductor 246 functioning as plugs (also can be referred to as connection electrodes) electrically connected to the memory cell 150a and the memory cell 150b. The conductor 245 is placed in an opening formed in the insulator 180, the insulator 280, and the insulator 140 and is in contact with the bottom surface of the conductor 240. The conductor 246 is placed in an opening portion formed in the insulator 287, the insulator 283, and the insulator 250 and is in contact with the top surface of the conductor 240. In addition, a conductive material or the like usable for the conductor 240 can be used for the conductor 245 and the conductor 246.

The insulator 287 is provided over the insulator 283. The insulator 287 functions as an interlayer film and thus preferably has low relative permittivity. When a material with low relative permittivity is used for an interlayer film, parasitic capacitance generated between wirings can be reduced. As the insulator 287, a single layer or stacked layers of insulators containing any of the materials with low relative permittivity described in the above-described section [Insulator] can be used.

The concentration of impurities such as water and hydrogen in the insulator 287 is preferably reduced. This can inhibit entry of impurities such as water and hydrogen into the channel formation region of the oxide semiconductor 230.

Here, the conductor 245 and the conductor 246 function as plugs or wirings for electrically connecting the memory cell 150a and the memory cell 150b to a circuit element such as a switch, a transistor, a capacitor, an inductor, a resistor, or a diode, a wiring, an electrode, or a terminal. For example, the conductor 245 can be electrically connected to a sense amplifier (not illustrated) provided below the memory device illustrated in FIG. 23, and the conductor 246 can be electrically connected to a similar memory device (not illustrated) provided above the memory device illustrated in FIG. 23. In that case, the conductor 245 and the conductor 246 function as part of the wiring BL. When the memory device or the like is provided above or below the memory device illustrated in FIG. 23 in this manner, the memory capacity per unit area can be increased.

The memory cell 150a and the memory cell 150b have a line-symmetric structure with a perpendicular bisector of the dashed-dotted line A1-A2 as the symmetric axis. Thus, the transistor 200a and the transistor 200b are also placed symmetrically with the conductor 245 and the conductor 246 therebetween. Here, the conductor 240 has a function of the other of the source electrode and the drain electrode of the transistor 200a and a function of one of a source electrode and a drain electrode of the transistor 200b. The transistor 200a and the transistor 200b share the conductor 245 and the conductor 246 functioning as plugs. Accordingly, when the two transistors and the plug are connected as described above, a memory device that can be miniaturized or highly integrated can be provided.

Note that the conductor 110 functioning as the wiring PL may be provided in each of the memory cell 150a and the memory cell 150b or may be provided to be shared by the memory cell 150a and the memory cell 150b. However, as illustrated in FIG. 23B, the conductor 110 is provided to be apart from the conductor 245 so that the conductor 110 and the conductor 245 are not short-circuited.

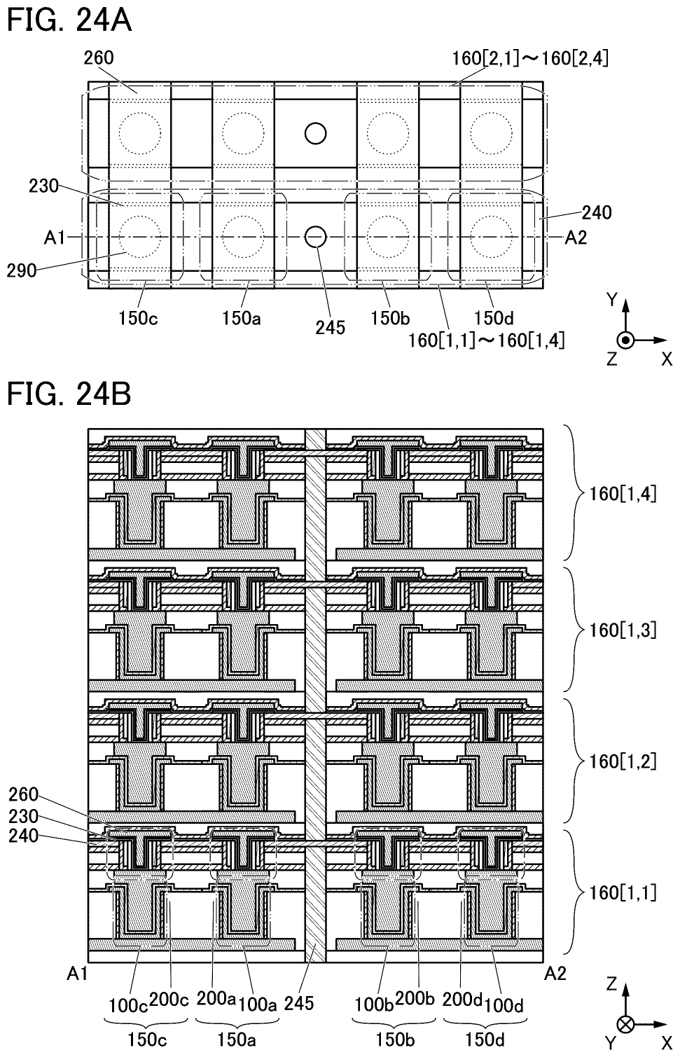

Note that the memory cells 150 can be three-dimensionally arranged in a matrix to form a memory cell array. As an example of the memory cell array, FIG. 24A and FIG. 24B illustrate an example of a memory device in which 4×2×4 memory cells 150 are arranged in the X direction, the Y direction, and the Z direction. FIG. 24A is a plan view of the memory device. In addition, FIG. 24B is a cross-sectional view of a portion indicated by the dashed-dotted line A1-A2 in FIG. 24A. For the sake of clarity of the drawing, some components are omitted in the plan view in FIG. 24A.

Here, the memory cell 150a to the memory cell 150d illustrated in FIG. 24A and FIG. 24B each have a structure similar to that of the memory cell 150. The memory cell 150a includes the capacitor 100a and the transistor 200a, the memory cell 150b includes the capacitor 100b and the transistor 200b, the memory cell 150c includes a capacitor 100c and a transistor 200c, and the memory cell 150d includes a capacitor 100d and a transistor 200d. Thus, in the memory device illustrated in FIG. 24A and FIG. 24B, components having the same functions as the components of the memory device illustrated in FIG. 22 are denoted by the same reference numerals.

Hereinafter, a memory device including the memory cell 150a to the memory cell 150d is referred to as a memory unit. The memory device illustrated in FIG. 24A and FIG. 24B each include a memory unit 160[1,1] to a memory unit 160[2,4]. Hereinafter, the memory unit 160[1,1] to the memory unit 160[2,4] are collectively referred to as a memory unit 160 in some cases. The memory unit 160[1,2] is provided over the memory unit 160[1,1], the memory unit 160[1,3] is provided over the memory unit 160[1,2], and the memory unit 160[1,4] is provided over the memory unit 160[1,3]. The memory unit 160[2,1] is provided to be adjacent to the memory unit 160[1,1] in the Y direction. The memory unit 160[2,2] is provided over the memory unit 160[2, 1], the memory unit 160[2,3] is provided over the memory unit 160[2,2], and the memory unit 160[2,4] is provided over the memory unit 160[2,3].

In the memory unit 160, as illustrated in FIG. 24B, the memory cell 150c is placed outside the memory cell 150a with the conductor 245 as the center, and the memory cell 150d is placed outside the memory cell 150b. In other words, the memory unit 160 can be regarded as a memory device in which the memory cell 150c is provided adjacent to the memory cell 150a and the memory cell 150d is provided adjacent to the memory cell 150b in the memory device illustrated in FIG. 23.

As illustrated in FIG. 24A and FIG. 24B, the conductor 260 functioning as the wiring WL is shared by the memory cells 150 adjacent to each other in the Y direction. The conductor 240 functioning as part of the wiring BL is shared in the same memory unit. That is, the conductor 240 is in contact with the oxide semiconductor 230 of each of the memory cell 150a to the memory cell 150d.

The conductor 245 is provided between the conductors 240 included in the memory units adjacent to each other in the Z direction. For example, as illustrated in FIG. 24B, the conductor 245 is provided in contact with the top surface of the conductor 240 of the memory unit 160[1,1] and the bottom surface of the conductor 240 of the memory unit 160[1,2]. In this manner, the conductor 240 and the conductor 245 provided in the memory unit 160 form the wiring BL. The conductor 245 is electrically connected to a sense amplifier (not illustrated) provided below the memory device illustrated in FIG. 24. As described above, when a plurality of memory units are stacked in the memory device illustrated in FIG. 24, the memory capacity per unit area can be increased.

The memory cell 150a and the memory cell 150c are line-symmetrical to the memory cell 150b and the memory cell 150d with a perpendicular bisector of the dashed-dotted line A1-A2 as the symmetric axis. Thus, the transistor 200a and the transistor 200c are also arranged symmetrically to the transistor 200b and the transistor 200d with the conductor 245 therebetween. Here, the conductor 240 serves as the other of the source electrode and the drain electrode of each of the transistor 200a to the transistor 200d. The transistor 200a to the transistor 200d share the conductor 245 functioning as a plug. Accordingly, when the four transistors are connected to the plug as described above, a memory device that can be miniaturized or highly integrated can be provided.

When a plurality of memory cells are stacked as illustrated in FIG. 24A and FIG. 24B, cells can be integrated without increasing the occupation area of the memory cell array. In other words, a 3D memory cell array can be formed. Although FIG. 24A and FIG. 24B illustrate the structure in which four layers each including two memory units are stacked, the present invention is not limited to the structure. The memory device may include one layer including at least one memory cell 150 or may include two or more stacked layers each including at least one memory cell 150.

FIG. 24A and FIG. 24B illustrate a structure in which the conductor 245 functioning as a plug is placed between the memory cells 150. In other words, the conductor 245 functioning as a plug is placed inside the memory unit 160. Note that the present invention is not limited to the structure. The conductor 245 may be placed outside the memory unit.

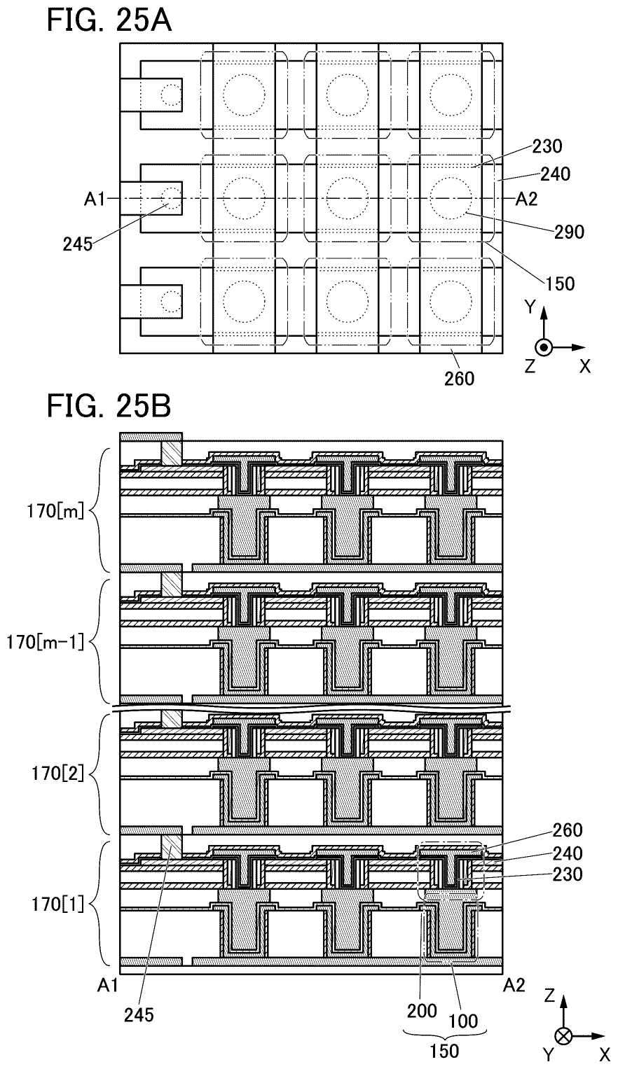

As an example of the memory cell array, FIG. 25A and FIG. 25B illustrate an example of a memory device in which 3×3×4 memory cells 150 are arranged in the X direction, the Y direction, and the Z direction. FIG. 25A is a plan view of a memory device. FIG. 25B is a cross-sectional view of a portion indicated by the dashed-dotted line A1-A2 in FIG. 25A. For the sake of clarity of the drawing, some components are omitted in the plan view of FIG. 25A.

The memory device illustrated in FIG. 25A and FIG. 25B has a structure in which m layers (m is an integer greater than or equal to 2) each including the memory cells 150 are stacked. Here, in FIG. 25B, the layer provided in the first layer (the lowermost layer) is referred to as a layer 170[1], the layer provided in the second layer is referred to as a layer 170[2], the layer provided in the (m−1)-th layer is referred to as a layer 170[m−1], and the layer provided in the m-th layer (the uppermost layer) is referred to as a layer 170[m]. In other words, the memory device of one embodiment of the present invention may include a plurality of layers including memory cells 150 and have a structure in which the plurality of layers are stacked.

As illustrated in FIG. 25A and FIG. 25B, the conductor 245 may be provided outside the memory unit. The conductor 245 may be electrically connected to a wiring provided in a layer above the layer including the conductor 245. For example, the conductor 245 provided in the layer 170[1] is electrically connected to a wiring provided in the layer 170[2]. In addition, the wiring provided in the layer 170[2] is provided in the same layer as the lower electrode (the conductor 110) of the memory cell 150 included in the layer 170[2]. That is, the wiring can be formed in the same step as the conductor 110.

Although FIG. 25A and FIG. 25B illustrates a structure in which the conductor 245 is electrically connected to a wiring provided in a layer above the layer including the conductor 245, the present invention is not limited thereto. For example, the conductor 245 may be electrically connected to a wiring provided in the layer including the conductor 245. For example, the conductor 245 provided in the layer 170[1] may be electrically connected to a wiring provided in the layer 170[1]. The wiring provided in the layer 170[1] is provided in the same layer as the lower electrode (the conductor 110) of the memory cell 150 included in the layer 170[1]. In other words, the wiring can be formed in the same step as the conductor 110.

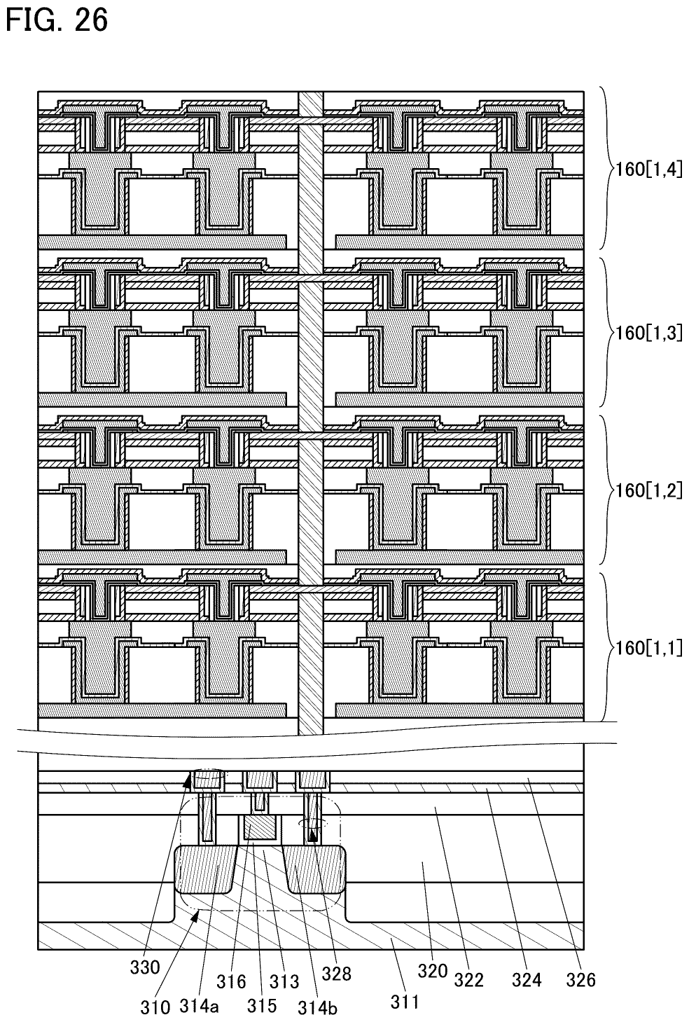

A driver circuit may be provided below the memory device. For example, FIG. 26 illustrates a structure in which a layer functioning as a driver circuit is provided below the memory device illustrated in FIG. 24B. With such a structure in which a driver circuit is provided below the memory device, the area of the memory device can be increased and the memory capacity of the memory device can be increased.

FIG. 26 illustrates a transistor 310 included in a driver circuit as an example. The transistor 310 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. The transistor 310 can be a p-channel transistor or an n-channel transistor. As the substrate 311, a single crystal silicon substrate can be used, for example.

Here, in the transistor 310 illustrated in FIG. 26, the semiconductor region 313 (part of the substrate 311) in which a channel is formed has a protruding shape. Furthermore, the conductor 316 is provided to cover the side and top surfaces of the semiconductor region 313 with the insulator 315 therebetween. Note that the conductor 316 may be formed using a material for adjusting the work function. The transistor 310 is also referred to as a Fin-type transistor because it utilizes a protruding portion of the semiconductor substrate. An insulator functioning as a mask for forming the protruding portion may be provided in contact with the upper portion of the protruding portion. Although the case where the protruding portion is formed by processing part of the semiconductor substrate is described here, a semiconductor film having a protruding shape may be formed by processing an SOI substrate.

Note that the transistor 310 illustrated in FIG. 26 is an example and the structure is not limited thereto; an appropriate transistor can be used in accordance with a circuit structure or a driving method.

A wiring layer provided with an interlayer film, a wiring, a plug, and the like may be provided between the memory device and the driver circuit. A plurality of wiring layers can be provided in accordance with the design. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are sequentially stacked over the transistor 310 as interlayer films. A conductor 328 and the like are embedded in the insulator 320 and the insulator 322. A conductor 330 and the like are embedded in the insulator 324 and the insulator 326. Note that the conductor 328 and the conductor 330 function as a contact plug or a wiring.

The insulator functioning as an interlayer film may function as a planarization film that covers an uneven shape thereunder. For example, the top surface of the insulator 322 may be planarized through planarization treatment using a CMP method to increase the level of planarity.

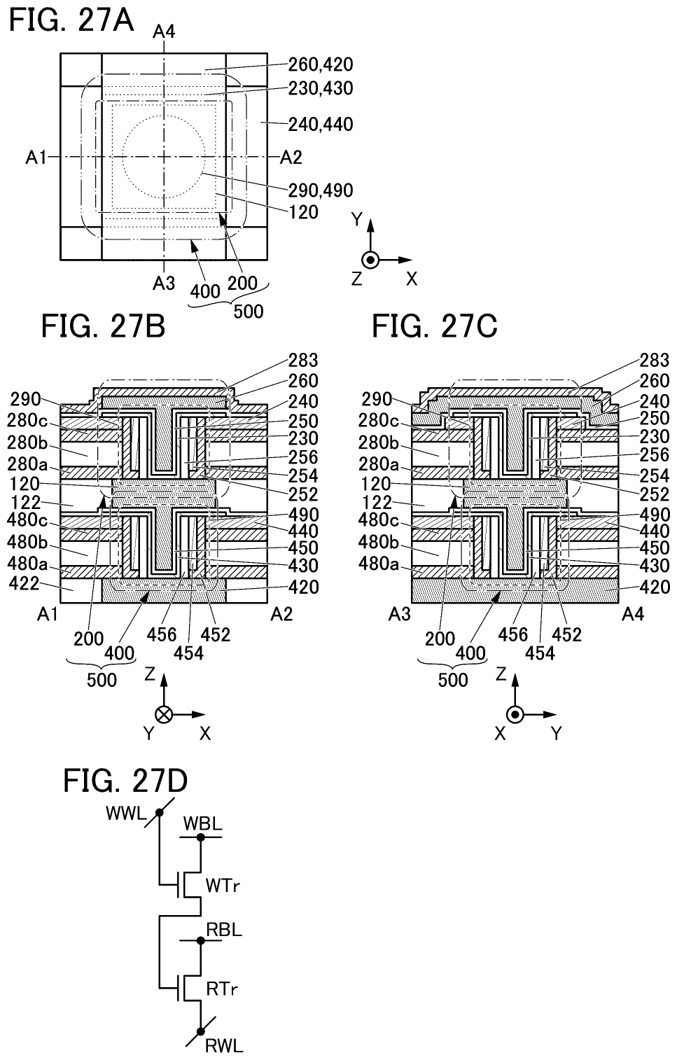

Although the memory cell 150 includes the capacitor 100 and the transistor 200 over the capacitor 100 in the above memory device, the present invention is not limited thereto. For example, as illustrated in FIG. 27, the memory cell can include two stacked transistors.

FIG. 27A to FIG. 27C are a plan view and cross-sectional views of a memory device including the transistor 200 and a transistor 400. FIG. 27A is a plan view of the memory device. FIG. 27B and FIG. 27C are cross-sectional views of the memory device. FIG. 27B is a cross-sectional view of a portion indicated by the dashed-dotted line A1-A2 in FIG. 27A. FIG. 27C is a cross-sectional view of a portion indicated by the dashed-dotted line A3-A4 in FIG. 27A. For the sake of clarity of the drawing, some components are omitted in the plan view of FIG. 27A.

A memory cell 500 includes the transistor 400 and the transistor 200 over the transistor 400. The structure of the transistor 400 and the structures in the vicinity thereof are similar to the structure of the transistor 200 and the structures in the vicinity thereof.

Thus, an insulator 422 corresponds to the insulator 122; a conductor 420 corresponds to the conductor 120; an insulator 480a corresponds to the insulator 280a; an insulator 480b corresponds to the insulator 280b; an insulator 480c corresponds to the insulator 280c; an oxide semiconductor 430 corresponds to the oxide semiconductor 230; an insulator 450 corresponds to the insulator 250; a conductor 440 corresponds to the conductor 240; an insulator 452 corresponds to the insulator 252; an insulator 454 corresponds to the insulator 254; an insulator 456 corresponds to the insulator 256; and an opening portion 490 corresponds to the opening portion 290. The structure of the transistor 200 and the structures in the vicinity thereof can be referred to for the structure of the transistor 400 and the structures in the vicinity thereof.

The conductor 120 functions as one of a source and a drain of the transistor 200 and as a gate of the transistor 400.

FIG. 27D is a circuit diagram corresponding to the memory cell 500. The memory cell illustrated in FIG. 27D includes a transistor WTr and a transistor RTr. Here, the transistor WTr corresponds to a transistor WTr0 and the transistor RTr corresponds to a transistor RTr0.

As illustrated in FIG. 27D, in the memory cell 500, a gate of the transistor RTr is electrically connected to a wiring WWL, one of a source and a drain thereof is electrically connected to a wiring WBL, and the other of the source and the drain thereof is electrically connected to a gate of the transistor WTr. One of a source and a drain of the transistor WTr is electrically connected to a wiring RBL, and the other of the source and the drain thereof is electrically connected to a wiring RWL. The wiring WWL functions as a write word line, the wiring WBL functions as a write bit line, the wiring RBL functions as a read bit line, and the wiring RWL functions as a read word line.

Here, the gate capacitance of the transistor WTr is used as a storage capacitance. That is, the memory cell 500 can be regarded as a capacitor-less memory cell. Thus, the memory cell 500 can also be regarded as a gain-cell memory cell (2Tr0C) that consists of two transistors and does not include a capacitor. Note that without limitation to this structure, a structure including a capacitor and two transistors (2Tr1C) may be employed, and the capacitor may be electrically connected to the gate of the transistor WTr. The above-described capacitor 100 can be used as the capacitor.

When the OS transistor is used as the transistor RTr and the transistor RTr is brought into the off state, charge at a node where one of the source and the drain of the transistor RTr is electrically connected to the gate of the transistor WTr can be retained for an extremely long time. Accordingly, a memory cell with an extremely long refresh interval or a nonvolatile memory cell can be obtained.

According to one embodiment of the present invention, a novel transistor, a novel semiconductor device, and a novel memory device can be provided. A memory device that can be miniaturized or highly integrated can be provided. A memory device having favorable reliability can be provided. A memory device with favorable frequency characteristics can be provided. A memory device with high operating speed can be provided. A memory device with low power consumption can be provided. A memory device including a transistor with high on-state current can be provided. A memory device with a small variation in transistor characteristics can be provided. A memory device having favorable electrical characteristics can be provided.

The memory cell 150 including the transistor 200 and the capacitor 100 described in this embodiment can be used as a memory cell of the memory device. The transistor 200 is a transistor in which a channel is formed in a semiconductor layer including an oxide semiconductor. Since the transistor 200 has a low off-state current, a memory device that uses the transistor 200 can retain stored contents for a long time. In other words, such a memory device does not require refresh operation or has extremely low frequency of the refresh operation, which leads to a sufficient reduction in power consumption of the memory device. The transistor 200 also has high frequency characteristics and thus enables high-speed reading and writing of the memory device.

At least part of the structure, method, and the like described in this embodiment can be implemented in appropriate combination with any of the other embodiments described in this specification.

### Embodiment 2

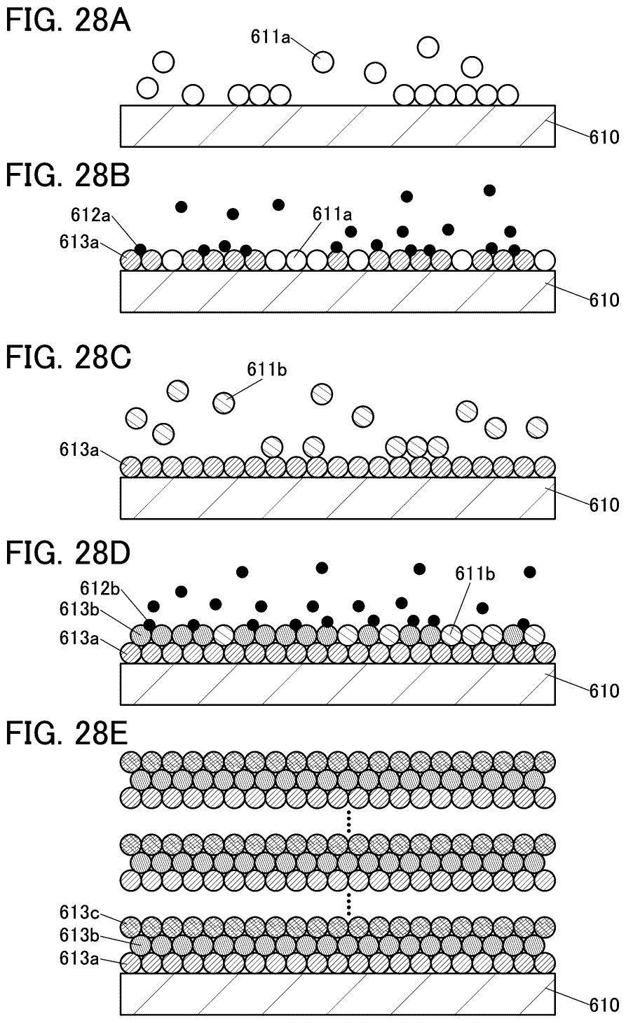

In this embodiment, a metal oxide (hereinafter, also referred to as an oxide semiconductor or an oxide in some cases) usable for the semiconductor layer of the transistor described in the above embodiment and a formation method thereof are described with reference to FIG. 28 to FIG. 31.

In the semiconductor device of one embodiment of the present invention, it is preferable to use a metal oxide with high crystallinity for a metal oxide including a channel formation region. The crystal preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is a direction in which the plurality of layers are stacked.

For the formation of a metal oxide having the layered crystal structure, atomic layers are preferably deposited one by one. For example, an ALD (Atomic Layer Deposition) method can be used as the formation method of the metal oxide.

In an ALD method, atomic layers can be deposited one by one. Hence, an ALD method has effects such as deposition of an extremely thin film, deposition of a film on a structure with a high aspect ratio, deposition of a film with a small number of defects such as pinholes, deposition of a film with excellent coverage, and deposition of a film at a low temperature. An ALD method includes a thermal ALD method, which is a formation method using heat, and a plasma ALD method, which is a formation method using plasma. The use of plasma is sometimes preferable because deposition at a lower temperature is possible. Note that a precursor used in an ALD method sometimes contains an element such as carbon or chlorine. Thus, in some cases, a film provided by an ALD method contains a larger amount of an element such as carbon or chlorine than a film provided by another formation method. These elements can be quantified by X-ray Photoelectron Spectroscopy (XPS) or Secondary Ion Mass Spectrometry (SIMS).

Unlike a formation method in which particles ejected from a target or the like are deposited, an ALD method is a formation method in which a film is formed by reaction at a surface of an object. Thus, an ALD method is a formation method that enables favorable step coverage almost regardless of the shape of an object to be processed. In particular, an ALD method enables excellent step coverage and excellent thickness uniformity and thus is suitable for covering a surface of an opening portion with a high aspect ratio, for example.

### <Formation Method of Metal Oxide by ALD Method>

Here, a method for depositing a metal oxide by an ALD method that can be used in one embodiment of the present invention is described.

An example of depositing a metal oxide having the layered crystal structure including three layers by an ALD method is described with reference to FIG. 28A to FIG. 28E. First, precursors 611a are introduced into a chamber and the precursors 611a are adsorbed onto a surface of a substrate 610 (see FIG. 28A; hereinafter, the step is referred to as a first step in some cases). Here, as illustrated in FIG. 28A, the precursors 611a are adsorbed onto the surface of the substrate 610, whereby a self-limiting mechanism of surface chemical reaction works and no more precursors 611a are adsorbed onto a layer of the precursor 611a over the substrate 610. In addition, the proper range of substrate temperatures at which the self-limiting mechanism of surface chemical reaction works is also referred to as an ALD Window. The ALD Window is determined by the temperature characteristics, vapor pressure, decomposition temperature, and the like of a precursor and is sometimes set to higher than or equal to 100° C. and lower than or equal to 600° C., preferably higher than or equal to 200° C. and lower than or equal to 400° C., for example.

Next, an inert gas (e.g., argon, helium, or nitrogen) or the like is introduced into the chamber, so that a surplus of the precursors 611a, a reaction product, and the like are released from the chamber (hereinafter, the step is referred to as a second step in some cases). Instead of introduction of an inert gas into the chamber, vacuum evacuation may be performed to release surplus precursors, a reaction product, and the like from the chamber. The second step is also called purge.

Next, a reactant 612a (e.g., an oxidizer (ozone (O₃), oxygen (O₂), water (H₂O), and plasma, a radical, and an ion thereof)) is introduced into the chamber to react with the precursor 611a adsorbed onto the surface of the substrate 610, whereby part of components contained in the precursor 611a is released while the component molecules of the precursor 611a are kept adsorbed onto the substrate 610 (see FIG. 28B; hereinafter, the step is referred to as a third step in some cases). Thus, a layer of an oxide 613a, which is formed by oxidation of part of the precursor 611a, is formed on the surface of the substrate 610.

Next, introduction of an inert gas or vacuum evacuation is performed, whereby a surplus of the reactant 612a, a reaction product, or the like are released from the chamber (hereinafter, the step is referred to as a fourth step in some cases).

Then, a precursor 611b containing a metal element different from that in the precursor 611a is introduced and a step similar to the first step is performed, so that the precursor 611b is adsorbed onto a surface of the layer of the oxide 613a (see FIG. 28C). Here, as illustrated in FIG. 28C, the precursor 611b is adsorbed onto the layer of the oxide 613a, whereby a self-limiting mechanism of surface chemical reaction works and no more precursor 611b is adsorbed onto a layer of the precursor 611b over the substrate 610.

Next, as in the second step, by introduction of an inert gas or vacuum evacuation, a surplus of the precursor 611b, a reaction product, and the like are released from the chamber.

Next, as in the third step, the reactant 612b is introduced into the chamber. Here, the reactant 612b that is the same as or different from the reactant 612a may be used (see FIG. 28D). Thus, a layer of an oxide 613b, which is formed by oxidation of part of the precursor 611b, is formed over the layer of the oxide 613a.

Then, as in the fourth step, by introduction of an inert gas or vacuum evacuation, a surplus of the reactant 612b, a reaction product, and the like are released from the chamber.

Furthermore, the first to fourth steps are performed in a similar manner, so that a layer of an oxide 613c can be formed over the layer of the oxide 613b. As described above, by performing the steps for forming the oxide 613a to the oxide 613c repeatedly, a metal oxide having a layered crystal structure in which the stacked-layer structure including the oxide 613a to the oxide 613c is repeated can be formed (see FIG. 28E). That is, an oxide layer can be formed through the first to fourth steps, which are regarded as one set, and by repeating the set, a layered crystal structure in which a plurality of oxide layers are stacked can be formed.

Note that the thickness of the metal oxide having a layered crystal structure is greater than or equal to 1 nm and less than 100 nm, preferably greater than or equal to 3 nm and less than 20 nm.

In the formation of a metal oxide having a layered crystal structure, it is preferable that the steps illustrated in FIG. 28 be performed while the substrate is being heated. The substrate temperature is higher than or equal to 200° C. and lower than or equal to 600° C., preferably higher than or equal to 300° C. and lower than or equal to the precursor decomposition temperature. In the case where deposition by an ALD method is performed with use of a plurality of different kinds of precursors, the substrate temperature is preferably lower than or equal to the lowest precursor decomposition temperature among the plurality of precursors. Accordingly, in deposition by an ALD method, the plurality of precursors that are used can be adsorbed onto an object (e.g., a substrate) without being decomposed.

By performing the deposition while the substrate is being heated in such a temperature range, an impurity such as hydrogen or carbon contained in the precursor, the reactant, and the like can be removed from the metal oxide in each of the step 1 to the step 4. For example, carbon in the metal oxide can be released as CO₂ and CO, and hydrogen in the metal oxide can be released as H₂O. Furthermore, metal atoms and oxygen atoms are rearranged concurrently with removal of the impurity, so that layers of oxides can be arranged orderly. Thus, a metal oxide having a layered crystal structure with high crystallinity can be formed.

In order to perform deposition while the substrate is being heated in the above temperature range, the decomposition temperature of a precursor used for the deposition is preferably high. For example, the precursor decomposition temperature is preferably higher than or equal to 200° C. and lower than or equal to 700° C., further preferably higher than or equal to 300° C. and lower than or equal to 600° C. As such a precursor having a high decomposition temperature, a precursor formed of an inorganic material (hereinafter, referred to as an inorganic precursor) is preferably used. In general, an inorganic precursor tends to have a higher decomposition temperature than a precursor formed of an organic material (hereinafter, referred to as an organic precursor); thus, some inorganic precursors have the ALD Window in the above temperature range. Moreover, an inorganic precursor does not contain an impurity such as hydrogen or carbon, which can prevent an increase in the concentration of an impurity such as hydrogen or carbon in a metal oxide to be deposited.

Furthermore, after the deposition of the metal oxide, heat treatment is preferably performed. In particular, the heat treatment is preferably performed without exposure to the air successively after the deposition by an ALD method. The heat treatment is performed at a temperature higher than or equal to 100° C. and lower than or equal to 1200° C., preferably higher than or equal to 200° C. and lower than or equal to 1000° C., further preferably higher than or equal to 250° C. and lower than or equal to 650° C., still further preferably higher than or equal to 300° C. and lower than or equal to 600° C., still further preferably higher than or equal to 400° C. and lower than or equal to 550° C., still further preferably higher than or equal to 420° C. and lower than or equal to 480° C. Note that the heat treatment is performed in a nitrogen gas or inert gas atmosphere, or an atmosphere containing an oxidizing gas at 10 ppm or more, 1% or more, or 10% or more. The heat treatment may be performed under reduced pressure. Alternatively, it is acceptable that after heat treatment is performed in a nitrogen gas or inert gas atmosphere, heat treatment is performed in an atmosphere containing an oxidizing gas at 10 ppm or more, 1% or more, or 10% or more in order to compensate for released oxygen.

By performing heat treatment in such a manner, an impurity such as hydrogen or carbon contained in the metal oxide can be removed. For example, carbon in the metal oxide can be released as CO₂ and CO, and hydrogen in the metal oxide can be released as H₂O. Furthermore, metal atoms and oxygen atoms are rearranged concurrently with removal of the impurity, which can improve crystallinity. Thus, a metal oxide having a layered crystal structure with high crystallinity can be formed.

After the deposition of the metal oxide, microwave treatment is preferably performed in an oxygen-containing atmosphere so that the impurity concentration in the metal oxide can be reduced. Specific examples of the impurity include hydrogen and carbon. The above-describe example in which the microwave treatment in an oxygen-containing atmosphere is performed on the metal oxide is a non-limiting example. For example, the microwave treatment in an oxygen-containing atmosphere may be performed on an insulating film, specifically a silicon oxide film, which is positioned in the vicinity of the metal oxide.

Note that FIG. 28 illustrates the structure in which the stacked-layer structure including the oxide 613a to the oxide 613c is repeated; however, the present invention is not limited to the structure. For example, a single layer, two layers, or four or more layers of oxides may be repeatedly formed in a metal oxide.

In the description of this specification and the like, in the case of using ozone, oxygen, and water as a reactant or an oxidizer, not only those in gas or molecular states but also those in a plasma state, a radical state, and an ion state are included, unless otherwise specified. In the case where a film is deposited using an oxidizer having a plasma state, a radical state, or an ion state, a radical ALD apparatus or a plasma ALD apparatus, which will be described later, may be used.

In order to remove an impurity such as carbon or hydrogen contained in a precursor, the precursor is preferably made to react with an oxidizer sufficiently. For example, pulse time for introducing an oxidizer may be made longer. Alternatively, an oxidizer may be introduced multiple times. In the case where an oxidizer is introduced multiple times, the same kind of oxidizer may be introduced or different kinds of oxidizers may be introduced. For example, after water is introduced as a first oxidizer to the chamber, vacuum evacuation may be performed, ozone or oxygen which does not contain hydrogen may be introduced as a second oxidizer to the chamber, and vacuum evacuation may be performed.

In this manner, the introduction of an oxidizer and the introduction of an inert gas (or vacuum evacuation) in the chamber are repeated multiple times in a short time, whereby excess hydrogen atoms, carbon atoms, chlorine atoms, and the like can be more certainly removed from the precursor adsorbed onto the substrate surface, and can be released to the outside of the chamber. When the number of the kinds of the oxidizer is increased to two, more excess hydrogen atoms and the like can be removed from the precursor adsorbed onto the substrate surface. In this manner, hydrogen atoms are prevented from being taken into the film during the deposition, so that water, hydrogen, and the like contained in the formed film can be reduced.

An ALD method is a formation method in which deposition is performed through reaction of a precursor and a reactant using thermal energy. A temperature required for the reaction between the precursor and the reactant is determined by their temperature characteristics, vapor pressure, decomposition temperature, and the like and is set to higher than or equal to 100° C. and lower than or equal to 600° C., preferably higher than or equal to 200° C. and lower than or equal to 600° C., further preferably higher than or equal to 300° C. and lower than or equal to 600° C.

Moreover, an ALD method in which treatment is performed by introducing a plasma-excited reactant into the chamber as a third source gas in addition to the precursor and the reactant which react with each other is referred to as a plasma ALD method in some cases. In this case, a plasma generation apparatus is provided in the introduction portion of the third source gas. Inductively coupled plasma (ICP) can be used for plasma generation. On the other hand, an ALD method in which reaction between the precursor and the reactant is performed using thermal energy is sometimes referred to as a thermal ALD method.

In a plasma ALD method, deposition is performed by introducing a plasma-excited reactant in the third step. Alternatively, deposition is performed in way in which the first step to the fourth step are repeated while a plasma-excited reactant (a second reactant) is introduced. In this case, the reactant introduced in the third step is referred to as a first reactant. In the plasma ALD method, a material similar to the above-described oxidizer can be used for the second reactant used as the third source gas. In other words, plasma-excited ozone, oxygen, and water can be used as the second reactant. Other than oxidizer, a nitriding agent may be used as the second reactant. As the nitriding agent, nitrogen (N₂) or ammonia (NH₃) can be used. A mixed gas of nitrogen (N₂) and hydrogen (H₂) can also be used as the nitriding agent. For example, a mixed gas of nitrogen (N₂) of 5% and hydrogen (H₂) of 95% can be used as the nitriding agent. Deposition is performed while plasma-excited nitrogen or ammonia is introduced, whereby a nitride film such as a metal nitride film can be formed.

Argon (Ar), helium (He), or nitrogen (N₂) may be used as a carrier gas for the second reactant. The use of a carrier gas such as argon, helium, or nitrogen is preferable because plasma is easily discharged and the plasma-excited second reactant is easily generated. In the case where an oxide film such as a metal oxide film is formed by a plasma ALD method and nitrogen is used as a carrier gas, nitrogen enters the film and a desired film quality cannot be obtained in some cases. In that case, argon or helium is preferably used as the carrier gas.

An ALD method enables an extremely thin film with a uniform thickness to be deposited. In addition, the ALD method enables high surface coverage on an uneven surface.

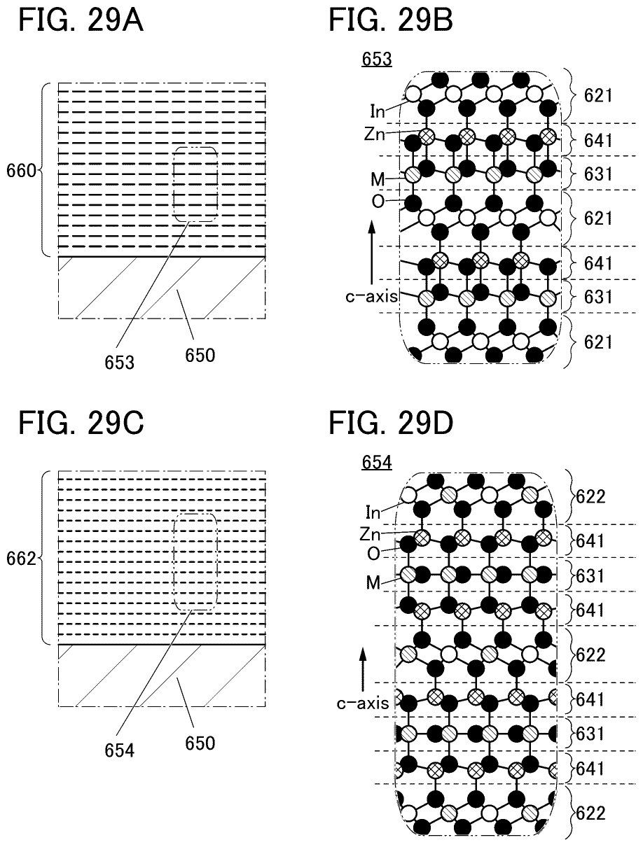

Here, atomic arrangement in the crystal when the metal oxide having a layered crystal structure is an In-M-Zn oxide is described with reference to FIG. 29A to FIG. 29D. In FIG. 29B and FIG. 29D, an atom is represented by a sphere (a circle) and a bond between a metal atom and an oxygen atom is represented by a line. In FIG. 29B and FIG. 29D, the c-axis direction in the crystal structure of the In-M-Zn oxide is indicated by the arrows in the drawings. The a-b plane direction in the crystal structure of the In-M-Zn oxide is the direction perpendicular to the c-axis direction indicated by the arrows in FIG. 29B and FIG. 29D.

FIG. 29A is a diagram illustrating an oxide 660 including an In-M-Zn oxide formed over a structural element 650. Here, the structural element refers to a component included in a semiconductor device such as a transistor. The structural element 650 includes a substrate, conductors such as a gate electrode, a source electrode, and a drain electrode, an insulator such as a gate insulating film, an interlayer insulating film, and a base insulating film, a semiconductor such as a metal oxide or silicon, and the like. In FIG. 29A, a formation surface of the structural element 650 is placed in parallel with a substrate (or a base, not illustrated).

FIG. 29B is an enlarged view illustrating the atomic arrangement in the crystal in a region 653, which is part of the oxide 660 in FIG. 29A. The composition of the oxide 660 illustrated in FIG. 29A and FIG. 29B is In:M:Zn=1:1:1 [atomic ratio], and the crystal structure is a YbFe₂O₄ type structure. The element M is a metal element having a valence of +3.

As illustrated in FIG. 29B, the crystal included in the oxide 660 has repetitive stacking of a layer 621 containing indium (In) and oxygen, a layer 631 containing the element M and oxygen, and a layer 641 containing zinc (Zn) and oxygen in this order. The layer 621, the layer 631, and the layer 641 are placed substantially parallel to the formation surface of the structural element 650. That is, the a-b plane of the oxide 660 is substantially parallel to the formation surface of the structural element 650, and the c-axis of the oxide 660 is substantially parallel to the normal direction of the formation surface of the structural element 650.

When the layer 621, the layer 631, and the layer 641 included in the above crystal are each composed of one metal element and oxygen as illustrated in FIG. 29B, arrangement with favorable crystallinity is achieved to increase the mobility of the metal oxide.

Note that the In-M-Zn oxide with In:M:Zn=1:1:1 [atomic ratio] is not limited to the structure illustrated in FIG. 29B. The stacking order of the layer 621, the layer 631, and the layer 641 may be changed. For example, the layer 621, the layer 641, and the layer 631 may be stacked repeatedly in this order. Alternatively, the layer 621, the layer 631, the layer 641, the layer 621, the layer 641, and the layer 631 may be stacked repeatedly in this order. Part of the element M in the layer 631 may be replaced with zinc, and part of zinc in the layer 641 may be replaced with the element M.

Although an example of forming the In-M-Zn oxide whose composition is In:M:Zn=1:1:1 [atomic ratio] is described above, a crystalline In-M-Zn oxide whose composition formula is represented by In_{(1+α)}M_{(1-α)}O₃(ZnO)ₘ (α is a real number greater than 0 and less than 1 and m is a positive number) can have a layered crystal structure in a similar manner. As an example, an In-M-Zn oxide with In:M:Zn=1:3:4 [atomic ratio] is described with reference to FIG. 29C and FIG. 29D.

FIG. 29C is a diagram illustrating an oxide 662 including an In-M-Zn oxide formed over the structural element 650. FIG. 29D is an enlarged view illustrating the atomic arrangement in the crystal in a region 654, which is part of the oxide 662 in FIG. 29C.

As illustrated in FIG. 29D, the crystal included in the oxide 662 includes a layer 622 containing indium (In), the element M, and oxygen, the layer 641 containing zinc (Zn) and oxygen, and the layer 631 containing the element M and oxygen. In the oxide 662, the plurality of layers are stacked repeatedly in the order of the layer 622, the layer 641, the layer 631, and the layer 641. The layer 622, the layer 631, and the layer 641 are placed substantially parallel to the formation surface of the structural element 650. That is, the a-b plane of the oxide 662 is substantially parallel to the formation surface of the structural element 650, and the c-axis of the oxide 662 is substantially parallel to the normal direction of the formation surface of the structural element 650.

Note that the In-M-Zn oxide with In:M:Zn=1:3:4 [atomic ratio] is not limited to the structure illustrated in FIG. 29D, and the structure may change in a range where In:M:Zn=1:3:4 [atomic ratio] is satisfied. The stacking order of the layer 622, the layer 631, and the layer 641 may be changed, for example. Part of the element M in the layer 631 may be replaced with zinc and part of zinc in the layer 641 may be replaced with the element M. The layer 621 or the layer 631 may be formed instead of the layer 622.

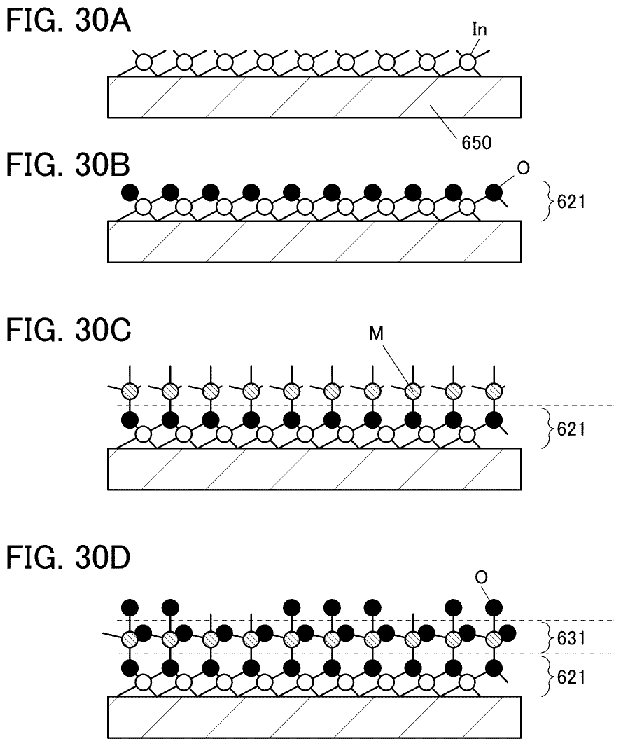

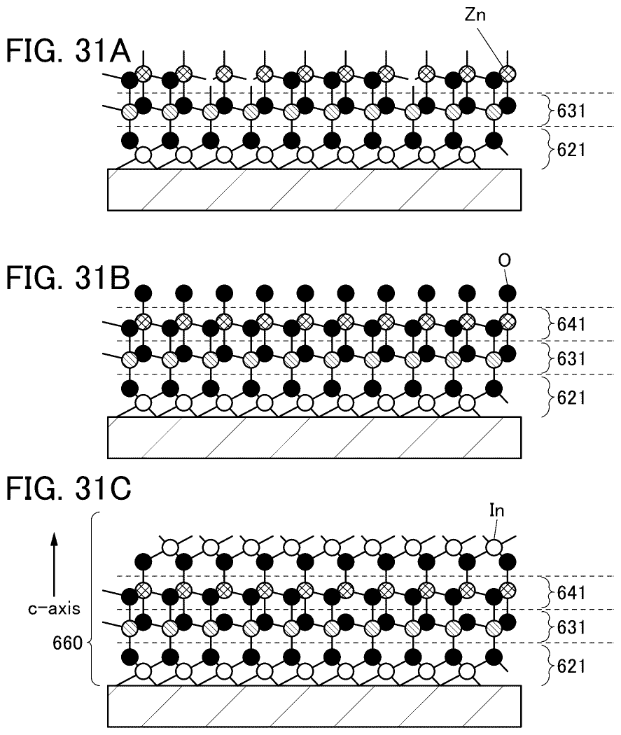

Next, details of a method for forming the oxide 660 including the In-M-Zn oxide illustrated in FIG. 29A and FIG. 29B are described with reference to FIG. 30A to FIG. 31C.

First, a source gas that contains a precursor containing indium is introduced into a chamber, so that the precursor is adsorbed onto the surface of the structural element 650 (see FIG. 30A). Here, the source gas contains a carrier gas such as argon, helium, or nitrogen in addition to the precursor. As the precursor containing indium, trimethylindium, triethylindium, tris(2,2,6,6-tetramethyl-3,5-heptanedionato) indium, cyclopentadienylindium, indium (III) acetylacetonate, (3-(dimethylamino) propyl)dimethylindium, or the like can be used.

As the precursor containing indium, an inorganic precursor not containing hydrocarbon may be used. As an inorganic precursor containing indium, a halogen-based indium compound such as indium trichloride, indium tribromide, or indium triiodide can be used. The decomposition temperature of indium trichloride is approximately higher than or equal to 500° C. and lower than or equal to 700° C. Thus, with use of indium trichloride, deposition by an ALD method can be performed while a substrate is being heated at approximately higher than or equal to 400° C. and lower than or equal to 600° C., for example, at 500° C.

Next, introduction of the source gas is stopped and the chamber is purged, so that a surplus precursor, a reaction product, and the like are released from the chamber.

Then, an oxidizer is introduced as a reactant into the chamber to react with the adsorbed precursor, and components other than indium are released while indium is adsorbed onto the substrate, so that the layer 621 in which indium and oxygen are bonded to each other is formed (see FIG. 30B). Ozone, oxygen, water, or the like can be used as the oxidizer. Then, introduction of the oxidizer is stopped and the chamber is purged, so that a surplus reactant, a reaction product, and the like are released from the chamber.

Subsequently, a source gas that contains a precursor containing the element M is introduced into the chamber, so that the precursor is adsorbed onto the layer 621 (see FIG. 30C). The source gas contains a carrier gas such as argon, helium, or nitrogen in addition to the precursor. In the case where gallium is used as the element M, trimethylgallium, triethylgallium, tris(dimethylamido)gallium, gallium (III) acetylacetonate, tris(2,2,6,6-tetramethyl-3,5-heptanedionato)gallium, dimethylchlorogallium, diethylchlorogallium, dimethyl gallium isopropoxide, or the like can be used as the precursor containing gallium.

As the precursor containing gallium, an inorganic precursor not containing hydrocarbon may be used. As an inorganic precursor containing gallium, a halogen-based gallium compound such as gallium trichloride, gallium tribromide, or gallium triiodide can be used. The decomposition temperature of gallium trichloride is approximately higher than or equal to 550° C. and lower than or equal to 700° C. Thus, with use of gallium trichloride, deposition by an ALD method can be performed while a substrate is being heated at approximately higher than or equal to 450° C. and lower than or equal to 650° C., for example, at 550° C.

Next, introduction of the source gas is stopped and the chamber is purged, so that a surplus precursor, a reaction product, and the like are released from the chamber.

Then, an oxidizer is introduced as a reactant into the chamber to react with the adsorbed precursor, and components other than the element M are released while the element M is adsorbed onto the substrate, so that the layer 631 in which the element M and oxygen are bonded to each other is formed (see FIG. 30D). At this time, part of oxygen included in the layer 641 may be adsorbed onto the layer 631. Then, introduction of the oxidizer is stopped and the chamber is purged, so that a surplus reactant, a reaction product, and the like are released from the chamber.

Subsequently, a source gas that contains a precursor containing zinc is introduced into the chamber, so that the precursor is adsorbed onto the layer 631 (see FIG. 31A). At this time, part of the layer 641 in which zinc is bonded to oxygen is formed in some cases. The source gas contains a carrier gas such as argon, helium, or nitrogen in addition to the precursor. Dimethylzinc, diethylzinc, bis(2,2,6,6-tetramethyl-3,5-heptanedionato) zinc, zinc acetate, or the like can be used as the precursor containing zinc.

As the precursor containing zinc, an inorganic precursor not containing hydrocarbon may be used. As an inorganic precursor containing zinc, a halogen-based zinc compound such as zinc dichloride, zinc dibromide, or zinc diiodide can be used. The decomposition temperature of zinc dichloride is approximately higher than or equal to 450° C. and lower than or equal to 700° C. Thus, with use of zinc dichloride, deposition by an ALD method can be performed while a substrate is being heated at approximately higher than or equal to 350° C. and lower than or equal to 550° C., for example, at 450° C.

Next, introduction of the source gas is stopped and the chamber is purged, so that a surplus precursor, a reaction product, and the like are released from the chamber.

Then, an oxidizer is introduced as a reactant into the chamber to react with the adsorbed precursor, and components other than zinc are released while zinc is adsorbed onto the substrate, so that the layer 641 in which zinc and oxygen are bonded to each other is formed (see FIG. 31B). After that, introduction of the oxidizer is stopped and the chamber is purged, so that a surplus reactant, a reaction product, and the like are released from the chamber.

Next, the layer 621 is formed again over the layer 641 by the above-described method (see FIG. 31C). By repeating the above-described method, the oxide 660 can be formed over the substrate or the structural element.

Some of the above-described precursors each containing the metal element further contain one or both of carbon and chlorine. A film that is formed using a precursor containing carbon may contain carbon. A film that is formed using a precursor containing halogen such as chlorine may contain halogen such as chlorine.

As described above, the oxide 660 is formed by an ALD method, whereby the metal oxide in which the c-axis is aligned substantially parallel to the normal direction of the formation surface can be formed. For example, in the oxide semiconductor 230 illustrated in FIG. 2B and FIG. 2C according to the above embodiment, a layered crystal substantially parallel to the sidewall of the opening portion 290, in particular, the side surface of the insulator 280, can be formed. With this structure, the layered crystals of the oxide semiconductor 230 are formed substantially parallel to the channel length direction of the transistor 200, so that the on-state current of the transistor can be increased.

The steps illustrated in FIG. 30A to FIG. 31C are preferably performed while the substrate is being heated. For example, the substrate temperature is set to higher than or equal to 200° C. and lower than or equal to 600° C., preferably higher than or equal to 300° C. and lower than or equal to the precursor decomposition temperature.

In order to perform deposition while the substrate is being heated in the above temperature range, the decomposition temperature of a precursor used for the deposition is preferably high. For example, the precursor decomposition temperature is preferably higher than or equal to 200° C. and lower than or equal to 700° C., further preferably higher than or equal to 300° C. and lower than or equal to 600° C. As such a precursor having a high decomposition temperature, an inorganic precursor is preferably used. In general, an inorganic precursor tends to have a higher decomposition temperature than an organic precursor, so that even when deposition is performed while the substrate is being heated as described above, the precursor is hardly decomposed.

As the inorganic precursor, for example, the above indium trichloride, gallium trichloride, or zinc dichloride can be used. As described above, the decomposition temperature of each of these precursors is approximately higher than or equal to 350° C. and lower than or equal to 700° C., which is much higher than the decomposition temperature of a general organic precursor. Note that as described above, the decomposition temperatures of indium trichloride, gallium trichloride, and zinc dichloride are different from each other. In the case where deposition is performed by an ALD method with use of a plurality of different kinds of precursors, the substrate temperature is preferably lower than or equal to the lowest precursor decomposition temperature among the plurality of precursors. In the above example, the substrate temperature is set within a range where zinc dichloride having the lowest precursor decomposition temperature is not decomposed. Accordingly, indium trichloride and gallium trichloride can also be adsorbed onto an object (e.g., a substrate) without being decomposed.

FIG. 30A to FIG. 31C illustrate an example in which the layer 621 is formed as a layer containing indium, the layer 631 is formed thereover as a layer containing the element M, and further, the layer 641 is formed thereover as a layer containing zinc; however, this embodiment is not limited to the example. One of the layer 631 and the layer 641 may be formed, the layer 621 may be formed thereover, and further, the other of the layer 631 and the layer 641 may be formed thereover. Alternatively, one of the layer 631 and the layer 641 may be formed, the other of the layer 631 and the layer 641 may be formed thereover, and further, the layer 621 may be formed thereover.

In the case of forming a metal oxide with an atomic ratio that is different from In:M:Zn=1:1:1 [atomic ratio], the above-described layer 621, layer 631, and layer 641 may be formed as appropriate in accordance with the atomic ratio. For example, the formation of the layer 641 may be repeated multiple times before and after the formation of the layer 631 illustrated in FIG. 31A so that a stack including the layers 631 and the layers 641 and having the desired numbers of atoms and layers and a desired thickness is formed between two layers 621.

### Embodiment 3

In this embodiment, specific structure examples of memory devices using the memory cell described in the above embodiment are described. This embodiment describes structure examples of memory devices in which stacked layers including memory cells and a layer including a functional circuit having functions of amplifying and outputting a data potential retained in a memory cell are provided.

### Structure Example of Memory Device

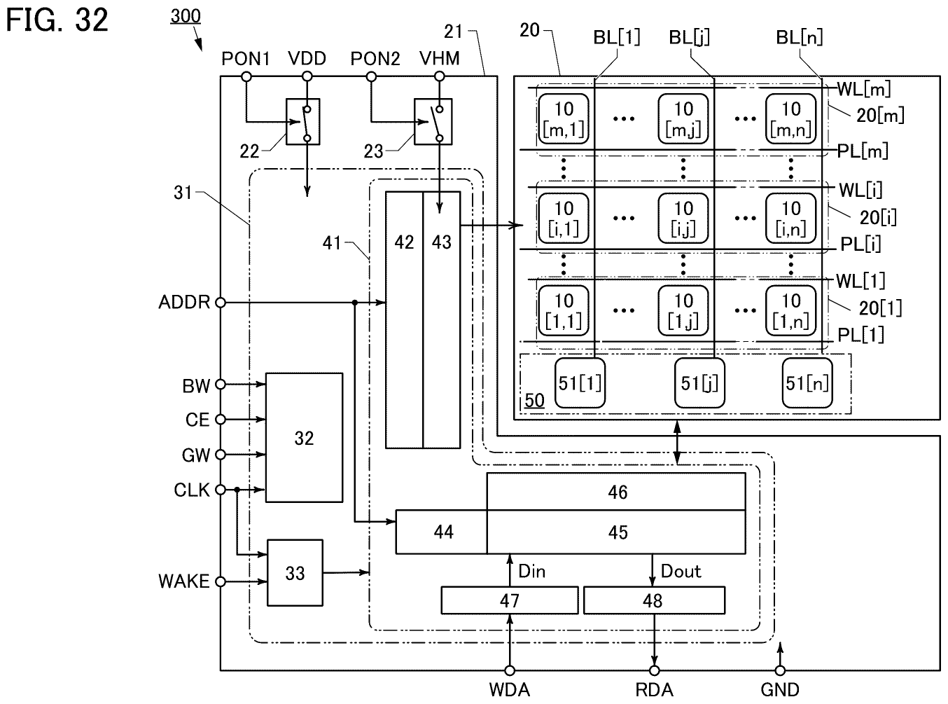

FIG. 32 is a block diagram illustrating a structure example of a memory device 300 of one embodiment of the present invention. The memory device 300 illustrated in FIG. 32 includes a driver circuit 21 and a memory array 20. The memory array 20 includes a functional layer 50 including a plurality of memory cells 10 and a plurality of functional circuits 51.

FIG. 32 illustrates an example in which the memory array 20 includes the plurality of memory cells 10 arranged in a matrix of m rows and n columns (m and n are each an integer greater than or equal to 2). The functional circuit 51 is provided for each of the wirings BL functioning as bit lines, for example. The plurality of functional circuits 51 corresponding to n wirings BL are provided in the example illustrated in FIG. 32.

In FIG. 32, the memory cell 10 in the first row and the first column is referred to as a memory cell 10[1,1], and the memory cell 10 in the m-th row and the n-th column is referred to as a memory cell 10[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 10 in the i-th row and the j-th column is referred to as a memory cell 10[i,j]. In this embodiment and the like, “i+a” (a is a positive or negative integer) is not below 1 and does not exceed m. Similarly, “j+a” is not below 1 and does not exceed n.

The memory array 20 includes m wirings WL extending in the row direction, m wirings PL extending in the row direction, and n wirings BL extending in the column direction. In this embodiment and the like, the first (first row) wiring WL is referred to as a wiring WL[1] and the m-th (m-th row) wiring WL is referred to as a wiring WL[m]. Similarly, the first (first row) wiring PL is referred to as a wiring PL[1] and the m-th (m-th row) wiring PL is referred to as a wiring PL[m]. Similarly, the first (first column) wiring BL is referred to as a wiring BL[1] and the n-th (n-th column) wiring BL is referred to as a wiring BL[n].

A plurality of memory cells 10 provided in the i-th row are electrically connected to the wiring WL in the i-th row (wiring WL[i]) and the wiring PL in the i-th row (wiring PL[i]). A plurality of memory cells 10 provided in the j-th column are electrically connected to the wiring BL in the j-th column (wiring BL[j]).

A DOSRAM (registered trademark) (Dynamic Oxide Semiconductor Random Access Memory) can be used in the memory array 20. A DOSRAM is a RAM that includes a 1T (transistor) 1C (capacitor) type memory cell and uses a transistor including an oxide semiconductor in a channel formation region (OS transistor) as an access transistor. The OS transistor has an extremely low current that flows between a source and a drain in an off state, that is, an extremely low leakage current. A DOSRAM can retain charge corresponding to data retained in a capacitor for a long time by turning off the access transistor (a non-conduction state). For this reason, the refresh operation frequency of a DOSRAM can be lower than that of a DRAM formed with a transistor containing silicon in its channel formation region (hereinafter also referred to as “Si transistor”). As a result, power consumption can be reduced.

The memory cells 10 can be stacked by stacking OS transistors as described in Embodiment 1 and the like. For example, in the memory array 20 illustrated in FIG. 32, a plurality of memory arrays 20[1] to 20[m] can be stacked. When the memory arrays 20[1] to 20[m] included in the memory array 20 are provided in a direction perpendicular to a surface of the substrate provided with the driver circuit 21, the memory density of the memory cells 10 can be increased. The memory array 20 can be formed by repeating the same manufacturing process in the perpendicular direction. The manufacturing cost of the memory array 20 in the memory device 300 can be reduced.

The wiring BL functions as a bit line for writing and reading data. The wiring WL functions as a word line for controlling on or off (a conduction state or a non-conduction state) of the access transistor serving as a switch. The wiring PL has a function of a constant potential line connected to a capacitor.

The memory cell 10 included in each of the memory arrays 20[1] to 20[m] is connected to the functional circuit 51 through the wiring BL. The wiring BL can be provided in the direction perpendicular to the surface of the substrate provided with the driver circuit 21. Since the wiring BL provided to extend from the memory cells 10 included in the memory arrays 20[1] to 20[m] is provided in the direction perpendicular to the surface of the substrate, the length of the wiring between the memory array 20 and the functional circuit 51 can be shortened. Accordingly, a signal transmission distance between the two circuits connected to the bit line can be shortened, and the resistance and parasitic capacitance of the bit line can be significantly reduced, so that power consumption and signal delays can be reduced. Moreover, even when the capacitance of the capacitors included in the memory cells 10 is reduced, operation of the memory device is possible.

The functional circuit 51 has functions of amplifying a data potential retained in the memory cell 10 and outputting the amplified data potential to a sense amplifier 46 included in the driver circuit 21 through a wiring GBL (not illustrated) described later. With this structure, a slight difference in the potential of the wiring BL can be amplified at the time of data reading. Like the wiring BL, the wiring GBL can be provided in the direction perpendicular to the surface of the substrate provided with the driver circuit 21. Since the wiring BL and the wiring GBL provided to extend from the memory cells 10 included in the memory arrays 20[1] to 20[m] are provided in the direction perpendicular to the surface of the substrate, the length of the wiring between the functional circuit 51 and the sense amplifier 46 can be shortened. Accordingly, a signal transmission distance between the two circuits connected to the wiring GBL can be shortened, and the resistance and parasitic capacitance of the wiring GBL can be significantly reduced, so that power consumption and signal delays can be reduced.

The wiring BL is provided in contact with a semiconductor layer of the transistor included in the memory cell 10. Alternatively, the wiring BL is provided in contact with a region functioning as a source or a drain in the semiconductor layer of the transistor included in the memory cell 10. Alternatively, the wiring BL is provided in contact with a conductor provided in contact with the region functioning as the source or the drain in the semiconductor layer of the transistor included in the memory cell 10. In other words, the wiring BL is a wiring for electrically connecting one of the source and the drain of the transistor included in the memory cell 10 in each layer of the memory array 20 to the functional circuit 51 in the perpendicular direction.

The memory array 20 can be provided over the driver circuit 21 to overlap therewith. When the driver circuit 21 and the memory array 20 are provided to overlap with each other, a signal transmission distance between the driver circuit 21 and the memory array 20 can be shortened. Accordingly, the resistance and parasitic capacitance between the driver circuit 21 and the memory array 20 are reduced, so that power consumption and signal delays can be reduced. In addition, the memory device 300 can be downsized.

The functional circuit 51 can be provided freely, e.g., over a circuit that is formed using Si transistors, in a manner similar to the memory arrays 20[1] to 20[m] when an OS transistor like the transistor included in the memory cell 10 of the DOSRAM is used for the functional circuit 51, and thus, integration can be easily performed. With the structure in which a signal is amplified by the functional circuit 51, a circuit in a subsequent stage, such as the sense amplifier 46, can be downsized, so that the memory device 300 can be downsized.

The driver circuit 21 includes a PSW 22 (power switch), a PSW 23, and a peripheral circuit 31. The peripheral circuit 31 includes a peripheral circuit 41, a control circuit 32 (Control Circuit), and a voltage generation circuit 33.

In the memory device 300, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. The signal PON1 and the signal PON2 may be generated in the control circuit 32.

The control circuit 32 is a logic circuit having a function of controlling the entire operation of the memory device 300. For example, the control circuit performs a logical operation on the signal CE, the signal GW, and the signal BW to determine an operation mode (e.g., a writing operation or a reading operation) of the memory device 300. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 is a circuit that outputs signals for controlling the functional circuits 51. The peripheral circuit 41 includes a row decoder 42, a column decoder 44 (Column Decoder), a row driver 43, a column driver 45 (Column Driver), an input circuit 47 (Input Cir.), an output circuit 48 (Output Cir.), and the sense amplifier 46 (Sense Amplifier).

The row decoder 42 and the column decoder 44 have a function of decoding the signal ADDR. The row decoder 42 is a circuit for addressing a row to be accessed, and the column decoder 44 is a circuit for addressing a column to be accessed. The row driver 43 has a function of selecting the wiring WL addressed by the row decoder 42. The column driver 45 has a function of writing data to the memory cells 10, a function of reading data from the memory cells 10, a function of retaining the read data, and the like.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. The output circuit 48 also has a function of outputting Dout to the outside of the memory device 300. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 300, a high power supply potential is VDD and a low power supply potential is GND (a ground potential). In addition, VHM is a high power supply potential used to set a word line at a high level and is higher than VDD. The on/off of the PSW 22 is controlled by the signal PON1, and the on/off of the PSW 23 is controlled by the signal PON2. In the peripheral circuit 31 in FIG. 32, the number of power domains to which VDD is supplied is one but can be more than one. In that case, a power switch can be provided for each power domain.

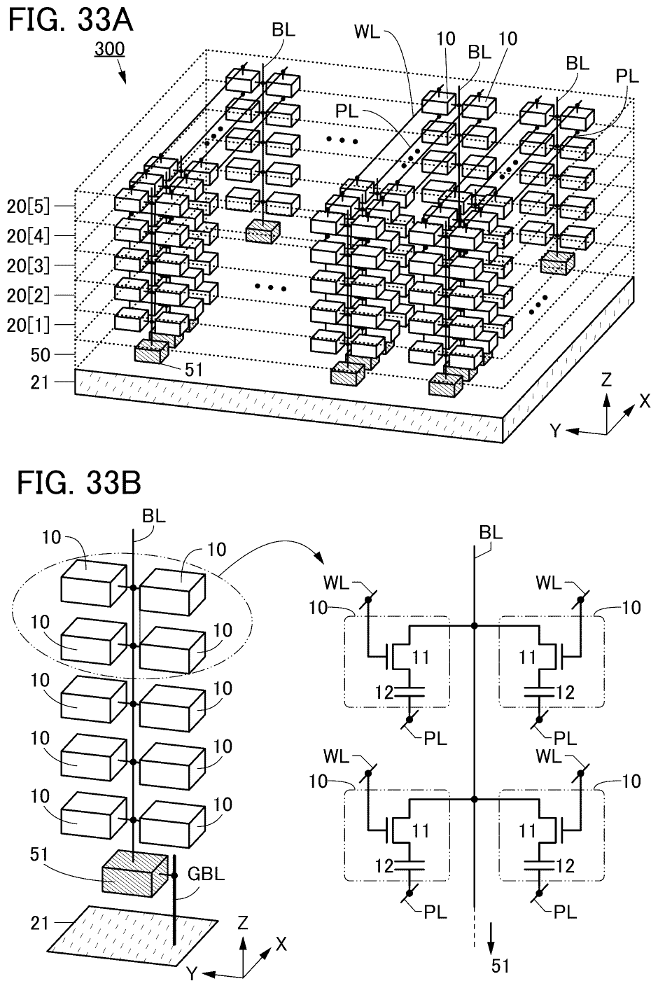

In the memory array 20 including the memory arrays 20[1] to 20[m] (m is an integer greater than or equal to 2) and the functional layer 50, a plurality of layers of the memory arrays 20 can be stacked over the driver circuit 21. Stacking the plurality of layers of the memory arrays 20 can increase the memory density of the memory cells 10. FIG. 33A is a perspective view of the memory device 300 in which five layers of the memory arrays 20[1] to 20[5] (m=5) and the functional layer 50 are stacked over the driver circuit 21.

In FIG. 33A, the memory array 20 provided in the first layer is denoted as the memory array 20[1], the memory array 20 provided in the second layer is denoted as the memory array 20[2], and the memory array 20 provided in the fifth layer is denoted as the memory array 20[5]. FIG. 33A also illustrates the wiring WL and the wiring PL extending in the X direction and the wiring BL extending in the Z direction (the direction perpendicular to the surface of the substrate provided with the driver circuit). For the sake of easy viewing of the drawing, some of the wirings WL and the wirings PL included in the memory arrays 20 are not illustrated. Although FIG. 33A illustrates the structure in which the wiring PL extends in the X direction, the present invention is not limited to the structure. For example, the wiring PL may extend in the Y direction, or the wiring PL may extend in the X direction and the Y direction, for example, the wiring PL may be provided in a planar manner.

FIG. 33B is a schematic view illustrating structure examples of the functional circuit 51, which is connected to the wiring BL illustrated in FIG. 33A, and the memory cells 10 included in the memory arrays 20[1] to 20[5], which are connected to the wiring BL. FIG. 33B illustrates the wiring GBL provided between the functional circuit 51 and the driver circuit 21. Incidentally, a structure in which a plurality of memory cells (memory cells 10) are electrically connected to one of the wirings BL is also referred to as “memory string”. In the drawings, the wiring GBL is represented by a bold line for increasing visibility in some cases.

FIG. 33B illustrates an example of a circuit structure of the memory cell 10 connected to the wiring BL. The memory cell 10 includes a transistor 11 and a capacitor 12. As for the transistor 11, the capacitor 12, and the wirings (e.g., BL and WL), for example, the wiring BL[1] and the wiring WL[1] are referred to as the wiring BL and the wiring WL, respectively, in some cases.

In the memory cell 10, one of a source and a drain of the transistor 11 is connected to the wiring BL. The other of the source and the drain of the transistor 11 is connected to one electrode of the capacitor 12. The other electrode of the capacitor 12 is connected to the wiring PL. A gate of the transistor 11 is connected to the wiring WL.

For example, the two memory cells 10 connected to the common wiring BL in the same layer can have the structure illustrated in FIG. 23 according to Embodiment 1.

Although FIG. 33B and the like illustrate the structure in which two memory cells 10 are connected to the common wiring BL in the same layer, the present invention is not limited to the structure. For example, the common wiring BL in the same layer may be provided with four memory cells 10 or the common wiring BL in the same layer may be provided with eight memory cells 10.

The wiring PL is a wiring for supplying a constant potential for retaining the potential of the capacitor 12.

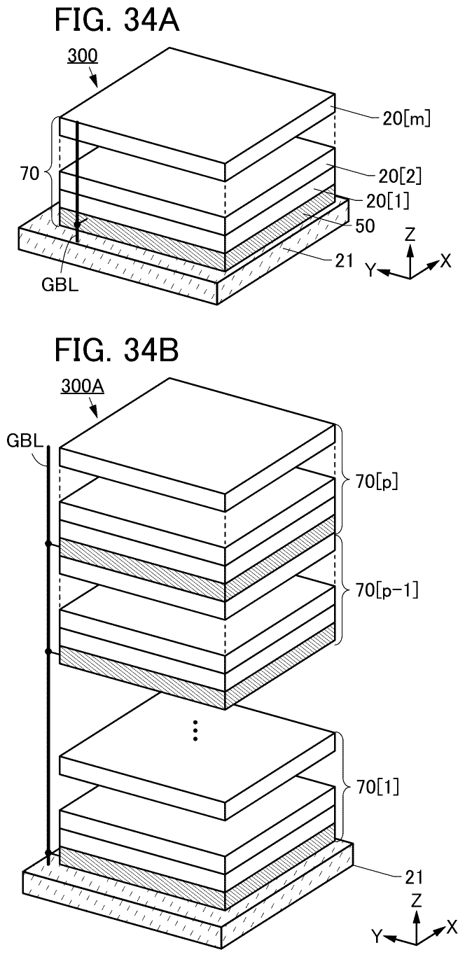

The wiring GBL illustrated in FIG. 33B is provided to electrically connect the driver circuit 21 and the functional layer 50. FIG. 34A is a schematic view of the memory device 300 in which the functional layer 51 and the memory arrays 20[1] to 20[m] are regarded as a repeating unit 70. Although FIG. 34A illustrates one wiring GBL, the wiring GBL may be provided as appropriate according to the number of functional circuits 51 provided in the functional layer 50.

The wiring GBL is provided in contact with a semiconductor layer of a transistor included in the functional circuit 51. Alternatively, the wiring GBL is provided in contact with a region functioning as a source or a drain in the semiconductor layer of the transistor included in the functional circuit 51. Alternatively, the wiring GBL is provided in contact with a conductor provided in contact with the region functioning as the source or the drain in the semiconductor layer of the transistor included in the functional circuit 51. In other words, the wiring GBL is a wiring for electrically connecting the driver circuit 21 and one of the source and the drain of the transistor included in the functional circuit 51 in the functional layer 50 in the perpendicular direction.

The repeating units 70 each including the functional circuit 51 and the memory arrays 20[1] to 20[m] may be stacked. A memory device 300A of one embodiment of the present invention can include repeating units 70[1] to 70[p] (p is an integer greater than or equal to 2) as illustrated in FIG. 34B. The wiring GBL is connected to the functional layers 50 included in the repeating units 70. The wiring GBL may be provided as appropriate according to the number of functional circuits 51.

In one embodiment of the present invention, OS transistors are stacked, and a wiring functioning as a bit line is placed in the direction perpendicular to the surface of the substrate provided with the driver circuit 21. Since the wiring provided to extend from the memory array 20 and function as a bit line is provided in the direction perpendicular to the surface of the substrate, the length of the wiring between the memory array 20 and the driver circuit 21 can be shortened. Thus, the parasitic capacitance of the bit line can be significantly reduced.

In one embodiment of the present invention, the functional layer 50 including the functional circuit 51 having functions of amplifying and outputting a data potential retained in the memory cell 10 is provided in a layer where the memory array 20 is provided. With this structure, a slight difference in the potential of the wiring BL functioning as a bit line can be amplified at the time of data reading to drive the sense amplifier 46 included in the driver circuit 21. A circuit such as a sense amplifier can be downsized, so that the memory device 300 can be downsized. Moreover, even when the capacitance of the capacitors 12 included in the memory cells 10 is reduced, operation is possible.

### Structure Examples of Memory Array 20 and Functional Circuit 51

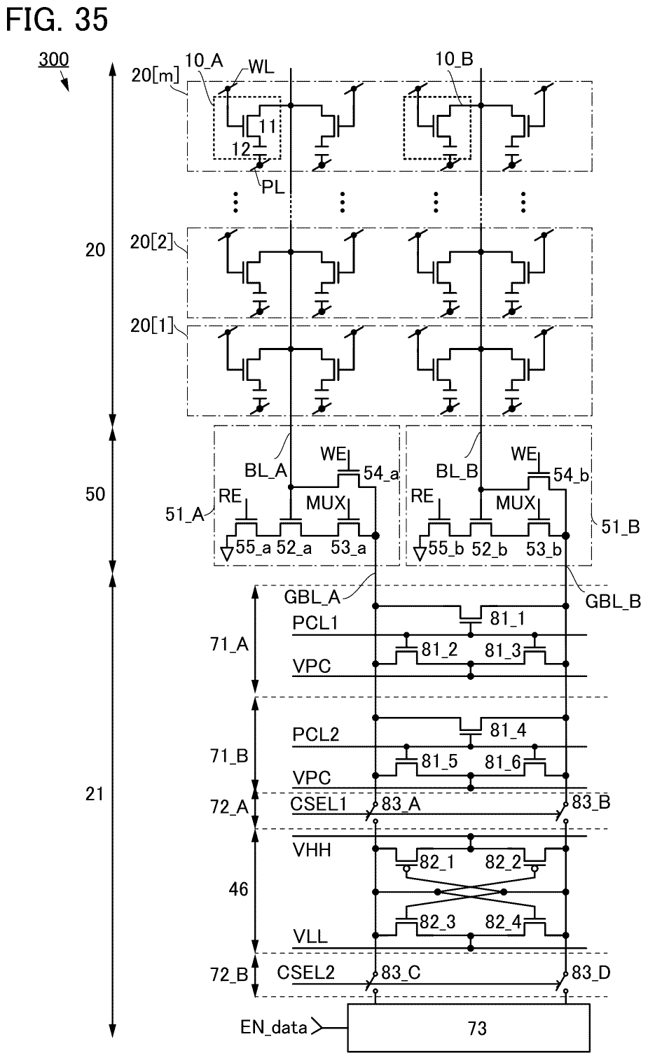

A structure example of the functional circuit 51 and structure examples of the memory array 20 and the sense amplifier 46 included in the driver circuit 21, which are described with reference to FIG. 32 to FIG. 34, are described with reference to FIG. 35. FIG. 35 illustrates the driver circuit 21 connected to the wirings GBL (GBL_A and GBL_B) connected to the functional circuits 51 (51_A and 51_B) connected to the memory cells 10 (10_A and 10_B) connected to different wirings BL (BL_A and BL_B). FIG. 35 illustrates, as the driver circuit 21, a precharge circuit 71_A, a precharge circuit 71_B, a switch circuit 72_A, a switch circuit 72_B, and a write/read circuit 73 in addition to the sense amplifier 46.

As the functional circuit 51_A and the functional circuit 51_B, a transistor 52_a, a transistor 52_b, a transistor 53_a, a transistor 53_b, a transistor 54_a, a transistor 54_b, a transistor 55_a, and a transistor 55_b are illustrated. The transistors 52_a, 52_b, 53_a, 53_b, 54_a, 54_b, 55_a, and 55_b illustrated in FIG. 35 are OS transistors, like the transistor 11 included in the memory cell 10. The functional layer 50 including the functional circuits 51 can be stacked, like the memory array 20[1] to the memory array 20[m].

The wirings BL_A and BL_B are connected to gates of the transistors 52_a and 52_b. Ones of sources and drains of the transistors 53_a, 53_b, 54_a, and 54_b are connected to the wirings GBL_A and GBL_B. The wirings GBL_A and GBL_B are provided in the perpendicular direction, like the wirings BL_A and BL_B, and connected to the transistors included in the driver circuit 21. As illustrated in FIG. 35, control signals WE, RE, and MUX are supplied to gates of the transistors 53_a, 53_b, 54_a, 54_b, 55_a, and 55_b.

Transistors 81_1 to 81_6 and 82_1 to 82_4 included in the sense amplifier 46, the precharge circuit 71_A, and the precharge circuit 71_B illustrated in FIG. 35 are configured with Si transistors. Switches 83_A to 83_D included in the switch circuit 72_A and the switch circuit 72_B can also be configured with Si transistors. The one of the source and the drain of each of the transistors 53_a, 53_b, 54_a, and 54_b is connected to the transistor or switch included in the precharge circuit 71_A, the precharge circuit 71_B, the sense amplifier 46, or the switch circuit 72_A.

The precharge circuit 71_A includes the n-channel transistors 81_1 to the n-channel transistor 81_3. The precharge circuit 71_A is a circuit for precharging the wirings BL_A and BL_B with an intermediate potential VPC corresponding to a potential VDD/2 between VDD and VSS in accordance with a precharge signal supplied to a precharge line PCL1.

The precharge circuit 71_B includes the n-channel transistors 81_4 to 81_6. The precharge circuit 71_B is a circuit for precharging the wiring GBL_A and the wiring GBL_B with the intermediate potential VPC corresponding to the potential VDD/2 between VDD and VSS in accordance with a precharge signal supplied to a precharge line PCL2.

The sense amplifier 46 includes a p-channel transistor 82_1, a p-channel transistor 82_2, an n-channel transistor 82_3, and an n-channel transistor 82_4, which are connected to a wiring VHH or a wiring VLL. The wiring VHH or the wiring VLL is a wiring having a function of supplying VDD or VSS. The transistors 82_1 to 82_4 are transistors that form an inverter loop. The potentials of the wiring BL_A and the wiring BL_B precharged are changed by selecting a memory cell 10_A and a memory cell 10_B, and the potentials of the wiring GBL_A and the wiring GBL_B are set to the high power supply potential VDD or the low power supply potential VSS in accordance with the change. The potentials of the wiring GBL_A and the wiring GBL_B can be output to the outside through a switch 83_C, a switch 83_D, and the write/read circuit 73. The wiring BL_A and the wiring BL_B correspond to a bit line pair, and the wiring GBL_A and the wiring GBL_B correspond to a bit line pair. Data signal writing of the write/read circuit 73 is controlled in accordance with a signal EN_data.

The switch circuit 72_A is a circuit for controlling electrical continuity between the sense amplifier 46 and each of the wiring GBL_A and the wiring GBL_B. The on/off of the switch circuit 72_A is switched under the control of a switch signal CSEL1. In the case where the switch 83_A and the switch 83_B are n-channel transistors, the switch 83_A and the switch 83_B are turned on when the switch signal CSEL1 is at a high level, and the switch 83_A and the switch 83_B are turned off when the switch signal CSEL1 is at a low level. The switch circuit 72_B is a circuit for controlling electrical continuity between the write/read circuit 73 and the bit line pair connected to the sense amplifier 46. The on/off of the switch circuit 72_B is switched under the control of a switching signal CSEL2. The switches 83_C and 83_D can function in a manner similar to the switches 83_A and 83_B.

As illustrated in FIG. 35, the memory device 300 can have a structure where the memory cell 10, the functional circuit 51, and the sense amplifier 46 are connected to each other through the wiring BL and the wiring GBL provided in the perpendicular direction, which is the shortest distance. Although the functional layer 50 including transistors included in the functional circuit 51 is added, the load of the wiring BL can be reduced, the writing time can be shortened, and data reading can be facilitated.

As illustrated in FIG. 35, the transistors included in the functional circuits 51_A and 51_B are controlled in accordance with the control signals WE and RE and the selection signal MUX. The transistors can output the potential of the wiring BL through the wiring GBL to the driver circuit 21 in accordance with the control signals and the selection signal. The functional circuits 51_A and 51_B can function as a sense amplifier configured with OS transistors. With this structure, a slight difference in the potential of the wiring BL can be amplified at the time of reading to drive the sense amplifier 46 using Si transistors.

When a plurality of memory cell arrays and a driver circuit are stacked as described above, high integration and large memory capacity of the memory device can be achieved.

This embodiment can be combined as appropriate with any of the other embodiments and the like described in this specification.

### Embodiment 4

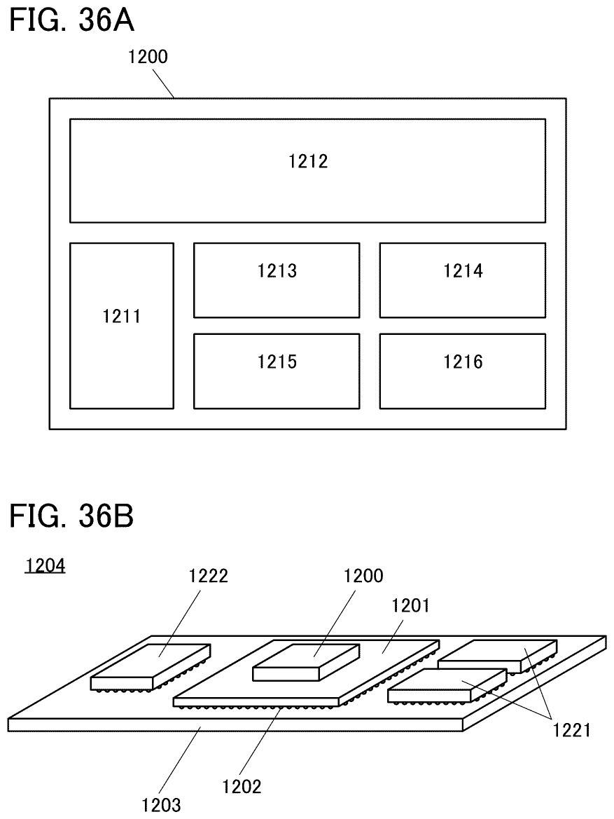

In this embodiment, an example of a chip 1200 on which the memory device of the present invention is mounted is described with reference to FIG. 36A and FIG. 36B. A plurality of circuits (systems) are mounted on the chip 1200. A technique for integrating a plurality of circuits (systems) into one chip is referred to as system on chip (SoC) in some cases.

As illustrated in FIG. 36A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 36B, the chip 1200 is connected to a first surface of a package substrate 1201. In addition, a plurality of bumps 1202 are provided on a rear side of the first surface of the package substrate 1201, and the package substrate 1201 is connected to a motherboard 1203.

Memory devices such as DRAMs 1221 and a flash memory 1222 may be provided over the motherboard 1203. For example, the DOSRAM described in the above embodiment can be used as the DRAM 1221. In that case, the DRAMs 1221 can have lower power consumption, higher speed, and higher capacity.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a memory common to the CPU 1211 and the GPU 1212 may be provided in the chip 1200. The DOSRAM described above can be used as the memory. Moreover, the GPU 1212 is suitable for parallel computation of a large number of pieces of data and thus can be used for image processing or product-sum operation. When an image processing circuit or a product-sum operation circuit including an oxide semiconductor of the present invention is provided in the GPU 1212, image processing and product-sum operation can be performed with low power consumption.

In addition, since the CPU 1211 and the GPU 1212 are provided on the same chip, a wiring between the CPU 1211 and the GPU 1212 can be shortened, and the data transfer from the CPU 1211 to the GPU 1212, the data transfer between memories included in the CPU 1211 and the GPU 1212, and the transfer of results obtained by arithmetic operation in the GPU 1212 from the GPU 1212 to the CPU 1211 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit with an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 employing SoC technology, and thus can have a small size. In addition, the GPU module 1204 excels in image processing, and thus is suitably used in a portable electronic appliance such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

At least part of the structure, method, and the like described in this embodiment can be implemented in an appropriate combination with any of the other embodiments, examples, and the like described in this specification.

### Embodiment 5

In this embodiment, examples of electronic components and electronic appliances in which the memory device or the like described in the above embodiment is incorporated are described. When the memory device described in the above embodiment is used for electronic components and electronic appliances described below, the electronic components and electronic appliances can have lower power consumption and higher speed.

### <Electronic Component>

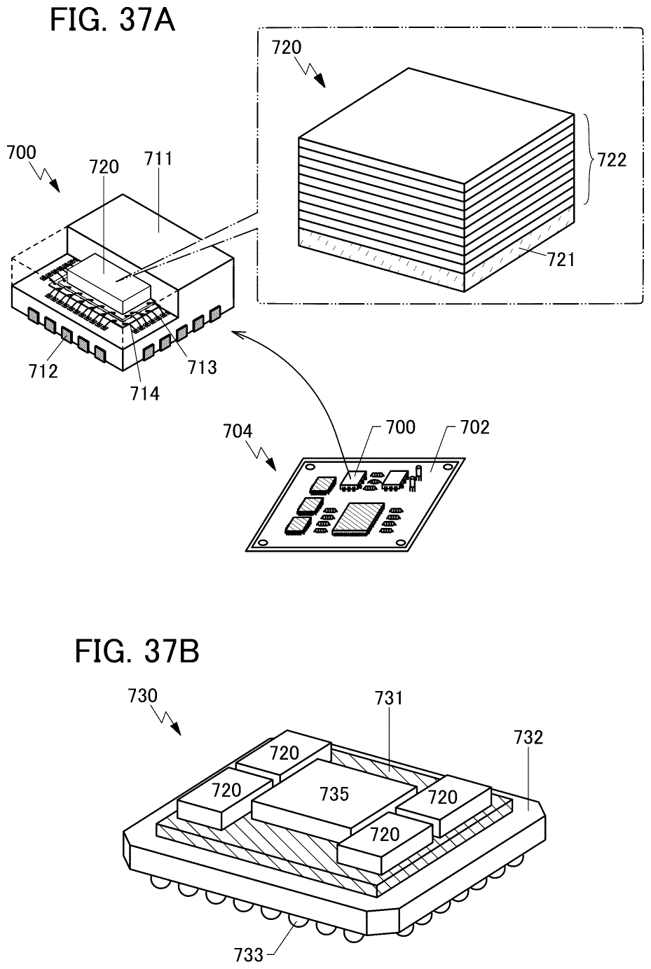

First, examples of an electronic component including a memory device 720 are described with reference to FIG. 37A and FIG. 37B.

FIG. 37A is a perspective view of an electronic component 700 and a substrate (mounting board 704) on which the electronic component 700 is mounted. The electronic component 700 illustrated in FIG. 37A includes the memory device 720 in a mold 711. FIG. 37A omits part of the electronic component to show the inside of the electronic component 700. The electronic component 700 includes a land 712 outside the mold 711. The land 712 is electrically connected to an electrode pad 713, and the electrode pad 713 is electrically connected to the memory device 720 via a wire 714. The electronic component 700 is mounted on a printed circuit board 702, for example. A plurality of such electronic components are combined and electrically connected to each other on the printed circuit board 702, which forms the mounting board 704.

The memory device 720 includes a driver circuit layer 721 and a memory circuit layer 722.

FIG. 37B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the memory devices 720 are provided over the interposer 731. When the memory device described in the above embodiment is used as the memory device 720, power consumption can be reduced and higher speed can be achieved.

An integrated circuit (semiconductor device) such as a CPU, a GPU, or an FPGA can be used as the semiconductor device 735.

As the package substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings have a single-layer structure or a multilayer structure. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 and be used for electrically connecting the integrated circuit and the package substrate 732 in some cases. In the case of using a silicon interposer, a TSV (Through Silicon Via) can also be used as the through electrode.

A silicon interposer is preferably used as the interposer 731. The silicon interposer can be manufactured at lower cost than an integrated circuit because the silicon interposer does not need to be provided with an active element. Meanwhile, since wirings of the silicon interposer can be formed through a semiconductor process, the formation of minute wirings, which is difficult for a resin interposer, is easily achieved.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. In particular, a silicon interposer is preferably used for a 2.5D package (2.5-dimensional packaging) in which a plurality of integrated circuits are arranged side by side on the interposer.

A heat sink (radiator plate) may be provided to overlap with the electronic component 730. In the case of providing a heat sink, the heights of integrated circuits provided on the interposer 731 are preferably the same. In the electronic component 730 of this embodiment, the heights of the memory device 720 and the semiconductor device 735 are preferably the same, for example.

An electrode 733 may be provided on the bottom portion of the package substrate 732 to mount the electronic component 730 on another substrate. FIG. 37B illustrates an example where the electrode 733 is formed of a solder ball. By providing solder balls in a matrix on the bottom portion of the package substrate 732, BGA (Ball Grid Array) packaging can be achieved. Alternatively, the electrode 733 may be formed of a conductive pin. When conductive pins are provided in a matrix on the bottom portion of the package substrate 732, PGA (Pin Grid Array) packaging can be achieved.

The electronic component 730 can be mounted on another substrate by any of various packaging methods other than BGA and PGA. For example, a packaging method such as SPGA (Staggered Pin Grid Array), LGA (Land Grid Array), QFP (Quad Flat Package), QFJ (Quad Flat J-leaded package), or QFN (Quad Flat Non-leaded package) can be employed.

The structure, method, and the like described in this embodiment can be used in an appropriate combination with any of the other structures, methods, and the like described in this embodiment or any of the structures, methods, and the like described in the other embodiments.

### Embodiment 6

In this embodiment, application examples of the memory device using the memory device described in the above embodiment are described. The memory device described in the above embodiment can be used in, for example, memory devices of a variety of electronic appliances (e.g., information terminals, computers, smartphones, e-book readers, digital cameras (including video cameras), video recording/reproducing devices, and navigation systems). When the memory device described in the above embodiment is used for the memory devices of the above electronic appliances, the electronic appliances can have lower power consumption and higher speed. Here, the computers refer not only to tablet computers, notebook computers, and desktop computers, but also to large computers such as server systems. Alternatively, the memory device described in the above embodiment is used in a variety of removable memory devices such as memory cards (e.g., SD cards), USB memories, and SSDs (solid state drives).

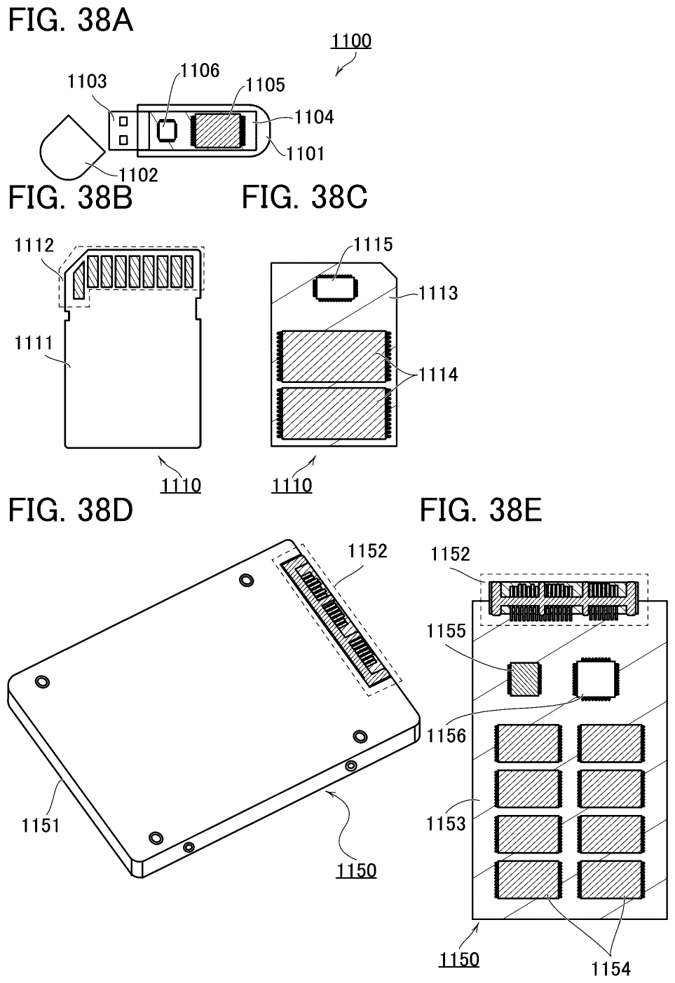

FIG. 38A to FIG. 38E schematically illustrate structure examples of some removable memory devices. The memory device described in the above embodiment is processed into a packaged memory chip and used in a variety of storage devices and removable memories, for example. FIG. 38A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The memory device described in the above embodiment can be incorporated in the memory chip 1105 or the like.

FIG. 38B is a schematic external view of an SD card, and FIG. 38C is a schematic view of an internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the rear side of the substrate 1113, the capacity of the SD card 1110 can be increased. In addition, a wireless chip with a radio communication function may be provided on the substrate 1113. This enables data reading and writing of the memory chip 1114 by wireless communication between a host device and the SD card 1110. The memory device described in the above embodiment can be incorporated in the memory chip 1114 or the like.

FIG. 38D is a schematic external view of an SSD, and FIG. 38E is a schematic view of an internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip can be used, for example. When the memory chip 1154 is also provided on the rear side of the substrate 1153, the capacity of the SSD 1150 can be increased. The memory device described in the above embodiment can be incorporated in the memory chip 1154 or the like.

At least part of the structure, method, and the like described in this embodiment can be implemented in an appropriate combination with any of those in the other embodiments, examples, and the like described in this specification.

### Embodiment 7

In this embodiment, electronic components, electronic devices, a large computer, space equipment, and a data center (also referred to as DC) in which the semiconductor device or the memory device described in the above embodiment can be used will be described. Electronic components, electronic devices, a large computer, space equipment, and a data center in which the semiconductor device or the memory device of one embodiment of the present invention is used are effective in improving performance, e.g., reducing power consumption.

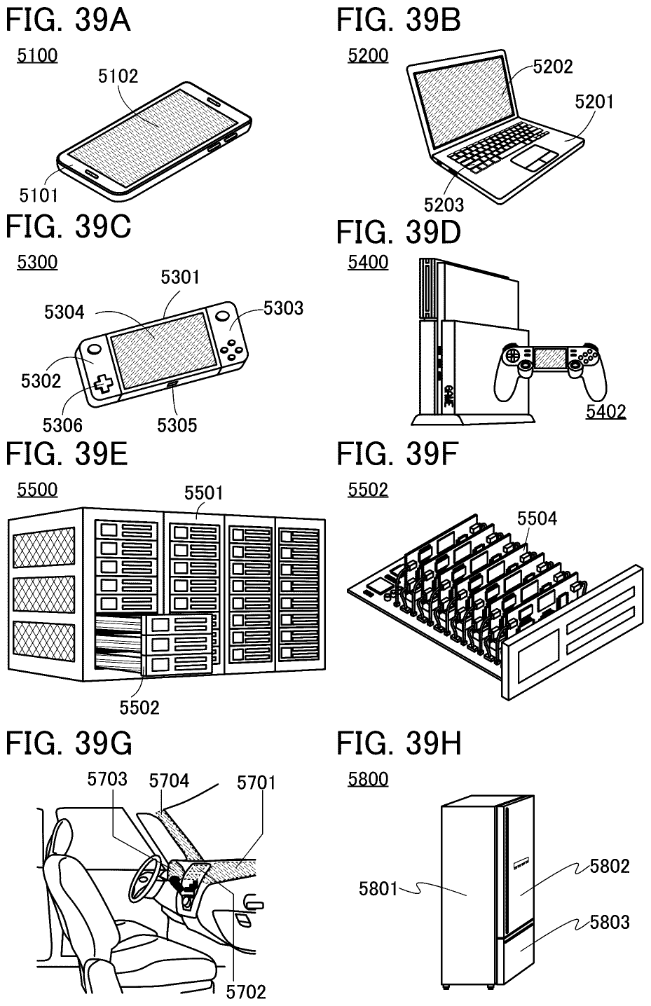

The memory device of one embodiment of the present invention can be used as a processor, e.g., a CPU or a GPU, or a chip. When such a processor, e.g., a CPU or a GPU, or such a chip is used for an electronic appliance, the electronic appliance can have lower power consumption and higher speed. FIG. 39A to FIG. 39H illustrate specific examples of electronic appliances provided with the processor, e.g., the CPU or the GPU, or the chip that includes the memory device.

### <Electronic Appliance and System>

The GPU or the chip of one embodiment of the present invention can be mounted on a variety of electronic appliances. Examples of electronic appliances include a digital camera, a digital video camera, a digital photo frame, an e-book reader, a mobile phone, a portable game machine, a portable information terminal, and an audio reproducing device in addition to electronic appliances provided with a relatively large screen, such as a television device, a monitor for a desktop or notebook information terminal or the like, digital signage, and a large game machine like a pachinko machine. When the GPU or the chip of one embodiment of the present invention is provided in the electronic appliance, the electronic appliance can include artificial intelligence.

The electronic appliance of one embodiment of the present invention may include an antenna. When a signal is received by the antenna, the electronic appliance can display a video, data, or the like on a display portion. When the electronic appliance includes the antenna and a secondary battery, the antenna may be used for contactless power transmission.

The electronic appliance of one embodiment of the present invention may include a sensor (a sensor having a function of detecting, sensing, or measuring force, displacement, position, speed, acceleration, angular velocity, rotational frequency, distance, light, liquid, magnetism, temperature, a chemical substance, sound, time, hardness, an electric field, current, voltage, electric power, radioactive rays, flow rate, humidity, a gradient, oscillation, odor, or infrared rays).

The electronic appliance of one embodiment of the present invention can have a variety of functions. For example, the electronic appliance can have a function of displaying a variety of data (a still image, a moving image, a text image, and the like) on the display portion, a touch panel function, a function of displaying a calendar, date, time, or the like, a function of executing a variety of software (programs), a wireless communication function, and a function of reading out a program or data stored in a recording medium. FIG. 39A to FIG. 39H illustrate examples of electronic appliances.

### [Information Terminal]

FIG. 39A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

The use of the chip of one embodiment of the present invention for the information terminal 5100 can reduce power consumption and enables higher speed.

FIG. 39B illustrates a notebook information terminal 5200. The notebook information terminal 5200 includes a main body 5201 of the information terminal, a display portion 5202, and a keyboard 5203.

Like the information terminal 5100 described above, the use of the chip of one embodiment of the present invention can reduce power consumption and enables higher speed of the notebook information terminal 5200.

Although FIG. 39A and FIG. 39B illustrate the smartphone and the notebook information terminal, respectively, as examples of the electronic appliance in the above description, an information terminal other than a smartphone and a notebook information terminal can be used. Examples of information terminals other than a smartphone and a notebook information terminal include a PDA (Personal Digital Assistant), a desktop information terminal, and a workstation.

### [Game Machine]

FIG. 39C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), an image to be output to the display portion 5304 can be output to another video device (not illustrated). In this case, the housing 5302 and the housing 5303 can each function as an operating unit. Thus, multiple players can play a game at the same time. The chip described in the above embodiment can be incorporated into the chip or the like provided on a substrate in the housing 5301, the housing 5302, and the housing 5303.

FIG. 39D illustrates a stationary game machine 5400 as an example of a game machine. A controller 5402 is wired or connected wirelessly to the stationary game machine 5400.

Using the GPU or the chip of one embodiment of the present invention in a game machine such as the portable game machine 5300 and the stationary game machine 5400 can achieve a low-power-consumption game machine. Moreover, heat generation from a circuit can be reduced owing to low power consumption; thus, the influence of heat generation on the circuit, a peripheral circuit, and a module can be reduced.

Furthermore, by using the GPU or the chip of one embodiment of the present invention in the portable game machine 5300, low power consumption and high speed can be achieved.

Although the portable game machine and the stationary game machine are illustrated as examples of game machines in FIG. 39C and FIG. 39D, the game machine using the GPU or the chip of one embodiment of the present invention is not limited thereto. Examples of the game machine in which the GPU or the chip of one embodiment of the present invention is used include an arcade game machine installed in entertainment facilities (a game center, an amusement park, and the like), and a throwing machine for batting practice installed in sports facilities.

### [Large Computer]

The GPU or the chip of one embodiment of the present invention can be used in a large computer.

FIG. 39E is a diagram illustrating a supercomputer 5500 as an example of a large computer. FIG. 39F is a diagram illustrating a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504 on which the GPU or the chip described in the above embodiment can be mounted.

The supercomputer 5500 is a large computer mainly used for scientific computation. In scientific computation, an enormous amount of arithmetic operation needs to be processed at high speed; hence, power consumption is high and chips generate a large amount of heat. For example, the amount of digital data used in a data center including a plurality of supercomputers 5500 is quite voluminous. Specifically, the amount of digital data in the world is estimated to exceed 1024 (yotta) byte or 1030 (quetta) byte.

Using the GPU or the chip of one embodiment of the present invention in the supercomputer 5500 can achieve a low-power-consumption supercomputer. Moreover, heat generation from a circuit can be reduced owing to low power consumption; thus, the influence of heat generation on the circuit, a peripheral circuit, and a module can be reduced. Using the GPU or the chip including the memory device of one embodiment of the present invention enables the realization of a low-power-consumption supercomputer. Thus, the amount of digital data in the world is expected to be reduced, leading to a great contribution to global warming countermeasures.

Although a supercomputer is illustrated as an example of a large computer in FIG. 39E and FIG. 39F, a large computer using the GPU or the chip of one embodiment of the present invention is not limited thereto. Other examples of large computers for which the GPU or the chip of one embodiment of the present invention is usable include a computer that provides service (a server) and a large general-purpose computer (a mainframe).

### [Moving Vehicle]

The GPU or the chip of one embodiment of the present invention can be used in an automobile, which is a moving vehicle, and the periphery of a driver's seat in the automobile. FIG. 39G is a diagram illustrating an area around a windshield inside an automobile, which is an example of a moving vehicle. FIG. 39G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, mileage, a fuel gauge, a gear state, air-condition setting, and the like. In addition, the content, layout, or the like of the display on the display panels can be changed as appropriate to suit the user's preference, and thus the design quality can be increased. The display panel 5701 to the display panel 5703 can also be used as lighting devices.

The display panel 5704 can complement a view obstructed by the pillar (a blind spot) by showing an image taken with an image capturing device (not illustrated) provided for the automobile. That is, displaying an image taken with the image capturing device provided on the exterior of the automobile leads to compensation for the blind spot and an increase in safety. In addition, displaying an image to complement a portion that cannot be seen makes it possible for the driver to confirm the safety more naturally and comfortably. The display panel 5704 can also be used as a lighting device.

Since the GPU or the chip of one embodiment of the present invention can be used as a component of artificial intelligence, the chip can be used for an automatic driving system of the automobile, for example. The chip can also be used for a system for navigation, risk prediction, or the like. A structure may be employed in which the display panel 5701 to the display panel 5704 display navigation information, risk prediction information, or the like.

Although an automobile is described above as an example of a moving vehicle, the moving vehicle is not limited to an automobile. Examples of the moving vehicle include a train, a monorail train, a ship, and a flying vehicle (a helicopter, an unmanned aircraft (a drone), an airplane, and a rocket), and these moving vehicles can each have a system utilizing artificial intelligence when the chip of one embodiment of the present invention is used in each of these moving vehicles.

### [Household Appliance]

FIG. 39H illustrates an electric refrigerator-freezer 5800 as an example of a household appliance. The electric refrigerator-freezer 5800 includes a housing 5801, a refrigerator door 5802, a freezer door 5803, and the like.

When the chip of one embodiment of the present invention is used in the electric refrigerator-freezer 5800, the electric refrigerator-freezer 5800 including artificial intelligence can be achieved. Utilizing the artificial intelligence enables the electric refrigerator-freezer 5800 to have a function of automatically making a menu based on foods stored in the electric refrigerator-freezer 5800, expiration dates of the foods, or the like, a function of automatically adjusting temperature to be suitable for the foods stored in the electric refrigerator-freezer 5800, and the like.

Although the electric refrigerator-freezer is described as an example of a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic appliances, the functions of the electronic appliances, the application examples of artificial intelligence, their effects, and the like described in this embodiment can be combined as appropriate with the description of another electronic appliance.

### [Data Center]

The memory device of one embodiment of the present invention can be suitably used for a storage system in a data center, for example. Long-term management of data, such as guarantee of data immutability, is required for the data center. The long-term management of data needs an increase in building size owing to installation of storages and servers for storing an enormous amount of data, stable electric power for data retention, cooling equipment necessary for data retention, and the like.

With use of the memory device of one embodiment of the present invention for the storage system used in the data center, electric power required for data retention can be reduced and a memory device retaining data can be downsized. Thus, downsizing of the storage system, downsizing of the power supply for retaining data, downscaling of the cooling equipment, and the like can be achieved, for example. This can reduce the space of the data center.

Since the memory device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the memory device of one embodiment of the present invention enables a data center that operates stably even in a high-temperature environment. Thus, the reliability of the data center can be increased.

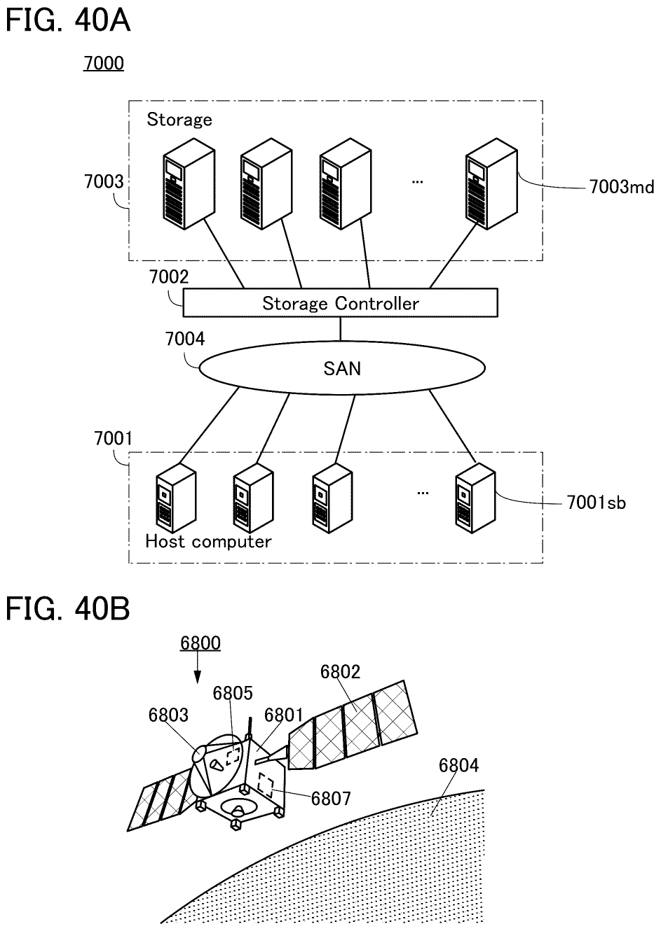

FIG. 40A illustrates a storage system applicable to a data center. A storage system 7000 illustrated in FIG. 40A includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated mode, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is considerably longer than the data access speed of a DRAM that can be used as a cache memory in the storage. In the storage system, in order to solve the problem of low access speed of the storage 7003, a cache memory is normally provided in the storage to shorten the time taken for data storage and output.

The above-described cache memory is used in the storage control circuit 7002 and the storage 7003. The data transmitted between the host 7001 and the storage 7003 is stored in the cache memory in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the memory device of one embodiment of the present invention for one or more selected from an electronic component, an electronic device, a large computer, space equipment, and a data center will produce an effect of reducing power consumption. While the demand for energy is expected to increase with higher performance or higher integration of memory devices, the emission amount of greenhouse effect gases typified by carbon dioxide (CO₂) can be reduced with use of the memory device of one embodiment of the present invention. The memory device of one embodiment of the present invention can be effectively used as one of the global warming countermeasures because of its low power consumption.

The configuration, structure, method, or the like described in this embodiment can be used in combination with the configuration, structure, method, or the like described in the other embodiments and the like as appropriate.

### [Space Equipment]

The memory device of one embodiment of the present invention can be suitably used as space equipment such as equipment that processes and stores information.

The memory device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

FIG. 40B illustrates an artificial satellite 6800 as an example of space equipment. The artificial satellite 6800 includes a body 6801, a solar panel 6802, an antenna 6803, a secondary battery 6805, and a control device 6807. In FIG. 40B, a planet 6804 in outer space is illustrated as an example. Note that outer space refers to, for example, space at an altitude greater than or equal to 100 km, and outer space in this specification may also include thermosphere, mesosphere, and stratosphere.

Although not illustrated in FIG. 40B, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is more than or equal to 100 times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for an operation of the artificial satellite 6800 is generated. However, for example, in the situation where the solar panel is not irradiated with sunlight or the amount of sunlight with which the solar panel is irradiated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed with one or more selected from a CPU, a GPU, and a memory device, for example. Note that the memory device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The memory device of one embodiment of the present invention can be suitably used for a device for space, such as a spacecraft, a space capsule, or a space probe, for example.

As described above, an OS transistor has excellent effects of achieving a wide memory bandwidth and being highly resistant to radiation as compared with a Si transistor.

At least part of the structure, method, and the like described in this embodiment can be implemented in an appropriate combination with any of the other embodiments, examples, and the like described in this specification.

[Reference Numerals]

BL: wiring, PL: wiring, Tr: transistor, WL: wiring, 10: memory cell, 11: transistor, 12: capacitor,
20: memory array, 21: driver circuit, 22: PSW, 23: PSW, 31: peripheral circuit, 32: control circuit,
33: voltage generation circuit, 41: peripheral circuit, 42: row decoder, 43: row driver, 44: column
decoder, 45: column driver, 46: sense amplifier, 47: input circuit, 48: output circuit, 50: functional
layer, 51_A: functional circuit, 51_B: functional circuit, 51: functional circuit, 52_a: transistor,
52_b: transistor, 53_a: transistor, 53_b: transistor, 54_a: transistor, 54_b: transistor, 55_a:
transistor, 55_b: transistor, 70: repeating unit, 71_A: precharge circuit, 71_B: precharge circuit,
72_A: switch circuit, 72_B: switch circuit, 73: write/read circuit, 81_1: transistor, 81_3: transistor,
81_4: transistor, 81_6: transistor, 82_1: transistor, 82_2: transistor, 82_3: transistor, 82_4:
transistor, 83_A: switch, 83_B: switch, 83_C: switch, 83_D: switch, 100a: capacitor, 100b:
capacitor, 100c: capacitor, 100d: capacitor, 100: capacitor, 110: conductor, 115: conductor, 120a:
conductor, 120b: conductor, 120c: conductor, 120: conductor, 122: insulator, 130: insulator, 140:
insulator, 150a: memory cell, 150b: memory cell, 150c: memory cell, 150d: memory cell, 150:
memory cell, 160[1, 1]: memory unit, 160[1, 2]: memory unit, 160[1, 3]: memory unit, 160[1, 4]:
memory unit, 160[2, 1]: memory unit, 160[2, 2]: memory unit, 160[2, 3]: memory unit, 160[2, 4]:
memory unit, 160: memory unit, 170[1]: layer, 170[2]: layer, 170[m-1]: layer, 170[m]: layer, 180:
insulator, 185: insulator, 190: opening portion, 200a: transistor, 200b: transistor, 200c: transistor,
200d: transistor, 200: transistor, 205: conductor, 230a: oxide semiconductor, 230b: oxide
semiconductor, 230: oxide semiconductor, 240a: conductor, 240A: conductive film, 240b:
conductor, 240c: conductor, 240: conductor, 245: conductor, 246: conductor, 250a: insulator,
250b: insulator, 250c: insulator, 250d: insulator, 250: insulator, 252A: insulating film, 252:
insulator, 254A: insulating film, 254: insulator, 256A: insulating film, 256: insulator, 260a:
conductor, 260A: conductive film, 260b: conductor, 260: conductor, 280a: insulator, 280b:
insulator, 280c: insulator, 280: insulator, 283: insulator, 287: insulator, 290: opening portion,
300A: memory device, 300: memory device, 310: transistor, 311: substrate, 313: semiconductor
region, 314a: low-resistance region, 314b: low-resistance region, 315: insulator, 316: conductor,
320: insulator, 322: insulator, 324: insulator, 326: insulator, 328: conductor, 330: conductor, 400:
transistor, 420: conductor, 422: insulator, 430: oxide semiconductor, 440: conductor, 450:
insulator, 452: insulator, 454: insulator, 456: insulator, 480a: insulator, 480b: insulator, 480c:
insulator, 490: opening portion, 500: memory cell, 610: substrate, 611a: precursor, 611b:
precursor, 612a: reactant, 612b: reactant, 613a: oxide, 613b: oxide, 613c: oxide, 621: layer, 622:
layer, 631: layer, 641: layer, 650: structural element, 653: region, 654: region, 660: oxide, 662:
oxide, 700: electronic component, 702: printed circuit board, 704: mounting board, 711: mold,
712: land, 713: electrode pad, 714: wire, 720: memory device, 721: driver circuit layer, 722:
memory circuit layer, 730: electronic component, 731: interposer, 732: package substrate, 733:
electrode, 735: semiconductor device, 1100: USB memory, 1101: housing, 1102: cap, 1103: USB
connector, 1104: substrate, 1105: memory chip, 1106: controller chip, 1110: SD card, 1111:
housing, 1112: connector, 1113: substrate, 1114: memory chip, 1115: controller chip, 1150: SSD,
1151: housing, 1152: connector, 1153: substrate, 1154: memory chip, 1155: memory chip, 1156:
controller chip, 1200: chip, 1201: package substrate, 1202: bump, 1203: motherboard, 1204: GPU
module, 1211: CPU, 1212: GPU, 1213: analog arithmetic unit, 1214: memory controller, 1215:
interface, 1216: network circuit, 1221: DRAM, 1222: flash memory, 5100: information terminal,
5101: housing, 5102: display portion, 5200: notebook information terminal, 5201: main body,
5202: display portion, 5203: keyboard, 5300: portable game machine, 5301: housing, 5302:
housing, 5303: housing, 5304: display portion, 5305: connection portion, 5306: operation key,
5400: stationary game machine, 5402: controller, 5500: supercomputer, 5501: rack, 5502:
computer, 5504: substrate, 5701: display panel, 5702: display panel, 5703: display panel, 5704:
display panel, 5800: electric refrigerator-freezer, 5801: housing, 5802: refrigerator door, 5803:
freezer door, 6800: artificial satellite, 6801: body, 6802: solar panel, 6803: antenna, 6804: planet,
6805: secondary battery, 6807: control device, 7000: storage system, 7001sb: server, 7001: host,
7002: storage control circuit, 7003md: memory device, 7003: storage

1. A semiconductor device comprising:
a first conductor;
a first insulator;
a second conductor over the first insulator;
an oxide semiconductor;
a second insulator;
a third conductor;
a third insulator; and
a fourth insulator,
wherein an opening portion reaching the first conductor is provided in the first insulator and the second conductor,
wherein part of the oxide semiconductor is placed in the opening portion and is in contact with a top surface of the first conductor,
wherein another part of the oxide semiconductor is placed over the opening portion and is in contact with at least part of a top surface of the second conductor,
wherein the second insulator is placed over the oxide semiconductor so that at least part of the second insulator is positioned in the opening portion,
wherein the third conductor is placed over the second insulator so that at least part of the third conductor is positioned in the opening portion,
wherein the third insulator is placed between a sidewall of the opening portion and the oxide semiconductor so as to be positioned in the opening portion,
wherein the fourth insulator is placed between the sidewall of the opening portion and the third insulator so as to be positioned in the opening portion,
wherein the third insulator comprises a metal oxide, and
wherein the fourth insulator comprises silicon nitride.

2. The semiconductor device according to claim 1,
the first insulator further comprising:
a first layer;
a second layer over the first layer; and
a third layer over the second layer,
wherein the first layer and the third layer each comprise silicon nitride, and
wherein the second layer comprises silicon oxide.

3. The semiconductor device according to claim 2,
wherein a side surface of the second conductor is in contact with the fourth insulator.

4. The semiconductor device according to claim 2,
wherein part of a bottom surface of the second conductor is in contact with an upper end portion of the third insulator and an upper end portion of the fourth insulator.

5. The semiconductor device according to claim 2,
wherein part of a bottom surface of the third layer is in contact with an upper end portion of the third insulator and an upper end portion of the fourth insulator.

6. The semiconductor device according to claim 1,
wherein a width of the opening portion is larger than a height of the opening portion in a cross-sectional view.

7. The semiconductor device according to claim 6, further comprising a fifth insulator comprising silicon oxide,
wherein the fifth insulator is placed between the third insulator and the oxide semiconductor so as to be positioned in the opening portion.

8. The semiconductor device according to claim 7,
wherein part of the fourth insulator is placed under the third insulator, and
wherein part of the fourth insulator is in contact with a lower end portion of the third insulator and a side surface of the fifth insulator.

9. The semiconductor device according to claim 6,
wherein the metal oxide comprises hafnium.

10. A semiconductor device comprising:
a first conductor;
a second conductor;
a third conductor;
a fourth conductor;
an oxide semiconductor;
a first insulator;
a second insulator;
a third insulator;
a fourth insulator; and
a fifth insulator,
wherein the second conductor is positioned over the first insulator,
wherein the second insulator is positioned over the second conductor,
wherein the third conductor is positioned over the second insulator,
wherein an opening portion reaching the first conductor is provided in the first insulator, the second conductor, the second insulator, and the third conductor,
wherein part of the oxide semiconductor is placed in the opening portion and is in contact with a top surface of the first conductor,
wherein another part of the oxide semiconductor is in contact with at least part of a top surface of the third conductor outside the opening portion,
wherein the third insulator is placed over the oxide semiconductor so that at least part of the third insulator is positioned in the opening portion,
wherein the fourth conductor is placed over the third insulator so that at least part of the fourth conductor is positioned in the opening portion,
wherein the fourth insulator is placed between the second conductor and the oxide semiconductor so as to be positioned in the opening portion,
wherein the fifth insulator is placed between the second conductor and the fourth insulator so as to be positioned in the opening portion,
wherein the fourth insulator comprises a metal oxide, and
wherein the fifth insulator comprises silicon nitride.

11. The semiconductor device according to claim 10,
wherein the first insulator and the second insulator each comprise silicon nitride.

12. The semiconductor device according to claim 10,
wherein a side surface of the third conductor is in contact with the fifth insulator.

13. The semiconductor device according to claim 10,
wherein part of a bottom surface of the third conductor is in contact with an upper end portion of the fourth insulator and an upper end portion of the fifth insulator.

14. The semiconductor device according to claim 10,
wherein part of a bottom surface of the second insulator is in contact with an upper end portion of the fourth insulator and an upper end portion of the fifth insulator.

15. The semiconductor device according to claim 10,
wherein a width of the opening portion is larger than a height of the opening portion in a cross-sectional view.

16. The semiconductor device according to claim 15, further comprising a sixth insulator comprising silicon oxide,
wherein the sixth insulator is placed between the fourth insulator and the oxide semiconductor so as to be positioned in the opening portion.

17. The semiconductor device according to claim 16,
wherein part of the fifth insulator is placed under the fourth insulator, and
wherein part of the fifth insulator is in contact with a lower end portion of the fourth insulator and a side surface of the sixth insulator.

18. The semiconductor device according to claim 15,
wherein the metal oxide comprises hafnium.
